(19) United States
(12) Patent Application Publication
(10) Pub. No.: US 2012/0126692 A1
(43) Pub. Date: May 24, 2012

(54) ORGANIC ELECTROLUMINESCENCE DEVICE

(75) Inventors: Toshihiro Ise, Kanagawa (JP); Tetsu Kitamura, Kanagawa (JP); Toru Watanabe, Kanagawa (JP); Akira Takeda, Kanagawa (JP); Keiju Tonosaki, Kanagawa (JP)

(73) Assignee: FUJIFILM CORPORATION, Tokyo (JP)

(21) Appl. No.: 13/388,111

(22) PCT Filed: Jul. 28, 2010
(86) PCT No.: PCT/JP2010/063132

§ 371 Date: Jan. 31, 2012

(30) Foreign Application Priority Data
Jul. 31, 2009 (JP) 2009-180224
Sep. 25, 2009 (JP) 2009-221665

(51) Int. Cl. H05B 33/14; C09K 11/06

(52) U.S. Cl. 313/504; 252/301.16

(57) ABSTRACT

An organic electroluminescence device which has on a substrate a pair of electrodes and a light emitting layer sandwiched between the electrodes, characterized by containing in the light emitting layer a compound represented by the following formula (1) and a particular indium complex;

(Cz)ₚ-L-(A)_{q} (1)

wherein Cz represents a substituted or unsubstituted arylcarbazolyl group or a substituted or unsubstituted carbazolylaryl group, L represents a single bond, a substituted or unsubstituted arylene group, a substituted or unsubstituted cycloalkylene group, or a group derived from a substituted or unsubstituted heteroaromatic ring, A represents a group derived from a substituted or unsubstituted nitrogen-containing heteroaromatic 6-membered ring, and each of p and q independently represents an integer from 1 to 6.

### TECHNICAL FIELD

The present invention relates to an organic electroluminescence device (hereinafter, referred to also as “a device” or “an organic EL device”), and more specifically, an organic electroluminescence device which is excellent in durability at high luminance intensity.

### BACKGROUND ART

Research and development of organic electroluminescence devices has been actively conducted in recent years because highly luminescent luminous is obtained from these devices with low-voltage driving. In general, organic electroluminescence devices are constituted of an organic layer including a light-emitting layer, and a pair of electrodes between which the organic layer is sandwiched, and electrons injected from the cathode are recombined with holes injected from the anode in the light-emitting layer, to produce excitons, whose energy is utilized to luminescence.

Improvement in the efficiency of devices has recently made by using a phosphorescent materials. For instance, WO 05/085387 discloses the organic electroluminescence device whose luminous efficiency and heat resistance are enhanced by using an iridium complex, a platinum complex or the like as a phosphorescent material.

On the other hand, doped devices using light-emitting layers whose host materials are doped with light-emitting materials are widely adopted.

Development of host materials also has been actively made. JP-A-2009-99783, for example, discloses the invention using condensed aromatic polycyclic materials as the host materials to form devices of high efficiency and long life. However, such an invention is insufficient in luminous efficiency and durability with high-temperature driving, and what is more, in the case of considering the uses for display and illumination, such an invention has a problem that shifts in chromaticity are caused as the devices are driven. Improvements in those points are therefore required.

As described in JP-A-2009-99783, it is known that the use of materials which can produce an unstable oxidized species having carbazolyl groups is unfavorable to durability of devices. In light of such common knowledge, embodiments of the present invention couldn't be expected to have effects on durability improvements. On the other hand, in the phosphorescent materials of iridium complex type, it is presumed that devices performance is degraded because of decomposition occurred by leaving ligand, which often occurs in complex-type materials, and production of quencher. Thus the practical use of phosphorescent materials is known to involve difficulties.

However, we have found that durability improvement effects are produced by using host materials containing carbazolyl group according to the invention in combination with specific materials of iridium complex type.

Hitherto, a chromaticity shift accompanied to the driving of a device as well as a rise in drive voltage and a reduction in efficiency has been adopted as a point of evaluation. Further, evaluations have been made at various ambient temperatures from room temperature to high temperatures (mainly in the sense of an acceleration test). However, no attention has been given to the fact that the extent of the chromaticity shift was greater under high-temperature drive than under low-temperature drive. In recent years the range of uses for organic electroluminescence devices has been extended e.g. to uses in displays and panels as well as uses for an illumination purpose. When uses in car-mounted panels or the like, which can get a high temperatures reach 80° C. or higher, are contemplated, it is predicted that the chromaticity shift under high-temperature drive will become an important problem.

### SUMMARY OF INVENTION

An objective of the invention is to provide an organic electroluminescence device which has excellent luminescence characteristics, can suppress a chromaticity shift under high-temperature drive and excel in luminous efficiency.

Another objective of the invention is to provide a composition and a light emitting layer useful to such an organic electroluminescence device. A further objective of the invention is to provide a film formation method for the compound useful to such an organic electroluminescence device. And still another objective of the invention is to provide a light luminous apparatus and an illumination apparatus each incorporating such an organic electroluminescence device.

More specifically, the invention is achieved by the following.

[1] An organic electroluminescence device which has on a substrate a pair of electrodes and a light emitting layer sandwiched between the electrodes, wherein the light emitting layer contains a compound represented by the following formula (1) and a compound represented by the following formula (T-1).

(Cz)p-L-(A)q (1)

In the formula (1), Cz represents a substituted or unsubstituted arylcarbazolyl group or a substituted or unsubstituted carbazolylaryl group, L represents a single bond, a substituted or unsubstituted arylene group, a substituted or unsubstituted cycloalkylene group, or a group derived from a substituted or unsubstituted heteroaromatic ring, A represents a group derived from a substituted or unsubstituted nitrogen-containing heteroaromatic 6-membered ring, and each of p and q independently represents an integer from 1 to 6.

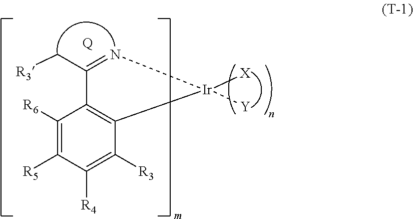

In the formula (T-1), R₃′ represents an alkyl group, a heteroalkyl group, an aryl group or a heteroaryl group, which each may further have a substituent Z; R₅ represents an aryl group or a heteroaryl group, which each may further have a nonaromatic substituent; the ring Q represents an aromatic heterocyclic ring or condensed aromatic heterocyclic ring which has at least one nitrogen atom to form a coordination bond with Ir, and the ring Q may further have a nonaromatic substituent; each of R₃, R₄ and R₆ independently represents a hydrogen atom, an alkyl group, an alkenyl group, an alkynyl group, —CN, —CF₃, —CₙF₂ₙ₊₁, a trifluorovinyl group, —CO₂R, —C(O)R, —NR₂, —NO₂, —OR, a halogen atom, an aryl group or a heteroaryl group, which each may further have a substituent; or R₃ and R₄ may combine with each other to complete a condensed 4- to 7-membered ring, and the 4- to 7-membered ring is a cycloalkane ring, a cycloheteroalkane ring, an arene ring or a heteroarene ring, which each may further have a substituent Z; or R₃′ and R₆ may complete a ring by linking via a linking group selected from the groups consisting of —CR₂—CR₂—, —CR═CR—, —CR₂—, —O—, —NR—, —O—CR₂—, —NR—CR₂— and —N═CR—, wherein each of Rs independently represents a hydrogen atom, an alkyl group, an alkenyl group, an alkynyl group, a heteroalkyl group, an aryl group or a heteroaryl group, which each may further have a substituent Z; each of Zs independently represents a halogen atom, —R′, —OR′, —N(R′)₂, —SR′, —C(O)R′, —C(O)OR′, —C(O)N(R′)₂, —CN, —NO₂, —SO₂, —SOR′, —SO₂R′ or —SO₃R′, and each of R's independently represents a hydrogen atom, an alkyl group, a perhaloalkyl group, an alkenyl group, an alkynyl group, a heteroalkyl group, an aryl group or a heteroaryl group; (X—Y) represents an ancillary ligand; m represents an integer from 1 to 3 and n represents an integer from 0 to 2, provided that m+n=3.

[2] The organic electroluminescence device according to [1],

wherein the compound represented by the formula (1) is a compound represented by the following formula (2).

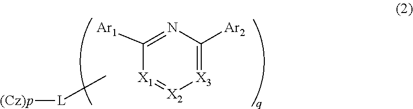

In the formula (2), Cz represents a substituted or unsubstituted arylcarbazolyl group or a substituted or unsubstituted carbazolylaryl group; L represents a single bond, a substituted or unsubstituted arylene group, a substituted or unsubstituted cycloalkylene group, or a group derived from a substituted or unsubstituted heteroaromatic ring, and L is linked to the carbon atom in Ar₁, Ar₂, X₁, X₂ or X₃; each of Ar₁ and Ar₂ independently represents a substituted or unsubstituted aryl group, a substituted or unsubstituted arylene group, or a group derived from a substituted or unsubstituted heteroaromatic ring; each of X₁, X₂ and X₃ independently represents a nitrogen atom or a carbon atom which may have a substituent; and each of p and q independently represents an integer from 1 to 6.

[3] The organic electroluminescence device according to [2],

wherein the compound represented by the formula (2) is a compound represented by the following formula (3).

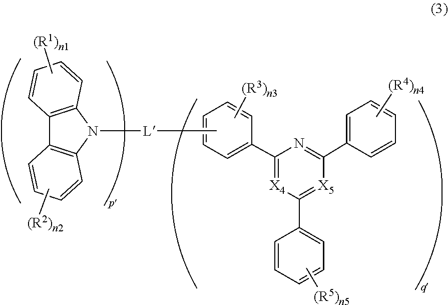

In the formula (3), each of X₄ and X₅ independently represents a nitrogen atom or a carbon atom which may have a substituent, provided that either X₄ or X₅ represents a nitrogen atom and the other represents a carbon atom which may have a substituent; L′ represents a single bond, a substituted or unsubstituted arylene group, a substituted or unsubstituted cycloalkylene group, or a group derived from a substituted or unsubstituted heteroaromatic ring; each of R¹ to R⁵ independently represents a substituent; each of n1 to n5 independently represents an integer from 0 to 5; and each of p′ and q′ independently represents an integer from 1 to 4.

[4] The organic electroluminescence device according to any of [1] to [3], wherein each of the ring from which the group represented by A in the formula (1) is derived, the ring containing X₁ to X₃ in the formula (2) and the ring containing X₄ and X₅ in the formula (3) is pyridine or pyrimidine.
[5] The organic electroluminescence device according to any of [1] to [3],

wherein each of the ring from which the group represented by A in the formula (1) is derived, the ring containing X₁ to X₃ in the formula (2) and the ring containing X₄ and X₅ in the formula (3) is pyrimidine.

[6] The organic electroluminescence device according to any of [1] to [5],

wherein the compound represented by the formula (T-1) is a compound represented by the following formula (T-2).

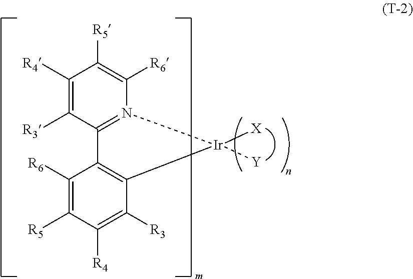

In the formula (T-2), R₃′ represents an alkyl group, a heteroalkyl group, an aryl group or a heteroaryl group, which each may further have a substituent Z; each of R₄′ to R₆′ independently represents a hydrogen atom, an alkyl group, an alkenyl group, an alkynyl group, a heteroalkyl group, an aryl group or a heteroaryl group, which each may further have a substituent Z; or R₃′ and R₄′, or R₄′ and R₅′, or R₅′ and R₆′ may combine with each other to complete a 4- to 7-membered ring condensed with the pyridine ring, and the 4- to 7-membered ring is a cycloalkane ring, a cycloheteroalkane ring, an arene ring or a heteroarene ring, which each may further have a substituent Z; or R₃′ and R₆ may complete a ring by linking via a linking group selected from the groups consisting of —CR₂—CR₂—, —CR═CR—, —CR₂—, —O—, —NR—, —O—CR₂—, —NR—CR₂— and —N═CR—, wherein each of the R₅ independently represents a hydrogen atom, an alkyl group, an alkenyl group, an alkynyl group, a heteroalkyl group, an aryl group or a heteroaryl group, which each may further have a substituent Z; R₅ represents an aryl group or a heteroaryl group, which each may further have a nonaromatic group; each of R₃, R₄ and R₆ independently represents a hydrogen atom, an alkyl group, an alkenyl group, an alkynyl group, —CN, —CF₃, —CₙF₂ₙ₊₁, a trifluorovinyl group, —CO₂R, —C(O)R, —NR₂, —NO₂, —OR, a halogen atom, an aryl group or a heteroaryl group, which each may further have a substituent Z, or R₃ and R₄ may combine with each other to complete a 4- to 7-membered ring condensed with the benzene ring, and the 4- to 7-membered ring is a cycloalkane ring, a cycloheteroalkane ring, an arene ring or a heteroarene ring, which each may further have a substituent Z; each of Zs independently represents a halogen atom, —R′, —OR′, —N(R′)₂, —SR′, —C(O)R′, —C(O)OR′, —C(O)N(R′)₂, —CN, —NO₂, —SO₂, —SOR′, —SO₂R′ or —SO₃R′, and each of R's independently represents a hydrogen atom, an alkyl group, a perhaloalkyl group, an alkenyl group, an alkynyl group, a heteroalkyl group, an aryl group or a heteroaryl group; (X—Y) represents an ancillary ligand; and m represents an integer from 1 to 3 and n represents an integer from 0 to 2, provided that m+n=3.

[7] The organic electroluminescence device according to [6],

wherein the compound represented by the formula (T-2) is a compound represented by the following formula (T-3).

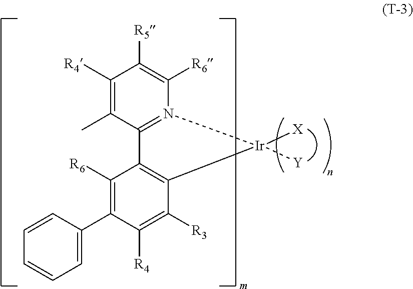

In the formula (T-3), R₄′ represents a hydrogen atom, an alkyl group, an alkenyl group, an alkynyl group, a heteroalkyl group, an aryl group or a heteroacryl group, which each may further have a substituent Z; R₅″ and R₆″ represent hydrogen atoms or combine with each other to complete a condensed 4- to 7-membered ring, and the condensed 4- to 7-membered ring is a cycloalkane ring, a cycloheteroalkane ring, an arene ring or a heteroarene ring; each of R₃, R₄ and R₆ independently represents a hydrogen atom, an alkyl group, an alkenyl group, an alkynyl group, —CN, —CF₃, —CₙF₂ₙ₊₁, a trifluorovinyl group, —CO₂R, —C(O)R, —NR₂, —NO₂, —OR, a halogen atom, an aryl group or a heteroaryl group, which each may further have a substituent Z; each of Rs independently represents a hydrogen atom, an alkyl group, an alkenyl group, an alkynyl group, a heteroalkyl group, an aryl group or a heteroaryl group, which each may further have a substituent Z; or R₃ and R₄ may combine with each other to form a condensed 4- to 7-membered ring, and the 4- to 7-membered ring is a cycloalkane ring, a cycloheteroalkane ring, an arene ring or a heteroarene ring, which each may have a substituent Z; each of Zs independently represents a halogen atom, —R′, —OR′, —N(R′)₂, —SR′, —C(O)R′, —C(O)OR′, —C(O)N(R′)₂, —CN, —NO₂, —SO₂, —SOR′, —SO₂R′ or —SO₃R′, and each of R's independently represents a hydrogen atom, an alkyl group, a perhaloalkyl group, an alkenyl group, an alkynyl group, a heteroalkyl group, an aryl group or a heteroaryl group; (X—Y) represents an ancillary ligand; and m represents an integer from 1 to 3 and n represents an integer from 0 to 2, provided that m+n=3.

[8] The organic electroluminescence device according to [7],

wherein the compound represented by the formula (T-3) is a compound represented by the following formula (T-4).

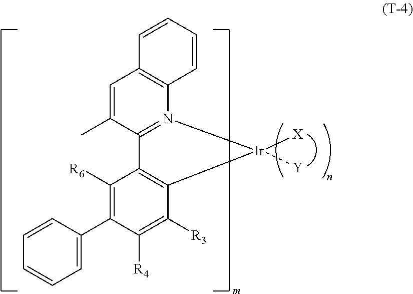

In the formula (T-4), each of R₃, R₄ and R₆ independently represents a hydrogen atom, an alkyl group, an alkenyl group, an alkynyl group, —CN, —CF₃, —CₙF₂ₙ₊₁, a trifluorovinyl group, —CO₂R, —C(O)R, —NR₂, —NO₂, —OR, a halogen atom, an aryl group or a heteroaryl group, which each may further have a substituent Z; each of Rs independently represents a hydrogen atom, an alkyl group, an alkenyl group, an alkynyl group, a heteroalkyl group, an aryl group or a heteroaryl group, which each may further have a substituent Z; each of Zs independently represents a halogen atom, —R′, —OR′, —N(R′)₂, —SR′, —C(O)R′, —C(O)OR′, —C(O)N(R′)₂, —CN, —NO₂, —SO₂, —SOR′, —SO₂R′ or —SO₃R′, and each of R's independently represents a hydrogen atom, an alkyl group, a perhaloalkyl group, an alkenyl group, an alkynyl group, a heteroalkyl group, an aryl group or a heteroaryl group; (X—Y) represents an ancillary ligand; and m represents an integer from 1 to 3 and n represents an integer from 0 to 2, provided that m+n=3.

[9] The organic electroluminescence device according to any of [1] to [8],

wherein the ancillary ligand (X—Y) is any of acetylacetonate (acac), picolinate (pic), derivative of acetylacetonate (acac) and derivative of picolinate (pic).

[10] A composition containing a compound represented by the formula (1) and a compound represented by the formula (T-1), which are described in [1].
[11] A light emitting layer containing a compound represented by the formula (1) and a compound represented by the formula (T-1), which are described in [1].
[12] A film formation method,

wherein a compound represented by the formula (1) and a compound represented by the formula (T-1), which are described in [1], are made to sublime by simultaneous heating and formed into film.

[13] A light luminous apparatus containing the organic electroluminescence device according any of [1] to [9].
[14] A display apparatus containing the organic electroluminescence device according to any of [1] to [9].
[15] An illumination apparatus containing the organic electroluminescence device according to any of [1] to [9].

### ADVANTAGE OF THE INVENTION

The organic electroluminescence devices according to the invention have low power consumption, high external quantum efficiency and excellent durability. In addition, they have small shifts in chromaticity under high-temperature drive, and can therefore deliver steady performance even in uses for which drive durability in high-temperature conditions are required, such as an automobile use.

### BRIEF DESCRIPTION OF DRAWINGS

FIG. 1 is a schematic diagram showing an example of a layer structure of the organic EL device relating to a first embodiment of the invention.

FIG. 2 is a schematic diagram showing an example of light luminous apparatus relating to a second embodiment of the invention.

FIG. 3 is a schematic diagram showing an example of illumination apparatus relating to a third embodiment of the invention.

### DESCRIPTION OF EMBODIMENTS

In illustration of the following formulae (1) to (3) and the following formulae (T-1) to (T-4), the expression “hydrogen atom” is intended to also include isotopes thereof (such as a deuterium atom) and the expression “atoms”, which constitute a substituent, is intended to also include isotopes thereof.

In the invention, the expression “the number of carbon atoms” in a substituent such as an alkyl group is used in the sense that the substituent may further have other substituents and the carbon atoms contained in the other substituents are also counted as the carbon atoms of the substituent.

And the term “heteroalkyl group” refers to the alkyl group at least one carbon atom of which is replaced with O, NR or S.

The present organic electroluminescence device contains a pair of electrodes on a substrate, and a light emitting layer is sandwiched between the pair of the electrodes, and the light emitting layer contains a compound represented by the following formula (1) and a compound represented by the following formula (T-1)

The compound represented by the formula (1) is illustrated below.

(Cz)ₚ-L-(A)_{q} (1)

In the formula (1), Cz represents a substituted or unsubstituted arylcarbazolyl group or a substituted or unsubstituted carbazolylaryl group, L represents a single bond, a substituted or unsubstituted arylene group, a substituted or unsubstituted cycloalkylene group, or a group derived from a substituted or unsubstituted heteroaromatic ring, A represents a group derived from a substituted or unsubstituted nitrogen-containing heteroaromatic 6-membered ring, and each of p and q independently represents an integer from 1 to 6.

The formula (1) is explained below in detail.

Cz represents a substituted or unsubstituted arylcarbazolyl group or a substituted or unsubstituted carbazolylaryl group.

The aryl group in each of the arylcarbazolyl group and the carbazolylaryl group is preferably from 6 to 30 in the number of carbons, with examples including a phenyl group, a naphthyl group, an anthryl group, a phenanthryl group, a naphthacenyl group, a pyrenyl group, a fluorenyl group, a biphenyl group and a terphenyl group. Of these groups, a phenyl group, a naphthyl group, a biphenyl group and a terphenyl group are preferable, a phenyl group and a biphenyl group are especially preferable.

The aryl group in each of the arylcarbazolyl group and the carbazolylaryl group is not particularly restricted as to its substitution position on the carbazole ring, but in terms of chemical stability and carrier-transporting capability, it is preferable that the aryl group substitutes for the hydrogen on the 2-position, 3-position, 6-position, 7-position or 9-position of the carbazole ring, it is more preferable that the aryl group substitutes for the hydrogen on the 3-position, 6-position and 9-position of the carbazole ring and it is the most preferable that the aryl group substitutes for the hydrogen on the 9-position (N-position) of the carbazole ring.

When Cz represents an arylcarbazolyl group, though there is no particular restriction on the Cz-L linking, the arylcarbazolyl group is preferably linked to L at the 2-position, 3-position, 6-position, 7-position or 9-position (N-position) of the carbazole ring, far preferably linked to the L at the 3-position, 6-position, or 9-position (N-position) of the carbazole, ring, especially preferably linked to the L at the 9-position (N-position) of the carbazole ring.

However, it is preferable that Cz is a carbazolylaryl group.

A represents a group derived from a substituted or unsubstituted nitrogen-containing heteroaromatic 6-membered ring, preferably a group derived from a nitrogen-containing heteroaromatic 6-membered ring in which the number of carbons is from 2 to 40. The group represented by A may have two or more substituents, and these substituents may combine with each other and form a ring or rings.

Examples of a nitrogen-containing heteroaromatic 6-membered ring or a nitrogen-containing heteroaromatic ring having a nitrogen-containing heteroaromatic 6-membered ring include pyridine, pyrimidine, pyrazine, pyridazine, triazine, azaindolizine, indolizine, purine, pteridine, β-carboline, naphthyridine, quinoxaline, terpyridine, bipyridine, acridine, phenanthroline, phenazine and imidazopyridine. Of these rings, pyridine, pyrimidine, pyrazine and triazine are preferable, pyridine and pyrimidine are far preferable, and pyrimidine is the most preferable.

L represents a single bond, a substituted or unsubstituted arylene group, a substituted or unsubstituted cycloalkylene group, or a group derived from a substituted or unsubstituted heteroaromatic ring.

The arylene group is preferably an arylene group in which the number of carbon atoms is from 6 to 30, with examples including a phenylene group, a biphenylene group, a terphenylene group, a naphthylene group, an anthranylene group, a phenanthrylene group, a pyrenylene group, a chrysenylene group, a fluoranthenylene group and a perfluoroarylene group. Of these groups, a phenylene group, a biphenylene group, a terphenylene group and a perfluoroarylene group are preferable to the others, a phenylene group, a biphenylene group and a terphenylene group are far preferable, and a phenylene group and a biphenylene group are further preferable.

The cycloalkylene group is preferably a cycloalkylene group in which the number of carbon atoms is from 5 to 30, with examples including a cyclopentylene group, a cyclohexylene group and a cycloheptylene group. Of such groups, a cyclopentylene group and a cyclohexylene group are preferable to the others, and a cyclohexylene group is far preferable.

The group derived from a heteroaromatic ring is preferably a group derived from a heteroaromatic ring in which the number of carbon atoms is from 2 to 30, with examples including groups derived respectively from a 1-pyrrolyl group, a 2-pyrrolyl group, a 3-pyrrolyl group, a pyrazinyl group, a 2-pyridinyl group, a 3-pyridinyl group, a 4-pyridinyl group, a 1-indolyl group, a 2-indolyl group, a 3-indolyl group, a 4-indolyl group, a 5-indolyl group, a 6-indolyl group, a 7-indolyl group, a 1-isoindolyl group, a 2-isoindolyl group, a 3-isoindolyl group, a 4-isoindolyl group, a 5-isoindolyl group, a 6-isoindolyl group, a 7-isoindolyl group, a 2-furyl group, a 3-furyl group, a 2-benzofuranyl group, a 3-benzofuranyl group, a 4-benzofuranyl group, a 5-benzofuranyl group, a 6-benzofuranyl group, a 7-benzofuranyl group, a 1-isobenzofuranyl group, a 3-isobenzofuranyl group, a 4-isobenzofuranyl group, a 5-isobenzofuranyl group, a 6-isobenzofuranyl group, a 7-isobenzofuranyl group, a 2-quinolyl group, a 3-quinolyl group, a 4-quinolyl group, a 5-quinolyl group, a 6-quinolyl group, a 7-quinolyl group, an 8-quinolyl group, a 1-isoquinolyl group, a 3-isoquinolyl group, a 4-isoquinolyl group, a 5-isoquinolyl group, a 6-isoquinolyl group, a 7-isoquinolyl group, an 8-isoquinolyl group, a 2-quinoxalinyl group, a 5-quinoxalinyl group, a 6-quinoxalinyl group, a 1-carbazolyl group, a 2-carbazolyl group, a 3-carbazolyl group, a 4-carbazolyl group, a 9-carbazolyl group, a 1-phenanthridinyl group, a 2-phenanthridinyl group, a 3-phenanthridinyl group, a 4-phenanthridinyl group, a 6-phenanthridinyl group, a 7-phenanthridinyl group, an 8-phenanthridinyl group, a 9-phenanthridinyl group, a 10-phenanthridinyl group, a 1-acridinyl group, a 2-acridinyl group, a 3-acridinyl group, a 4-acridinyl group, a 9-acridinyl group, a 1,7-phenanthroline-2-yl group, a 1,7-phenanthroline-3-yl group, a 1,7-phenanthroline-4-yl group, a 1,7-phenanthroline-5-yl group, a 1,7-phenanthroline-6-yl group, a 1,7-phenanthroline-8-yl group, a 1,7-phenanthroline-9-yl group, a 1,7-phenanthroline-10-yl group, a 1,8-phenanthroline-2-yl group, a 1,8-phenanthroline-3-yl group, a 1,8-phenanthroline-4-yl group, a 1,8-phenanthroline-5-yl group, a 1,8-phenanthroline-6-yl group, a 1,8-phenanthroline-7-yl group, a 1,8-phenanthroline-9-yl group, a 1,8-phenanthroline-10-yl group, a 1,9-phenanthroline-2-yl group, a 1,9-phenanthroline-3-yl group, a 1,9-phenanthroline-4-yl group, a 1,9-phenanthroline-5-yl group, a 1,9-phenanthroline-6-yl group, a 1,9-phenanthroline-7-yl group, a 1,9-phenanthroline-8-yl group, a 1,9-phenanthroline-10-yl group, a 1,10-phenanthroline-2-yl group, a 1,10-phenanthroline-3-yl group, a 1,10-phenanthroline-4-yl group, a 1,10-phenanthroline-5-yl group, a 2,9-phenanthroline-1-yl group, a 2,9-phenanthroline-3-yl group, a 2,9-phenanthroline-4-yl group, a 2,9-phenanthroline-5-yl group, a 2,9-phenanthroline-6-yl group, a 2,9-phenanthroline-7-yl group, a 2,9-phenanthroline-8-yl group, a 2,9-phenanthroline-10-yl group, a 2,8-phenanthroline-1-yl group, a 2,8-phenanthroline-3-yl group, a 2,8-phenanthroline-4-yl group, a 2,8-phenanthroline-5-yl group, a 2,8-phenanthroline-6-yl group, a 2,8-phenanthroline-7-yl group, a 2,8-phenanthroline-9-yl group, a 2,8-phenanthroline-10-yl group, a 2,7-phenanthroline-1-yl group, a 2,7-phenanthroline-3-yl group, a 2,7-phenanthroline-4-yl group, a 2,7-phenanthroline-5-yl group, a 2,7-phenanthroline-6-yl group, a 2,7-phenanthroline-8-yl group, a 2,7-phenanthroline-9-yl group, a 2,7-phenanthroline-10-yl group, a 1-phenazinyl group, a 2-phenazinyl group, a 1-phenothiazinyl group, a 2-phenothiazinyl group, a 3-phenothiazinyl group, a 4-phenothiazinyl group, a 10-phenothiazinyl group, a 1-phenoxazinyl group, a 2-phenoxazinyl group, a 3-phenoxazinyl group, a 4-phenoxazinyl group, a 10-phenoxazinyl group, a 2-oxazolyl group, a 4-oxazolyl group, a 5-oxazolyl group, a 2-oxadiazolyl group, a 5-oxadiazolyl group, a 3-furazanyl group, a 2-thienyl group, a 3-thienyl group, a 2-methylpyrrole-1-yl group, a 2-methylpyrrole-3-yl group, a 2-methylpyrrole-4-yl group, a 2-methylpyrrole-5-yl group, a 3-methylpyrrole-1-yl group, a 3-methylpyrrole-2-yl group, a 3-methylpyrrole-4-yl group, a 3-methylpyrrole-5-yl group, a 2-t-butylpyrrole-4-yl group, 3-(2-phenylpropyl)pyrrole-1-yl group, a 2-methyl-1-indolyl group, a 4-methyl-1-indolyl group, a 2-methyl-3-indolyl group, a 4-methyl-3-indolyl group, a 2-t-butyl-1-indolyl group, a 4-t-butyl-1-indolyl group, a 2-t-butyl-3-indolyl group and a 4-t-butyl-3-indolyl group. Of these groups, the groups derived respectively from a pyridinyl group, a quinolyl group, an indolyl group and a carbazolyl group are preferable to the others, and the groups derived respectively from a pyridinyl group and a carbazolyl group are far preferable.

L stands for preferably a single bond, a phenylene group, a biphenylene group, a cyclohexylene group, a pyridnylene group or a carbazolylene group, far preferably a single bond, a phenylene group or a biphenylene group, and further preferably a single bond or a phenylene group.

Examples of a substituent each of the groups represented by Cz and A in the formula (1) can include halogen atoms such as fluorine, chlorine, bromine and iodine, a carbazolyl group, a hydroxyl group, substituted or unsubstituted amino groups, a nitro group, a cyano group, a silyl group, a trifluoromethyl group, a carbonyl group, a carboxyl group, substituted or unsubstituted alkyl groups, substituted or unsubstituted alkenyl groups, substituted or unsubstituted arylalkyl groups, substituted or unsubstituted aryl groups, substituted or unsubstituted aromatic heterocyclic groups, substituted or unsubstituted aryloxy groups, and substituted or unsubstituted alkyloxy groups. Of these substituents, a fluorine atom, a methyl group, a perfluorophenylene group, a phenyl group, a naphthyl group, a pyridyl group, a pyrazyl group, a pyrimidyl group, an adamantyl group, a benzyl group, a nitro group, a cyano group, a silyl group, a trifluoromethyl group, a carbazolyl group and combinations of only these groups are preferable, a fluorine atom, a methyl group, a phenyl group, a pyridyl group, a pyrimidyl group, a cyano group, a silyl group, a carbazolyl group and combinations of only these groups are far preferable, a phenyl group, a pyridyl group, a pyrimidyl group, a carbazolyl group and combinations of only these groups are further preferable, and a phenyl group is the best. When the group represented by Cz or A has two or more substituents, these substituents may combine with each other and form a ring or rings.

Each of p and q in the formula (1) independently represents an integer from 1 to 6, preferably 1 to 4, far preferably 1 to 3, and further preferably 1 or 2.

The compound represented by the formula (1) is preferably a compound represented by the following formula (2).

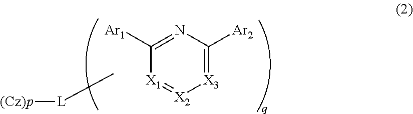

In the formula (2), Cz represents a substituted or unsubstituted arylcarbazolyl group or a substituted or unsubstituted carbazolylaryl group; L represents a single bond, a substituted or unsubstituted arylene group, a substituted or unsubstituted cycloalkylene group, or a group derived from a substituted or unsubstituted heteroaromatic ring, and L is linked to the carbon atom in Ar₁, Ar₂, X₁, X₂ or X₃; each of Ar₁ and Ar₂ independently represents a substituted or unsubstituted aryl group, a substituted or unsubstituted arylene group, or a group derived from a substituted or unsubstituted heteroaromatic ring; each of X₁, X₂ and X₃ independently represents a nitrogen atom or a carbon atom which may have a substituent; and each of p and q independently represents an integer from 1 to 6.

The formula (2) is explained below in detail.

Definitions of Cz, L, p and q in the formula (2) are the same as those in the formula (1), respectively, and preferable examples of Cz, L, p and q in the formula (2) are also the same as those in the formula (1).

Each of Ar₁ and Ar₂ independently represents a substituted or unsubstituted aryl group, a substituted or unsubstituted arylene group, or a group derived from a substituted or unsubstituted heteroaromatic ring.

The aryl group is preferably a substituted or unsubstituted aryl group in which the number of carbon atoms is from 6 to 30, with examples including a phenyl group, a biphenyl group, a terphenyl group, a naphthyl group, an anthranyl group, a phenanthryl group, a pyrenyl group, a chrysenyl group, a fluoranthenyl group and a perfluoroaryl group. Of these groups, a phenyl group, a biphenyl group, a terphenyl group and a perfluoroaryl group are preferably, a phenyl group, a biphenyl group and a terphenyl group are far preferable, and a phenyl group and a biphenyl group are further preferable.

The arylene group is preferably an arylene group in which the number of carbon atoms is from 6 to 30, and examples thereof and groups for which the arylene group has preferences are the same as those recited in the explanation of L in the formula (1). And the group derived from a heteroaromatic ring is preferably a heteroaromatic ring which is substituted or unsubstituted group and the number of carbon atoms is from 2 to 30, and examples thereof and groups for which the group has preferences are the same as those recited in the explanation of L in the formula (1). When substituents are attached to those groups, examples of the substituents and groups preferred as the substituents are the same as those recited as the substituents of Cz and A in the formula (1).

Each of the ring members X₁, X₂ and X₃ independently represents a nitrogen atom or a carbon atom which may have a substituent. Cases where at most two of X₁, X₂ and X₃ are nitrogen atoms are preferable, cases where none or one of X₁, X₂ and X₃ is a nitrogen atom are far preferable, and cases where any one of X₁, X₂ and X₃ is a nitrogen atom are the most preferable. When any one of X₁, X₂ and X₃ is a nitrogen atom, it is preferred that either of X₁ and X₃ be a nitrogen atom. The ring containing X₁ to X₃ in the formula (2) is preferably pyridine or pyrimidine, far preferably pyrimidine. Examples of a substituent which can be bonded to the carbon atom and groups preferred as the substituent are the same as those recited as the substituents of Cz and A in the formula (1). Additionally, the linking position of L in the formula (2) has no particular restriction but, in terms of chemical stability and carrier-transporting capability, it is preferred that L be linked to a Carbon atom in Ar₁.

The compound represented by the formula (1) is far preferably a compound represented by the following formula (3).

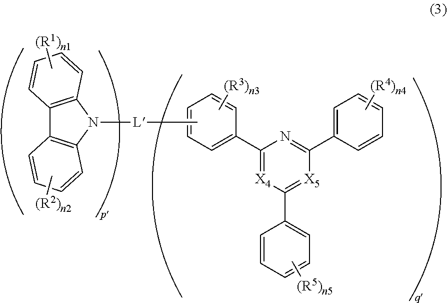

In the formula (3), each of X₄ and X₅ independently represents a nitrogen atom or a carbon atom which may have a substituent, it is preferable that either X₄ or X₅ represents a nitrogen atom and the other represents a carbon atom which may have a substituent; L′ represents a single bond, a substituted or unsubstituted arylene group, a substituted or unsubstituted cycloalkylene group, or a group derived from a substituted or unsubstituted heteroaromatic ring; each of R¹ to R⁵ independently represents a substituent; each of n1 to n5 independently represents an integer from 0 to 5; and each of p′ and q′ independently represents an integer from 1 to 4.

The formula (3) is explained below in detail.

Each of X₄ and X₅ independently represents a nitrogen atom or a carbon atom which may have a substituent. Herein, it is preferable that either X₄ or X₅ represents a nitrogen atom and the other represents a carbon atom which may have a substituent.

In the formula (3), the ring containing X₄ and X₅ is preferably pyridine or pyrimidine, far preferably pyrimidine. Examples of a substituent bonded to the carbon atom and groups preferred as the substituent are the same as those recited as the substituents of Cz and A in the formula (1).

The definition of L′ in the formula (3) is the same as that of L in the formula (1), and groups preferred as L′ are the same as those preferred as L. And L′ is linked to a benzene ring in the nitrogen-containing heteroaromatic ring structure drawn in the formula (3).

Each of R¹ to R⁵ independently represents a substituent. Examples of the substituent and preferred substituent are the same as those recited as the substituents of Cz and A in the formula (1). When more than one R¹, R², R³, R⁴ or R⁵ are present, each R¹, R², R³, R⁴ or R⁵ may be the same as or different from every other R′, R², R³, R⁴ or R⁵, respectively.

Each of n1 to n5 independently represents an integer from 0 to 5. And each is preferably 0, 1 or 2, far preferably 0 or 1, further preferably 0.

Each of p′ and q′ independently represents an integer from 1 to 4. And each is preferably 1, 2 or 3, far preferably 1 or 2.

The compound represented by the formula (1) is most preferably composed only of a carbon atom, a hydrogen atom, and a nitrogen atom.

The molecular weight of the compound represented by the formula (1) is preferably from 400 to 1,000, far preferably from 450 to 800, and further preferably from 500 to 700.

The lowest triplet excited state (T1) energy that the compound represented by the formula (1) has in the form of film is preferably from 2.61 eV (62 kcal/mol) to 3.51 eV (80 kcal/mol), far preferably from 2.69 eV (63.5 kcal/mol) to 3.51 eV (80 kcal/mol), further preferably from 2.76 eV (65 kcal/mol) to 3.51 eV (80 kcal/mol).

The glass transition temperature (Tg) of the compound represented by the formula (1) is preferably from 80° C. to 400° C., far preferably from 100° C. to 400° C., further preferably from 120° C. to 400° C.

Hydrogen atoms in the formula (1) may also include isotopic atoms of hydrogen (such as deuterium atoms). In such a case, the compound may be in a state that all the hydrogen atoms are replaced with isotopic atoms of hydrogen, or it may be a mixture of the compounds that have differing degrees of partial replacement of hydrogen atoms with isotopic atoms of hydrogen.

Examples of the compound represented by the formula (1) are illustrated below, but the invention should not be construed as being limited to these examples. Additionally, Ph in the following examples represents a phenyl group.

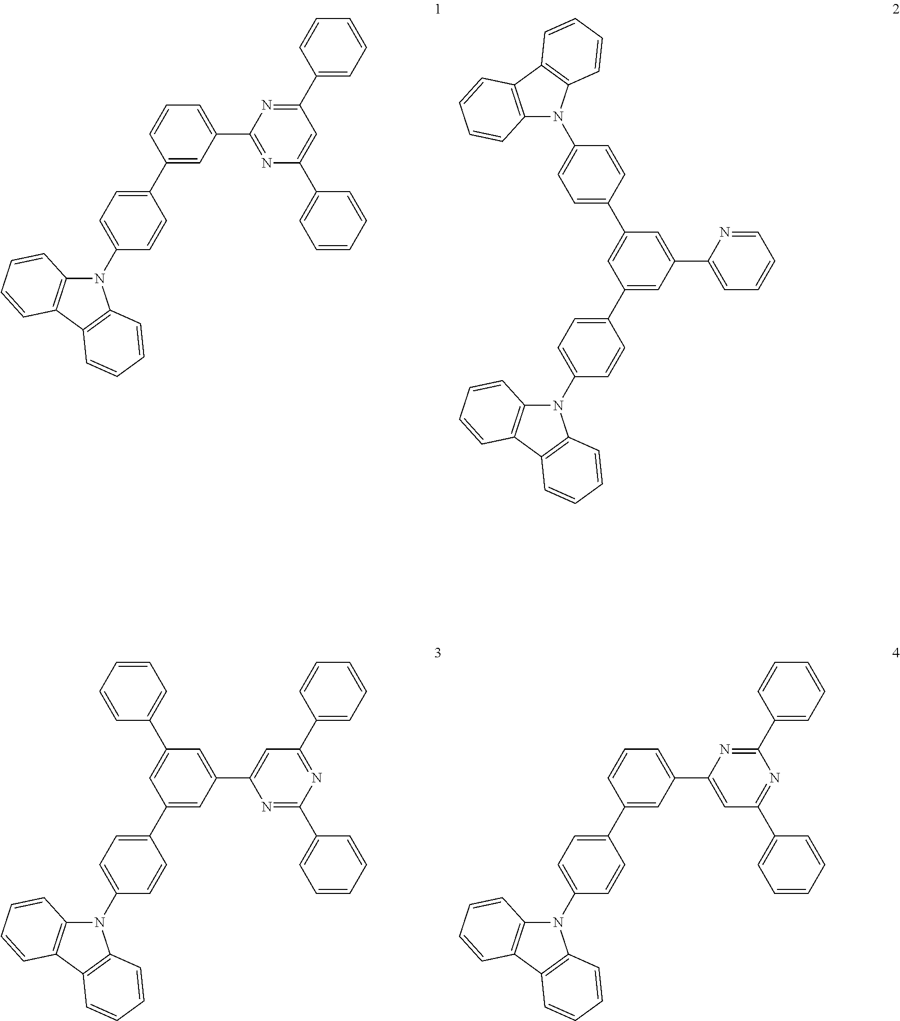

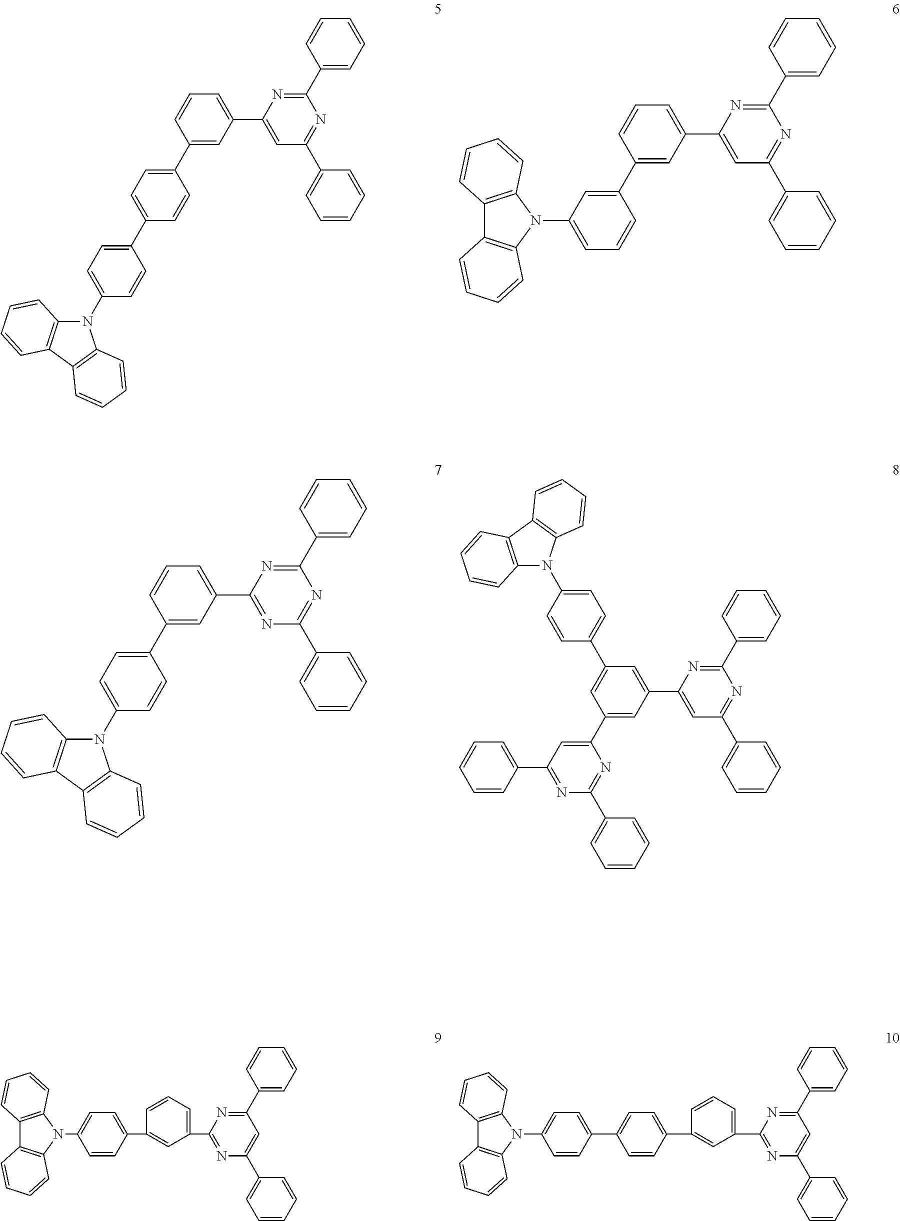

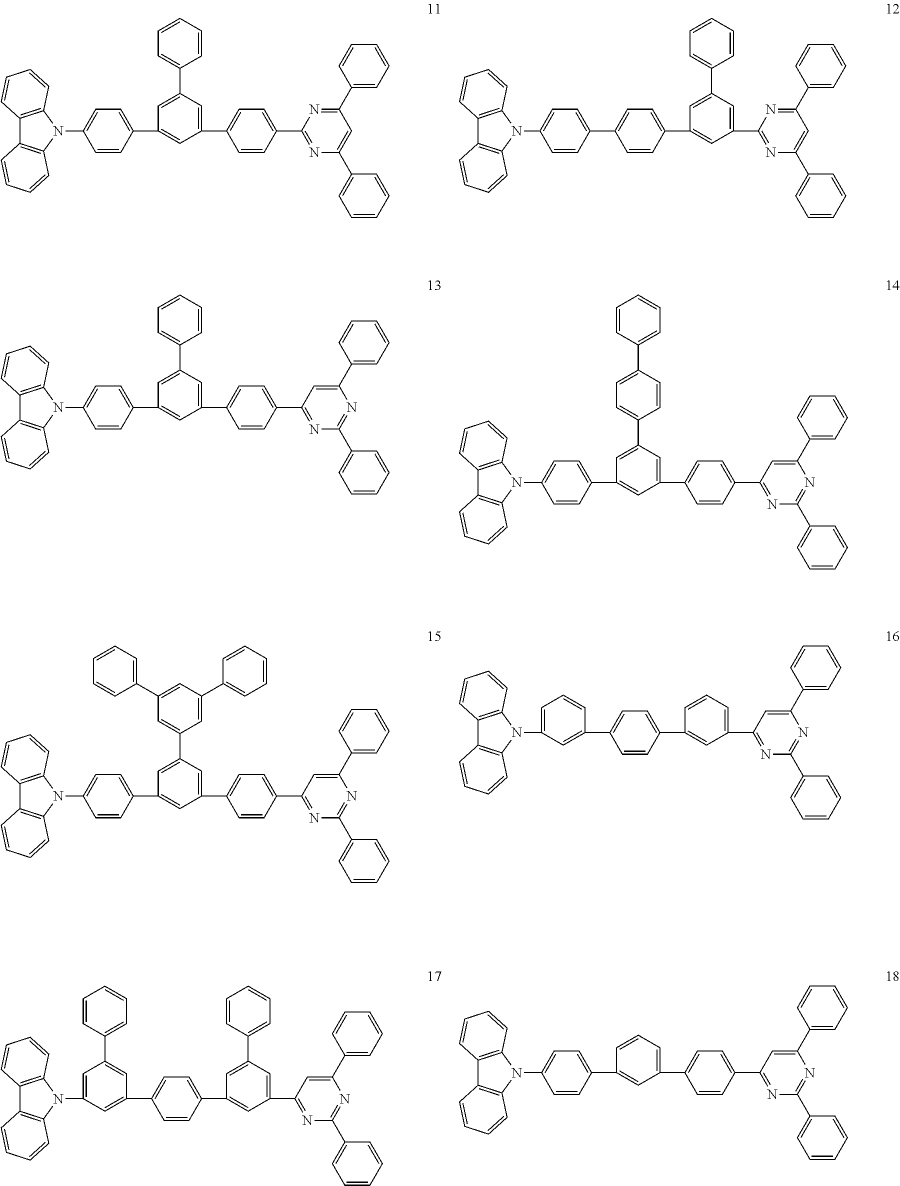

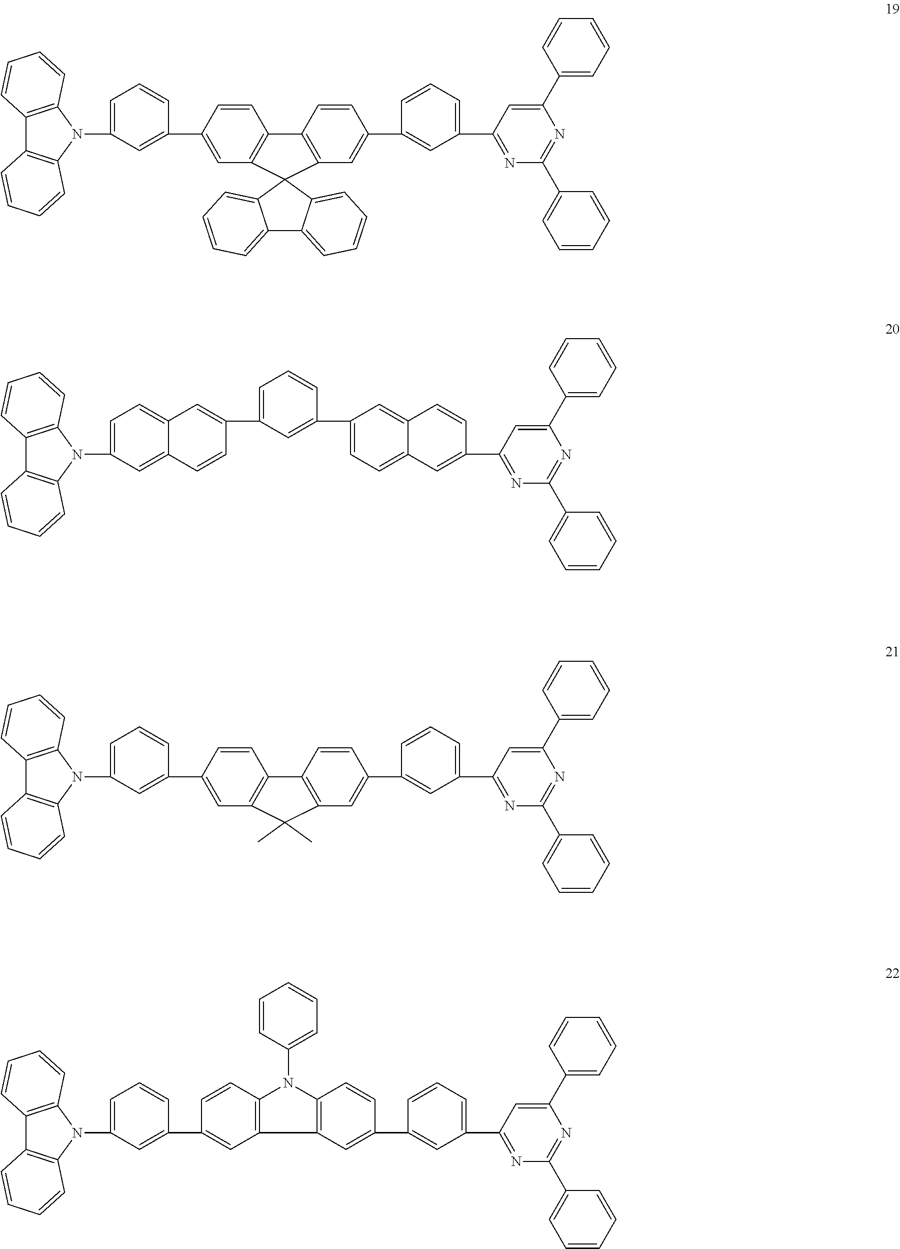

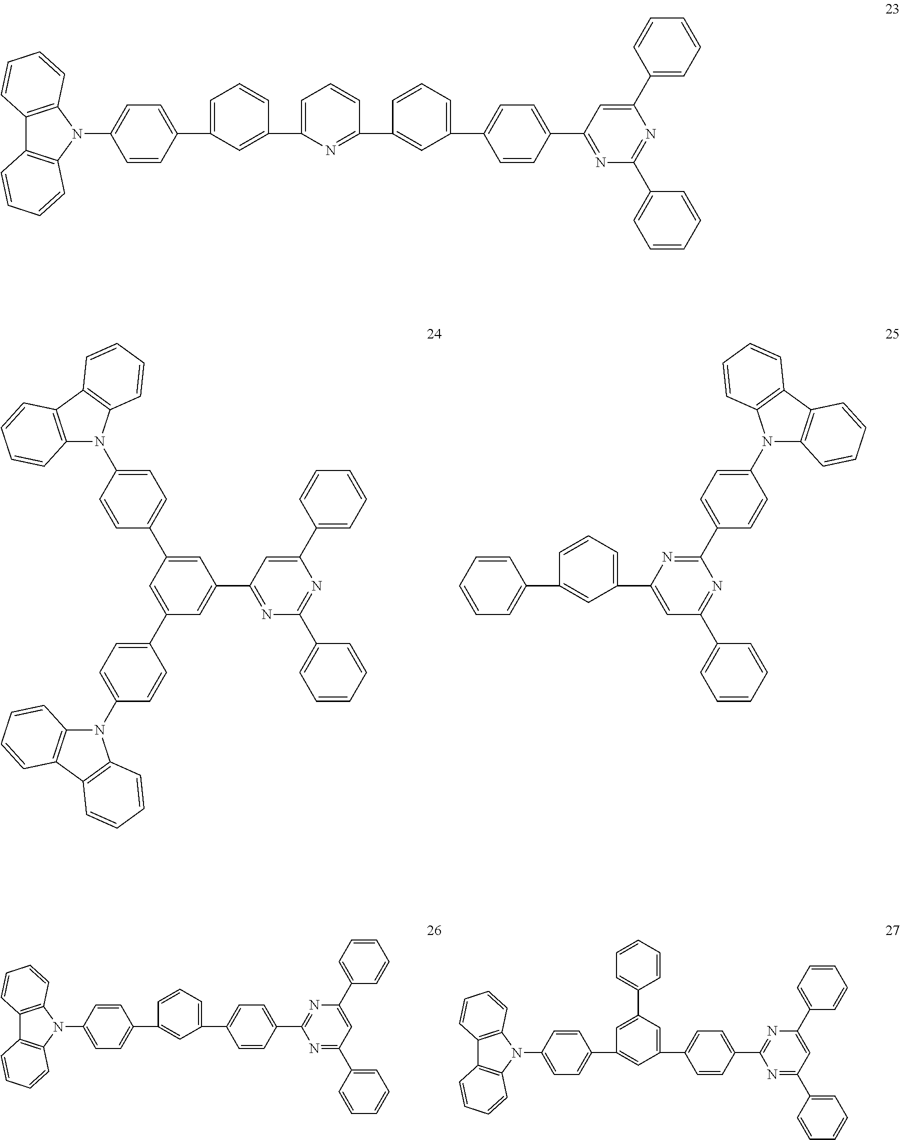

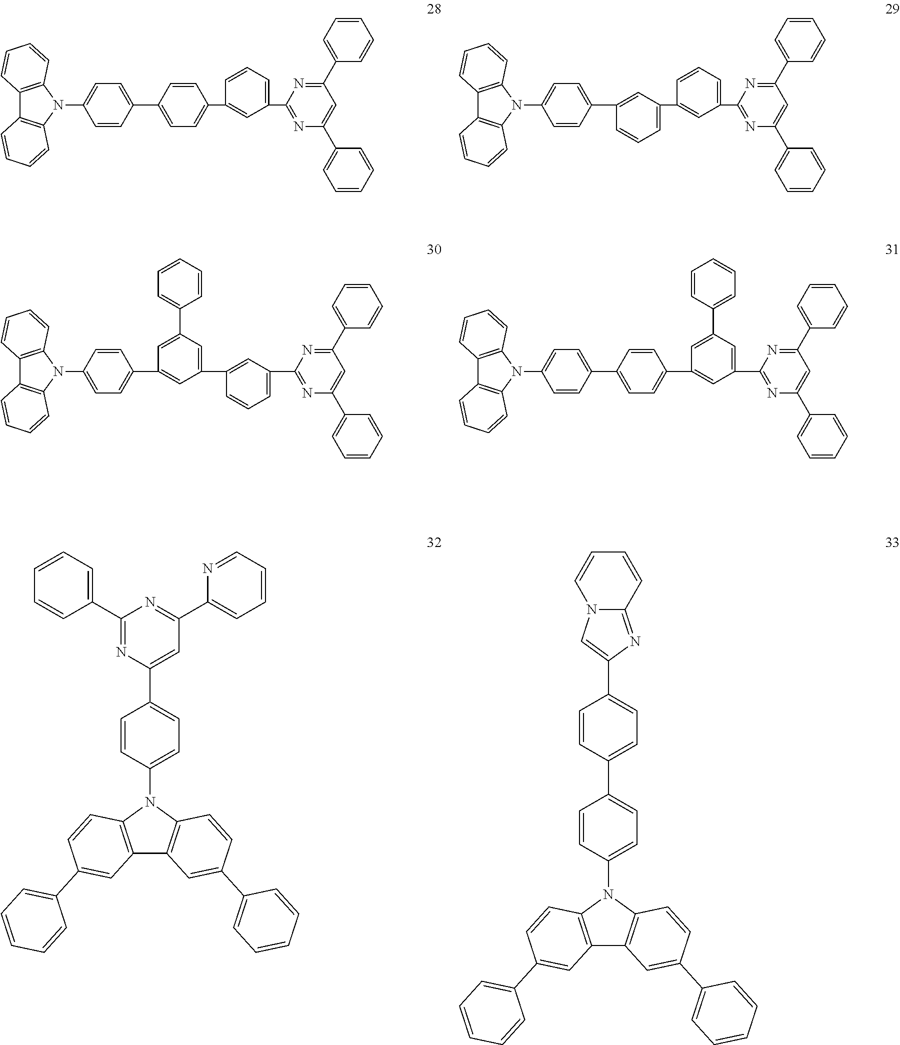

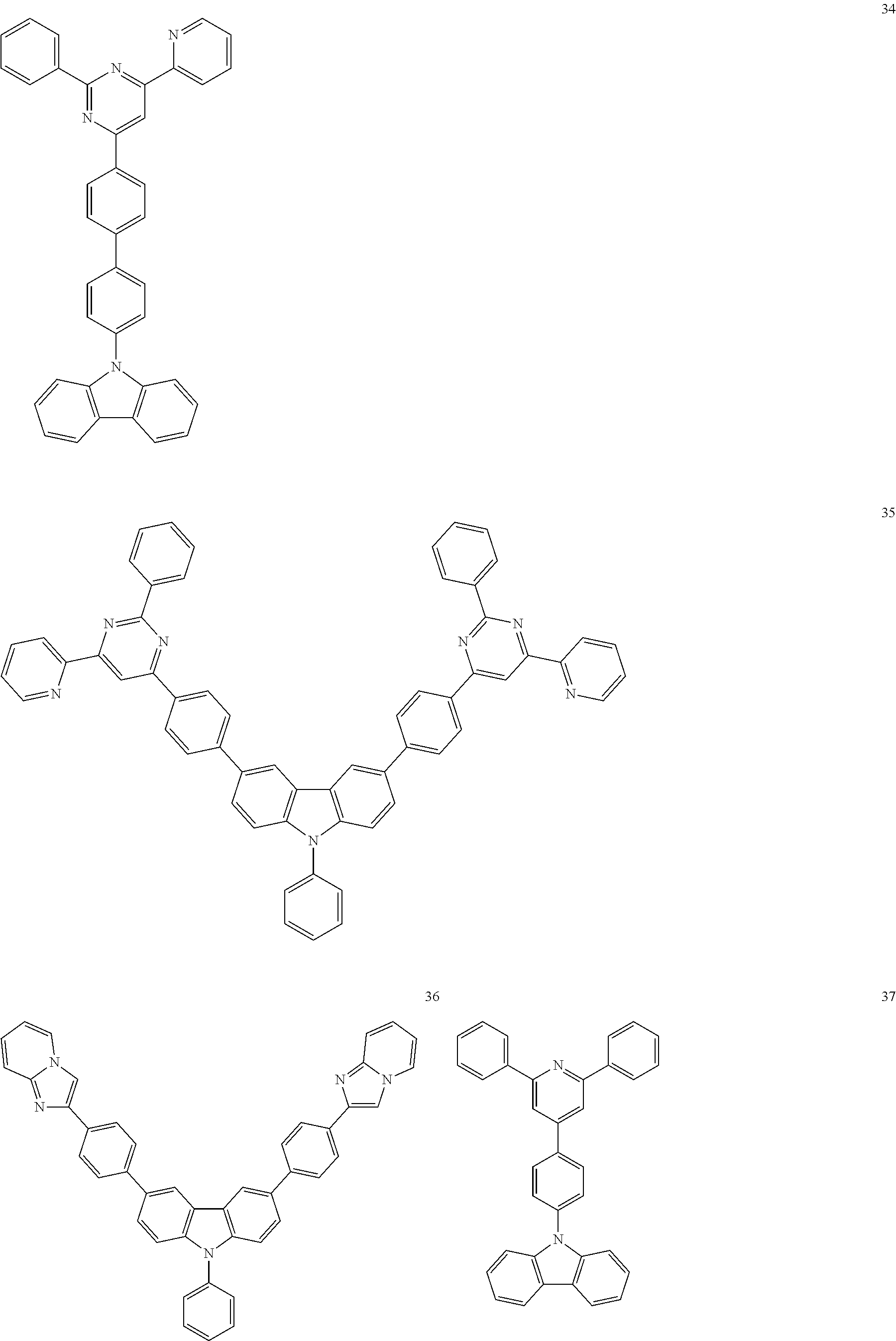

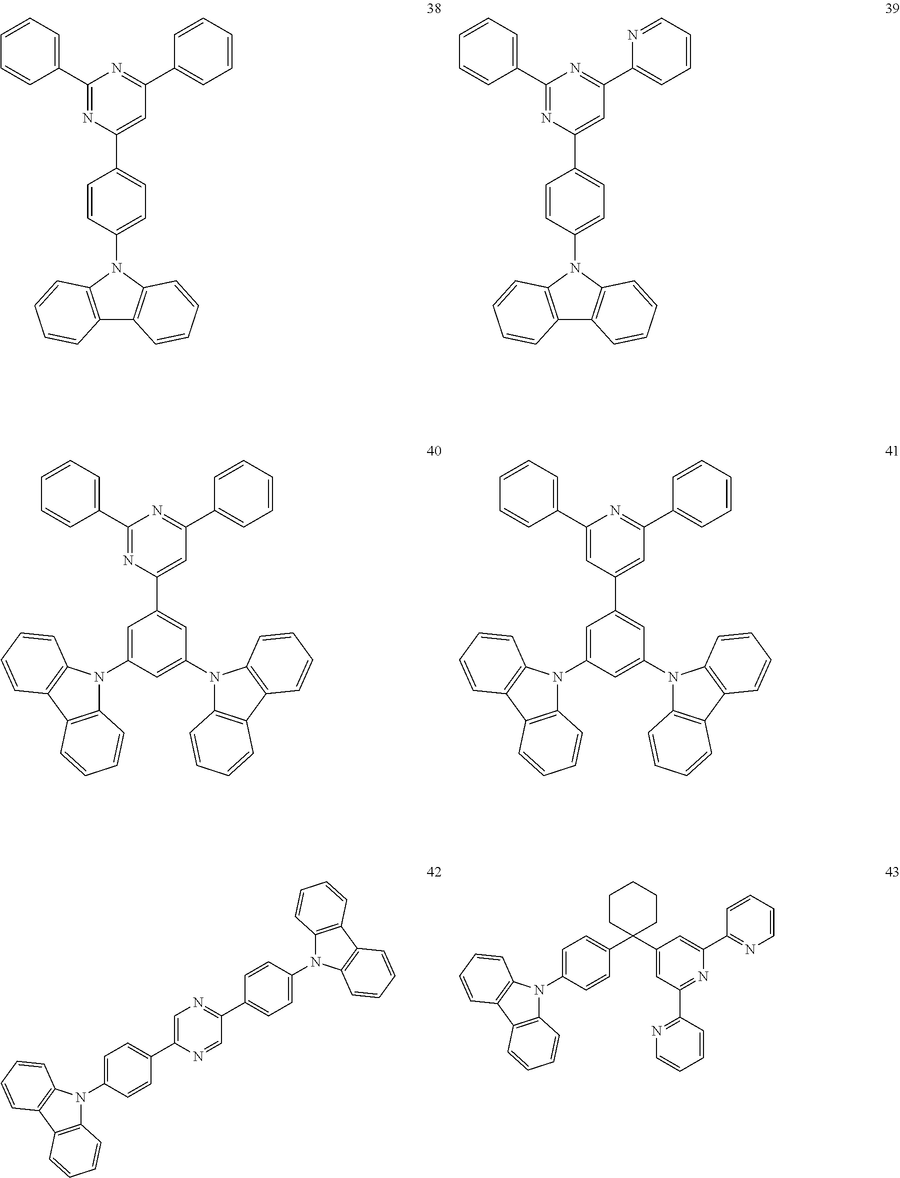

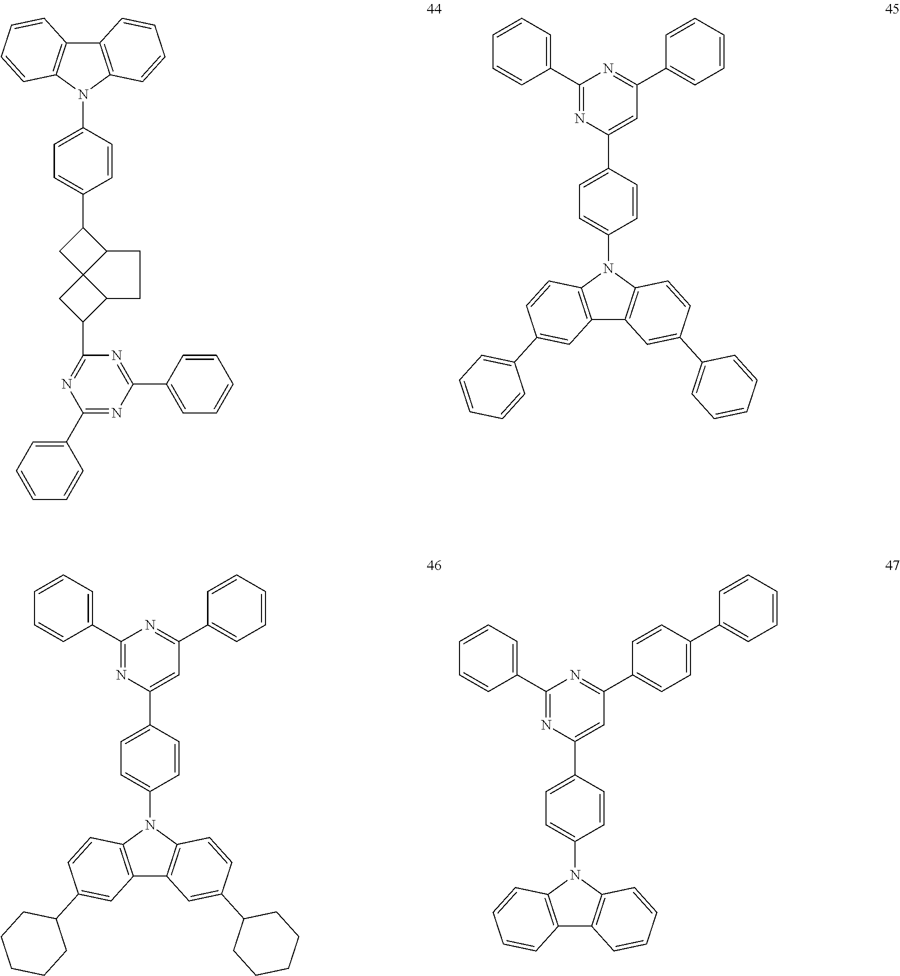

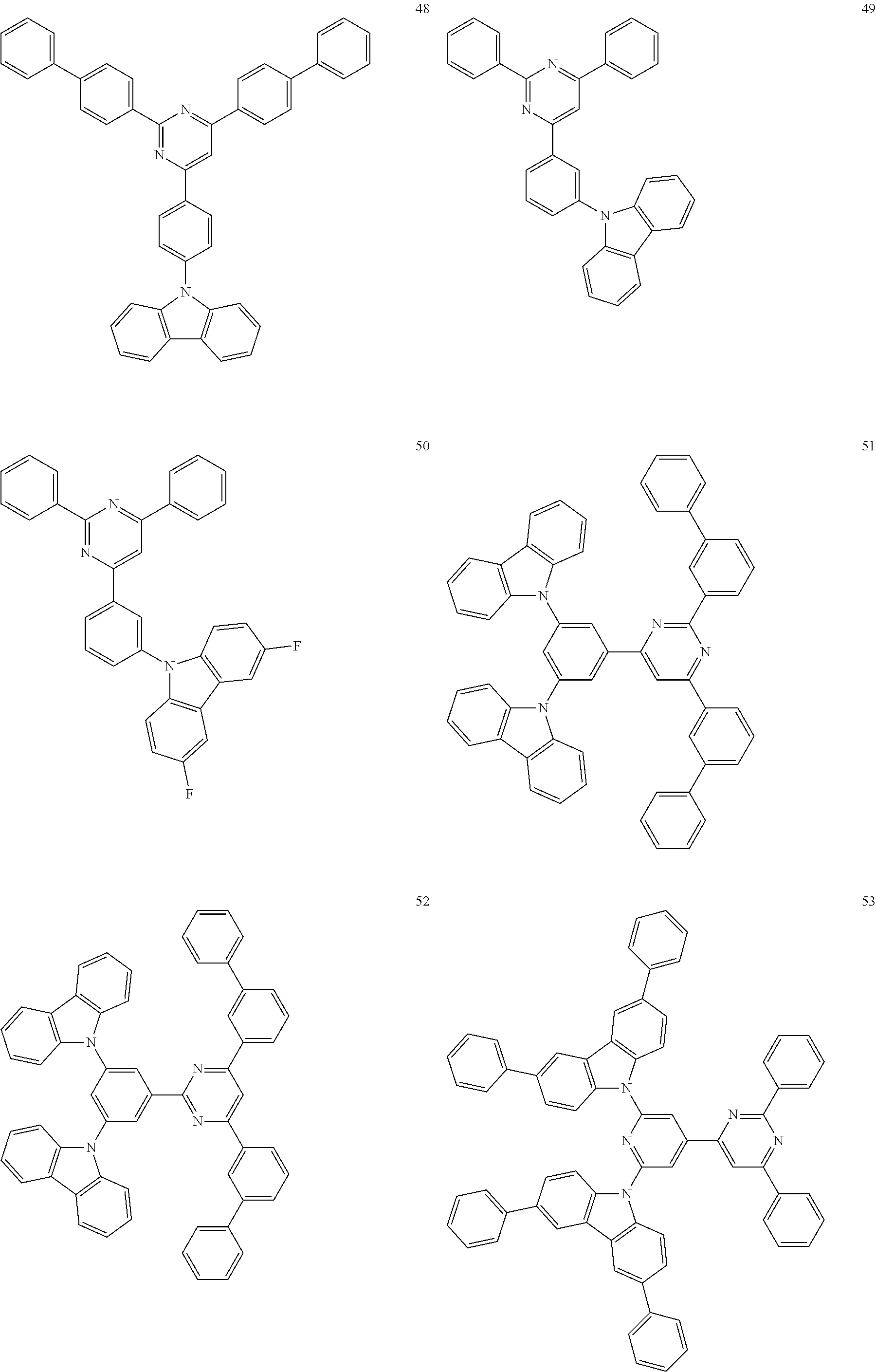

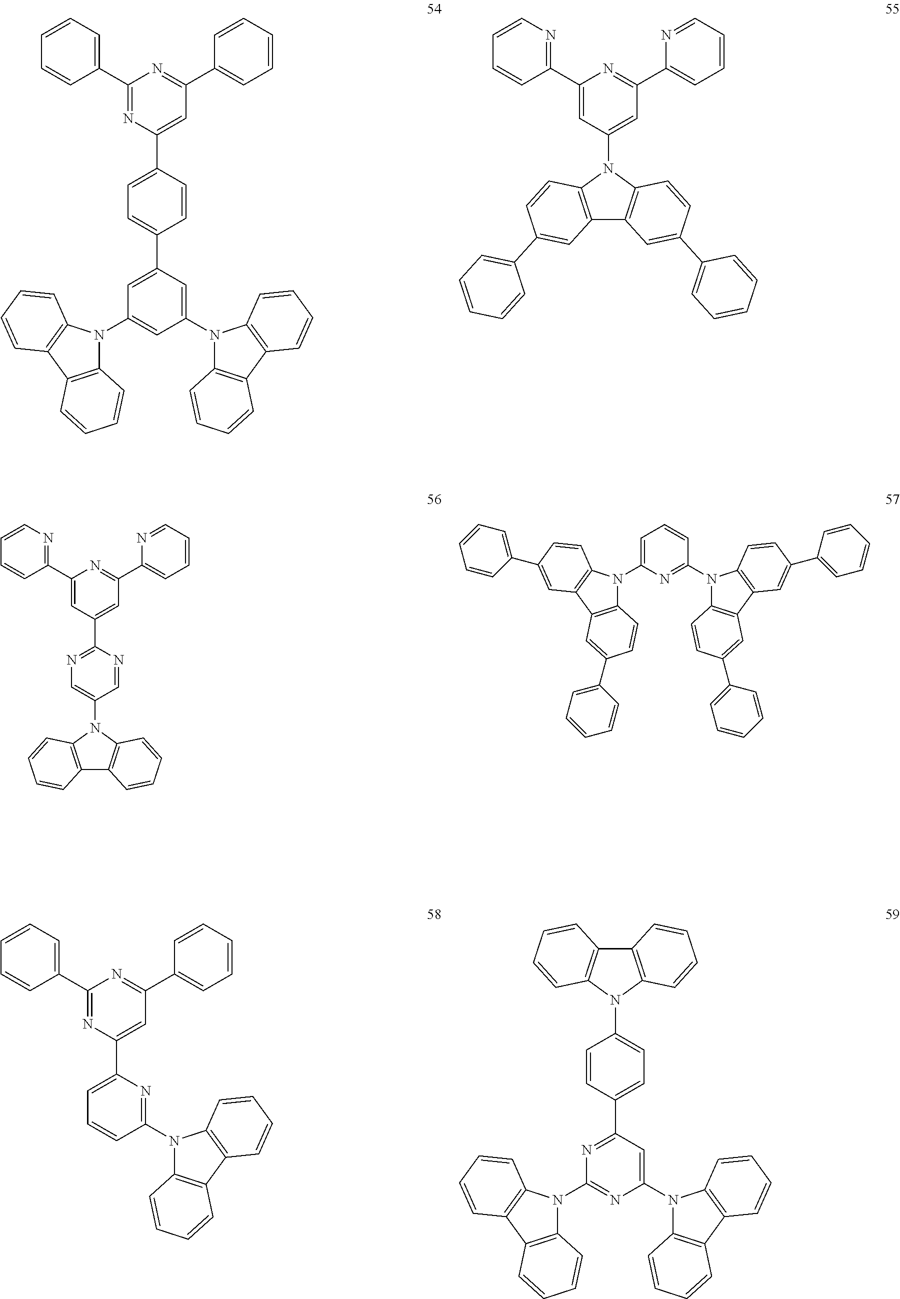

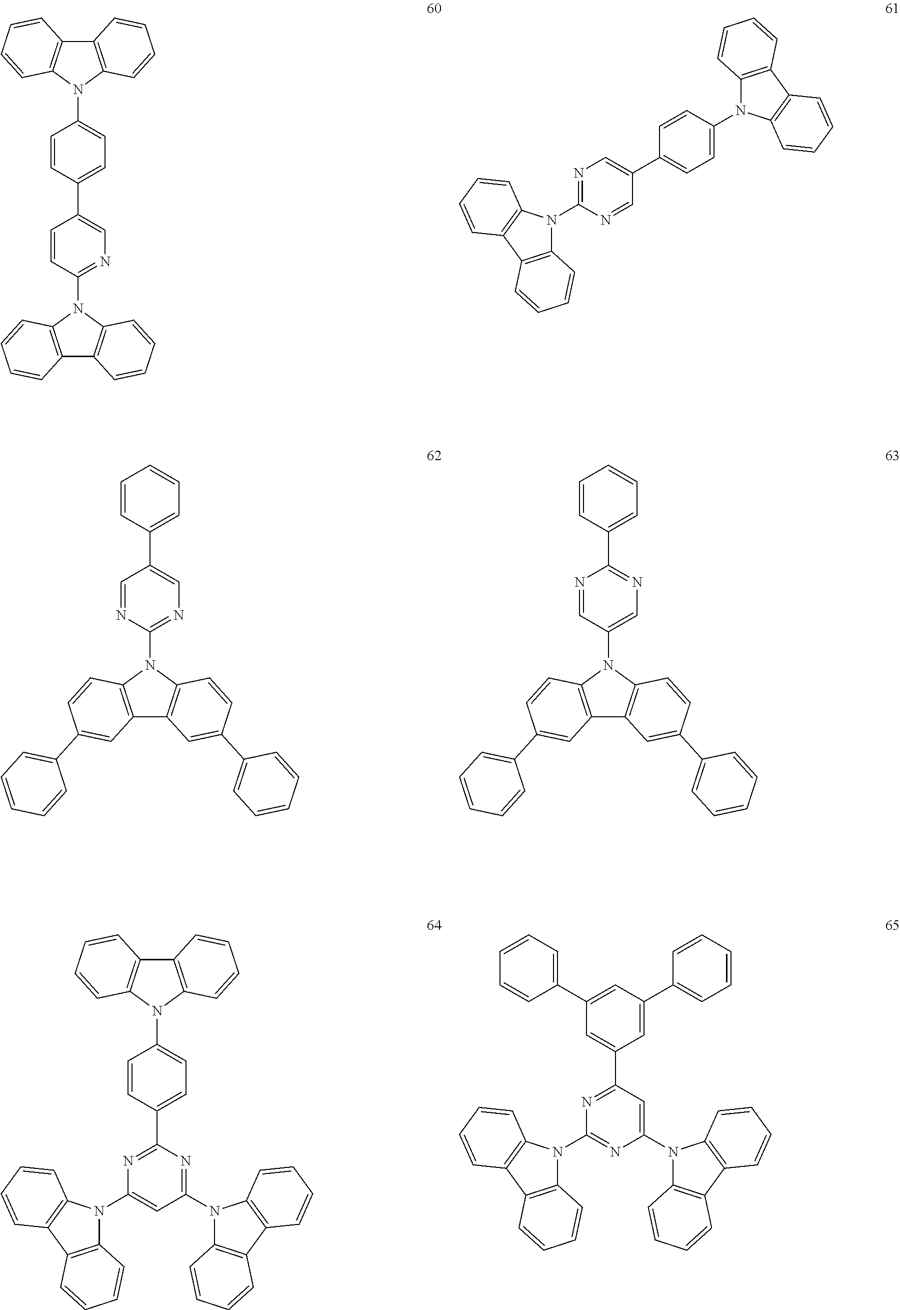

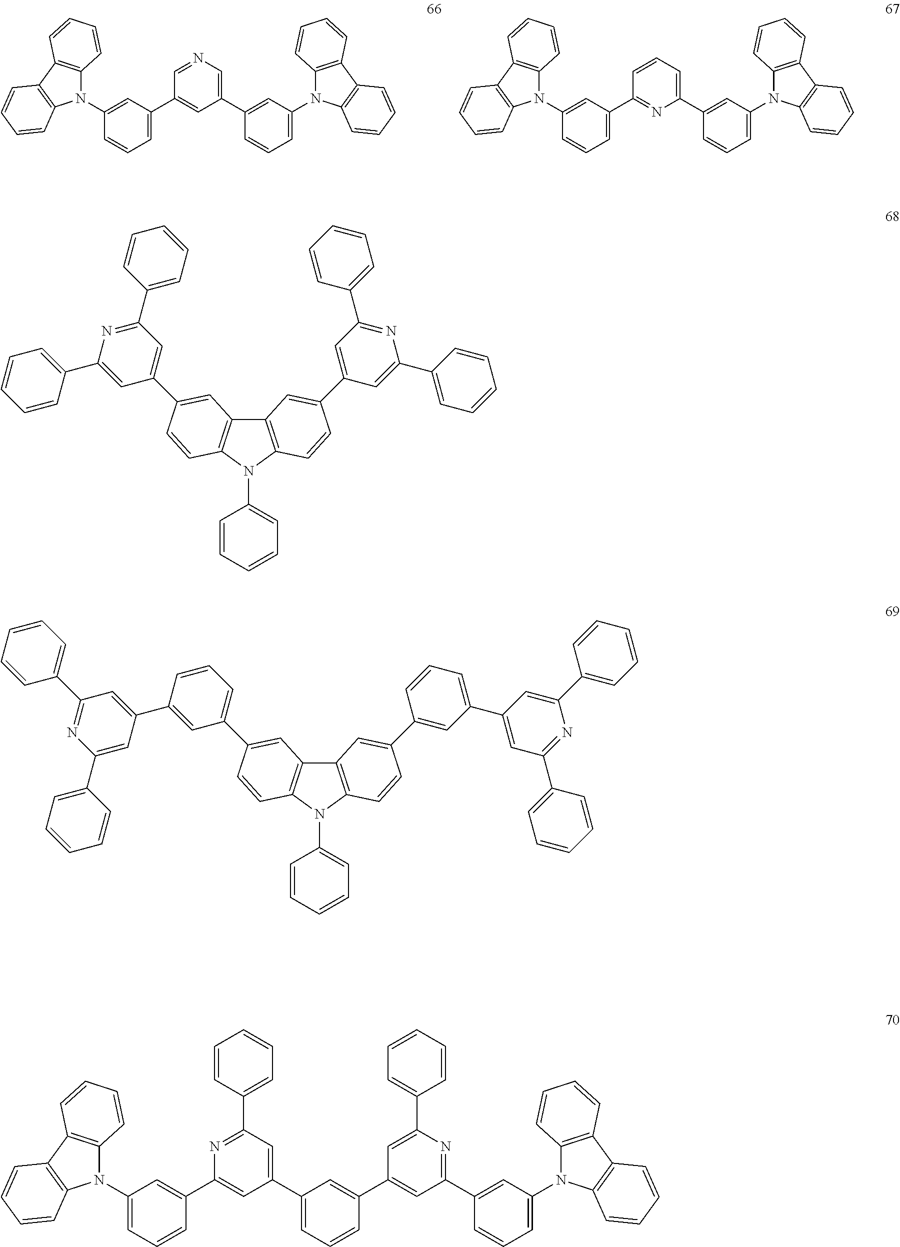

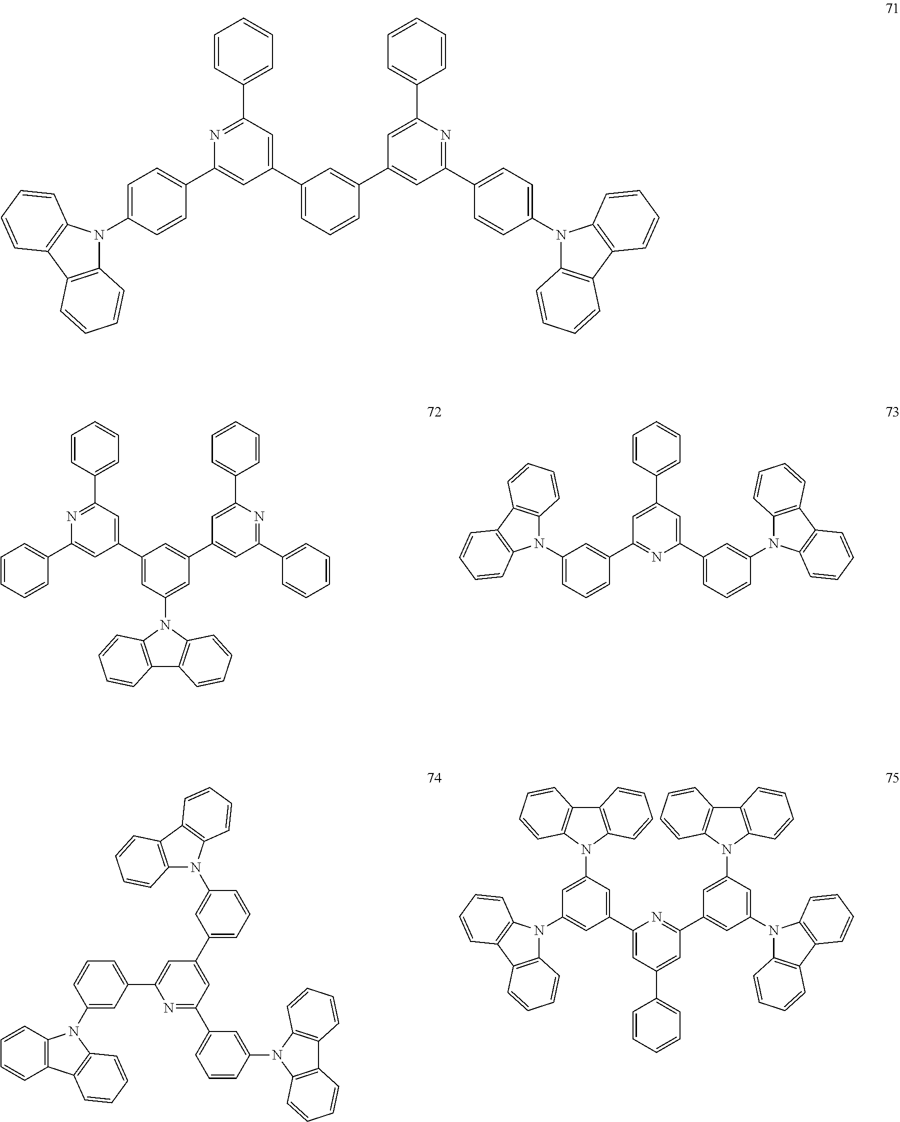

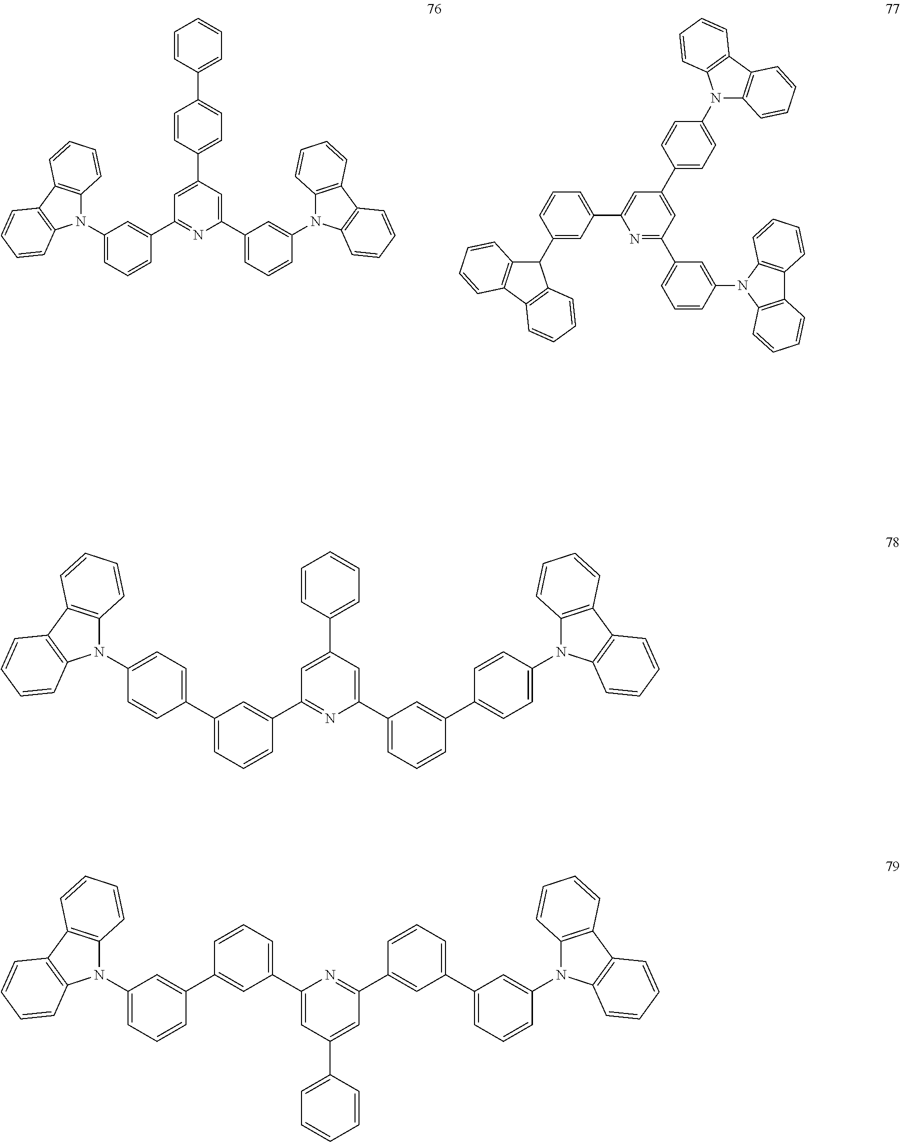

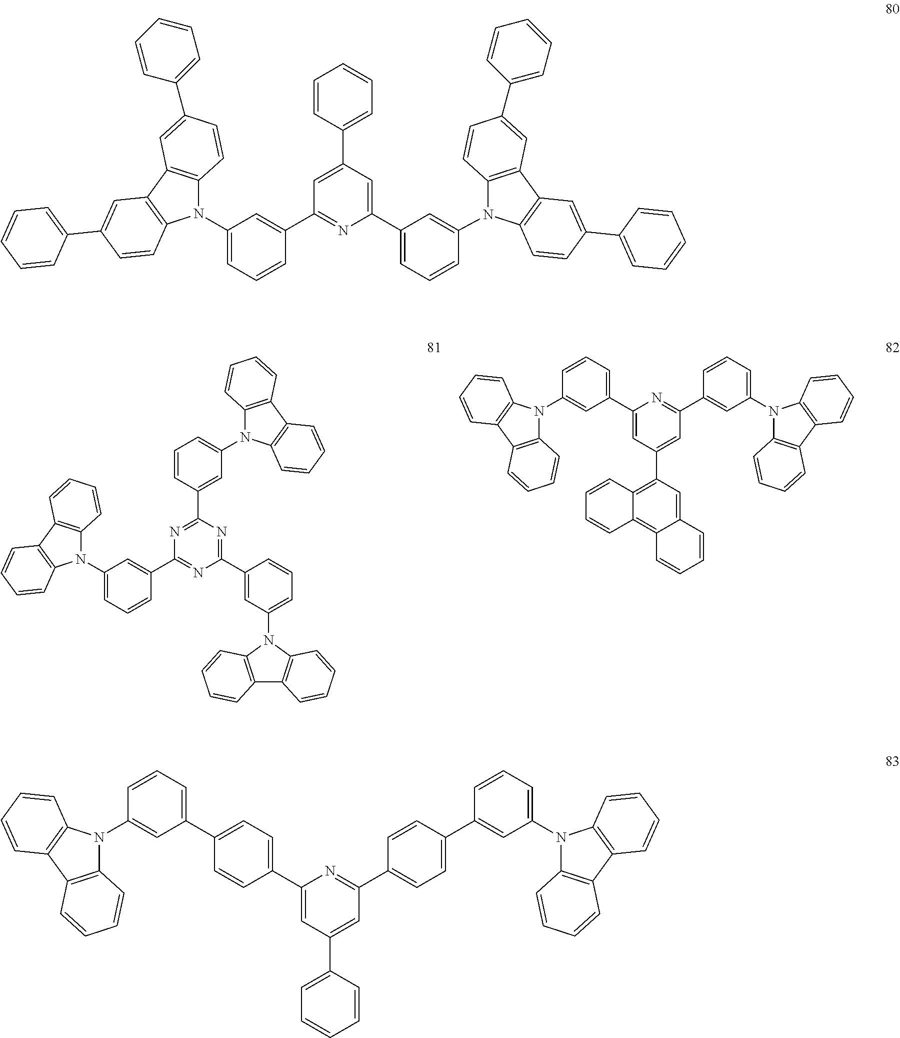

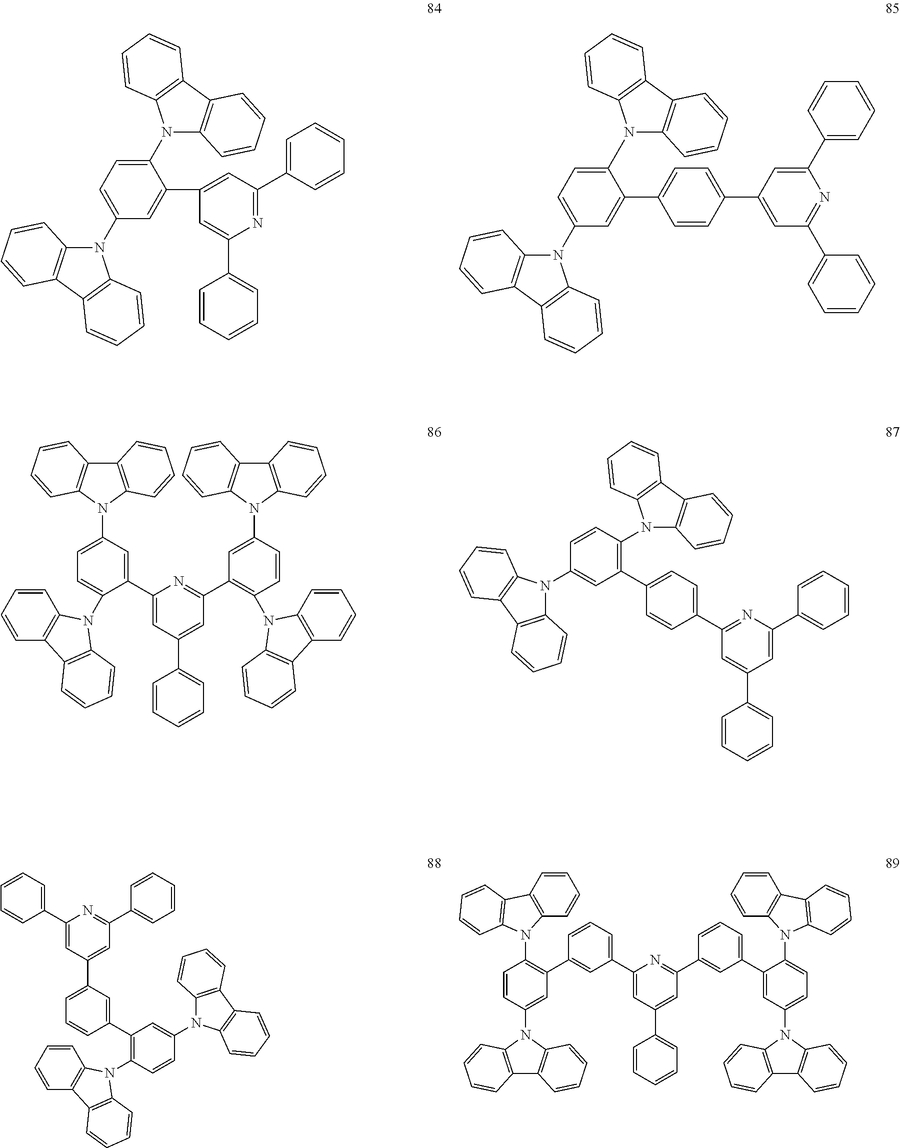

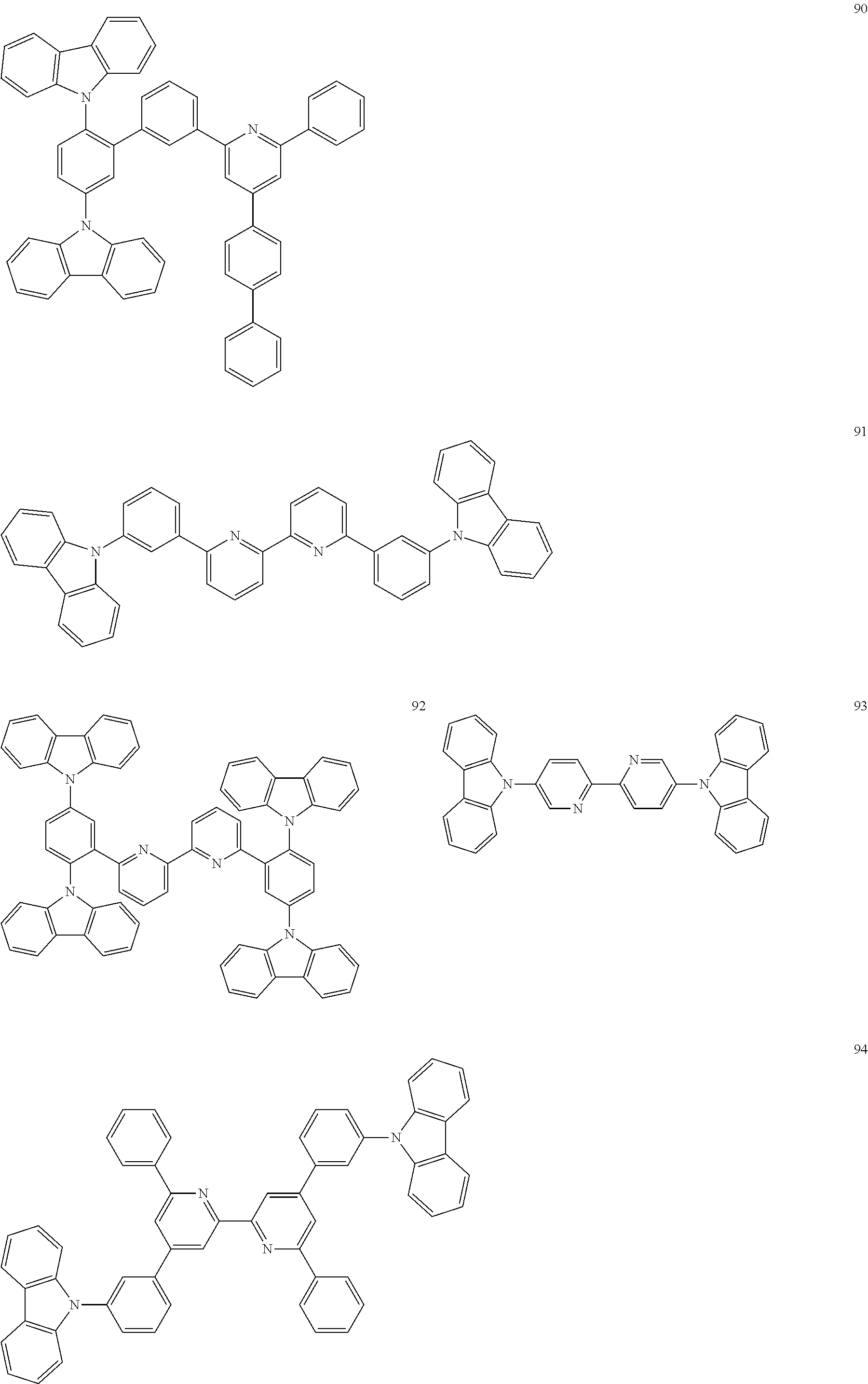

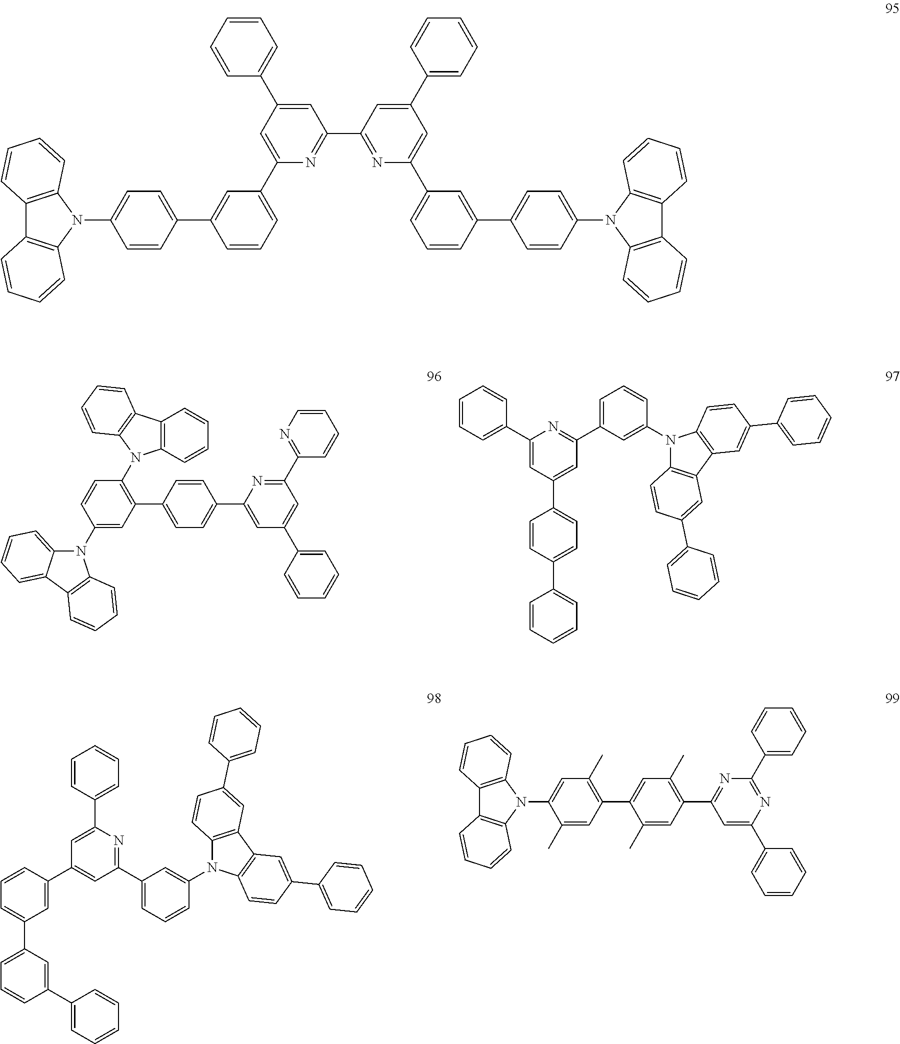

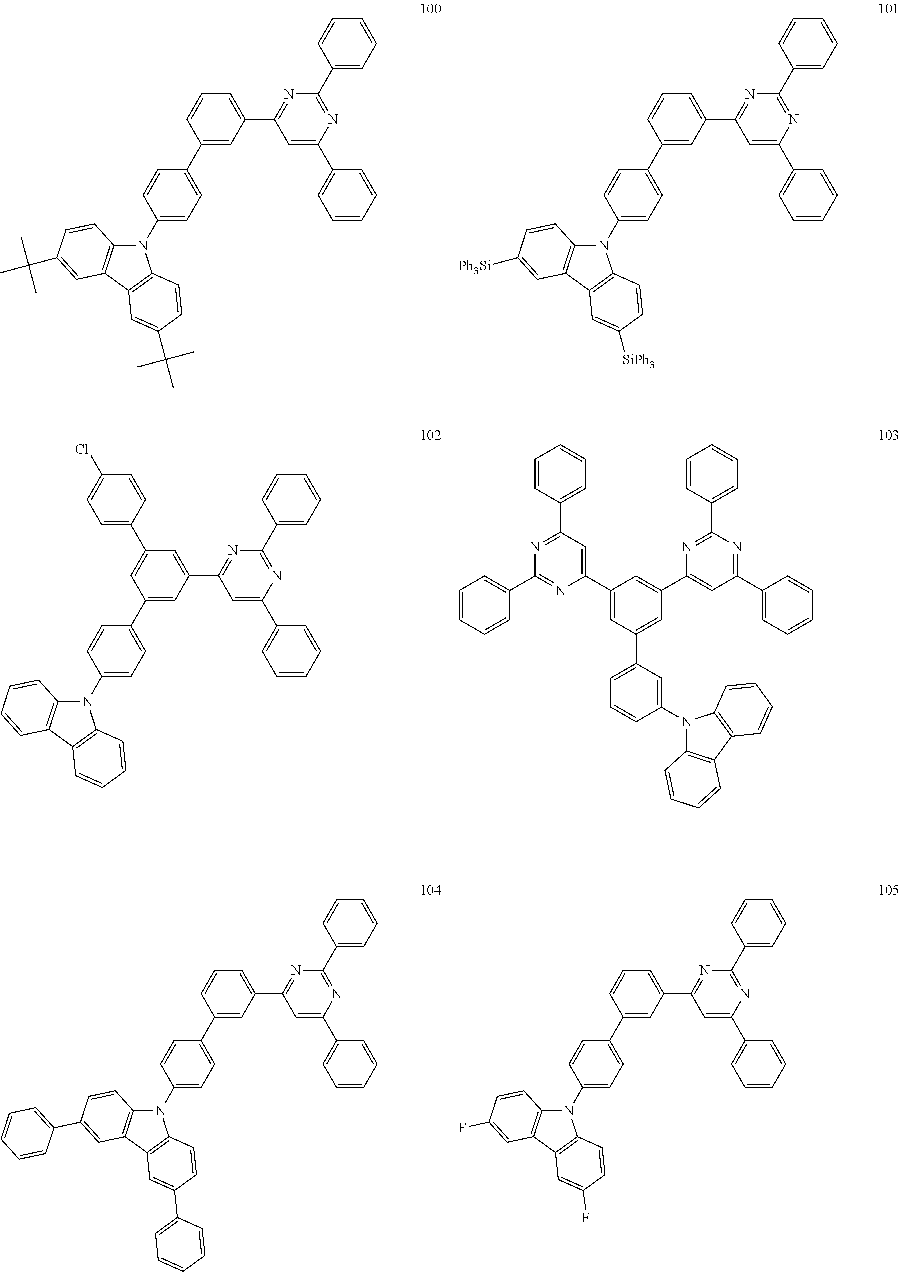

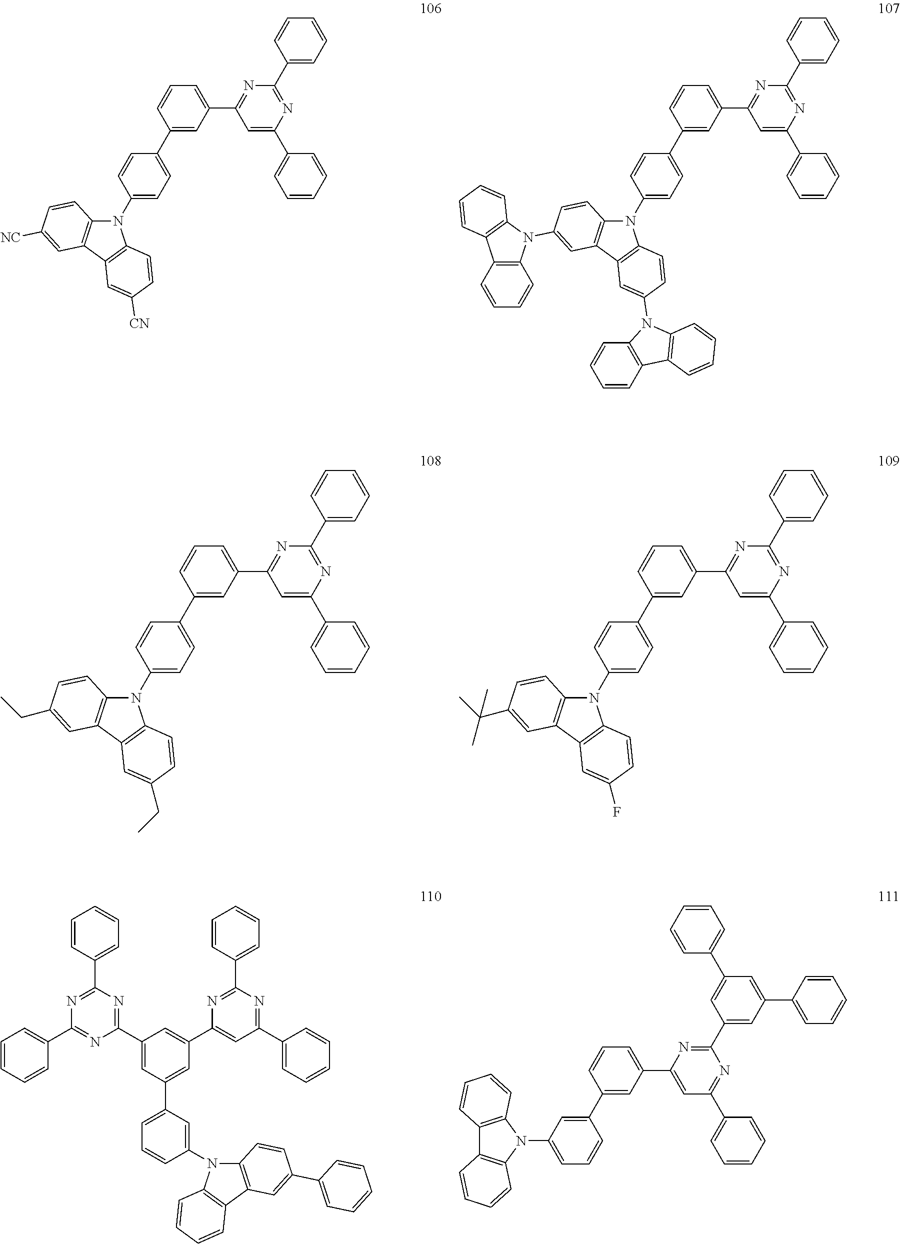

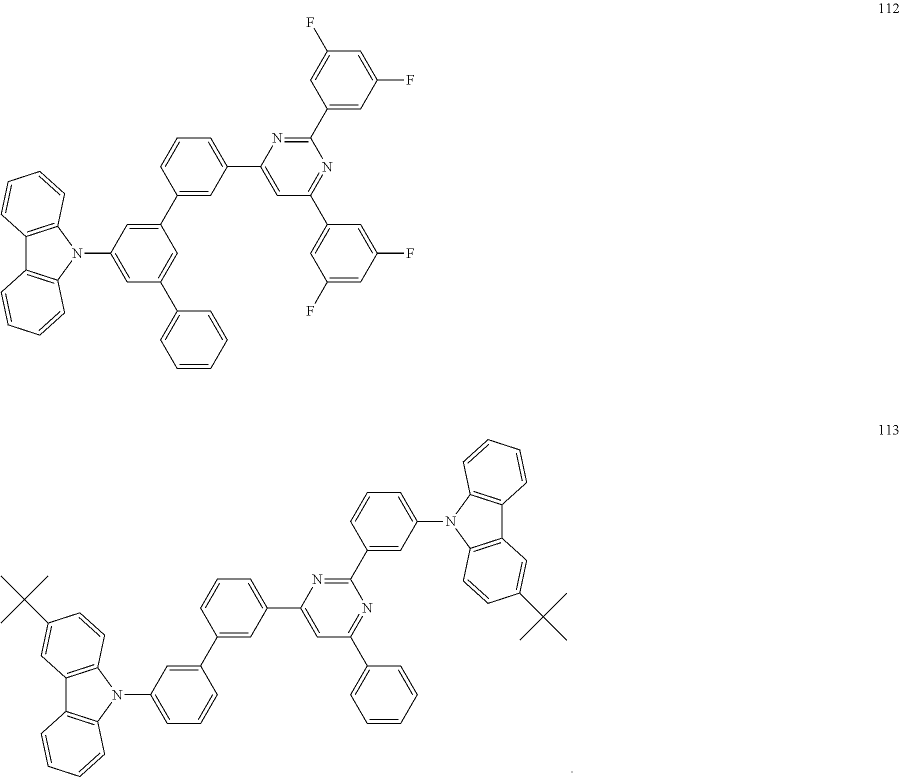

The above compounds which exemplify the compound represented by the formula (1) can be synthesized according to various methods, such as the methods disclosed in WO 03/080760, WO 03/078541 and WO 05/085387 brochures.

For example, the compound of Exemplified Compound 4 can be synthesized using m-bromobenzaldehyde as a starting material in accordance with the method disclosed in WO 05/085387 brochure (from page 45, line 11, to page 46, line 18). The compound of Exemplified Compound 45 can be synthesized using 3,5-dibromobenzaldehyde as a starting material in accordance with the method disclosed in WO 03/080760 brochure, page 46, line 9 to line 12. In addition, the compound of Exemplified Compound 68 can be synthesized using N-phenylcarbazole as a starting material in accordance with the method disclosed in WO 05/022962 brochure, page 137, line 10, to page 139, line 9.

In the invention, the compound represented by the formula (1) may be incorporated into any layer besides a light emitting layer. Examples of a layer suitable for introduction of the compound represented by the formula (1) include a light emitting layer, a hole injection layer, a hole transporting layer, an electron transporting layer, an electron injection layer, an exciton blocking layer and a charge blocking layer. It is preferable that the compound represented by the formula (1) may be introduced into one or any one or more of those layers.

When the compound represented by the formula (1) is incorporated into a light emitting layer, the compound content is preferably from 0.1% to 99% by mass, far preferably from 1% to 95% by mass, further preferably from 10% to 95% by mass, with respect to the total mass of the light emitting layer. When the compound represented by the formula (1) is further incorporated into a certain layer other than the light emitting layer, the compound content is preferably from 70% to 100% by mass, far preferably from 85% to 100% by mass.

### <Compound Represented by Formula (T-1)>

The compound represented by formula (T-1) is illustrated below.

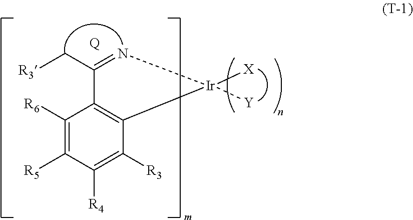

In the formula (T-1), R₃′ represents an alkyl group, a heteroalkyl group, an aryl group or a heteroaryl group, which each may further have a substituent Z.

R₅ represents an aryl group or a heteroaryl group, which each may further have a nonaromatic substituent.

The ring Q represents an aromatic heterocyclic ring or condensed aromatic heterocyclic ring which has at least one nitrogen atom to form a coordination bond with Ir, and the ring Q may further have a nonaromatic substituent.

each of R₃, R₄ and R₆ independently represents a hydrogen atom, an alkyl group, an alkenyl group, an alkynyl group, —CN, —CF₃, —CₙF₂ₙ₊₁, a trifluorovinyl group, —CO₂R, —C(O)R, —NR₂, —NO₂, —OR, a halogen atom, an aryl group or a heteroaryl group, which each may further have a substituent Z.

R₃ and R₄ may combine with each other to complete a condensed 4- to 7-membered ring, and the condensed 4- to 7-membered ring is a cycloalkane ring, a cycloheteroalkane, an arene or a heteroarene, which each may further have a substituent Z.

R₃′ and R₆ may complete a ring by linking via a linking group selected from the groups consisting of —CR₂—CR₂—, —CR═CR—, —CR₂—, —O—, —NR—, —O—CR₂—, —NR—CR₂— and —N═CR—, each of R₅ independently represents a hydrogen atom, an alkyl group, an alkenyl group, an alkynyl group, a heteroalkyl group, an aryl group or a heteroaryl group, which each may further have a substituent Z.

Each of Zs independently represents a halogen atom, —R′, —OR′, —N(R′)₂, —SR′, —C(O)R′, —C(O)OR′, —C(O)N(R′)₂, —CN, —NO₂, —SO₂, —SOR′, —SO₂R′ or —SO₃R′, and each of R's independently represents a hydrogen atom, an alkyl group, a perhaloalkyl group, an alkenyl group, an alkynyl group, a heteroalkyl group, an aryl group or a heteroaryl group.

(X—Y) represents an ancillary ligand.

m represents an integer from 1 to 3 and n represents an integer from 0 to 2, provided that m+n=3.

The compound represented by the formula (T-1) is a complex having iridium (Ir) as metal, and is superior in contribution to a high quantum yield in light luminous.

The alkyl group represented by each of R₃′, R₃, R₄ and R₆ may have a substituent and may be a saturated or unsaturated one. Examples of the substituent the alkyl group may have include those recited below as the substituent Z. The alkyl group represented by each of the above R and R′ is an alkyl group which is preferably from 1 to 8, far preferably from 1 to 6, in the total number of carbon atoms, with examples including a methyl group, an ethyl group, an i-propyl group, a cyclohexyl group and a t-butyl group.

The heteroalkyl group represented by R3′ may be a group formed by substituting O, NR or S for at least one carbon atom in any of the alkyl groups as recited above.

The aryl group represented by each of R₃′, R, R′ and R₃ to R₄ is preferably a substituted or unsubstituted aryl group which is from 6 to 30 in the number of carbon atoms, such as a phenyl group, a tolyl group or a naphthyl group.

The heteroaryl group represented by each of R₃′, R, R′ and R₃ to R₆ is preferably a heteroaryl group which is from 5 to 8 in the number of carbon atoms, far preferably a substituted or unsubstituted 5- or 6-membered heteroaryl group, with examples including a pyridyl group, a pyrazinyl group, a pyridazinyl group, a pyrimidinyl group, a triazinyl group, a quinolinyl group, an isoquinolinyl group, a quinazolinyl group, a cinnolinyl group, a phthalazinyl group, a quinoxalinyl group, a pyrrolyl group, an indolyl group, a furyl group, a benzofuryl group, a thienyl group, a benzothienyl group, a pyrazolyl group, an imidazolyl group, a benzimidazolyl group, a triazolyl group, an oxazolyl group, an benzoxazolyl group, a thiazolyl group, a benzothiazolyl group, an isothiazolyl group, a benzisothiazolyl group, a thiadiazolyl group, an isoxazolyl group, a benzisoxazolyl group, a pyrrolidinyl group, a piperidinyl group, a piperazinyl group, an imidazolidinyl group, a thiazolinyl group and a sulfolanyl group.

Examples of the heteroaryl group represented by R₃′ are preferably a pyridyl group, a pyrimidinyl group, an imidazolyl group and a thienyl group, far preferably a pyridyl group and a pyrimidinyl group.

Groups preferred as R₃′ include a methyl group, an ethyl group, a propyl group and a butyl group. Of these groups, a methyl group and an ethyl group are far preferred, and a methyl group is further preferred.

R₅ represents an aryl group or a heteroaryl group, and at least one hydrogen atom of the aryl or heteroaryl group may be replaced with a nonaromatic group.

The nonaromatic group in R₅ is preferably an alkyl group, an alkoxy group, a fluoro radical, a cyano group, an alkylamino group or a diarylamino group, far preferably an alkyl group, a fluoro group or a cyano group, further preferably an alkyl group.

Groups preferred as R₅ are a phenyl group, a p-tolyl group and a naphthyl group. Of these groups, a phenyl group is far preferable.

It is preferable that each of R₃, R₄ and R₆ represent a hydrogen atom, an alkyl group, a cyano group, a trifluoromethyl group, a perfluoroalkyl group, a dialkylamino group, a fluoro group, an aryl group or a heteroaryl group. Of these group, a hydrogen atom, an alkyl group, a cyano group, a trifluoromethyl group, a fluoro group and an aryl group are far preferably, and a hydrogen atom, an alkyl group and an aryl group are further preferable.

The substituent Z in each of R₃, R₄ and R₆ is preferably an alkyl group, an alkoxy group, a fluoro group, a cyano group or a dialkylamino group. It is far preferable that each of R₃, R₄ and R₆ has no substituent Z.

Examples of an aromatic heterocyclic ring which the ring Q represents include a pyridine ring, a pyrazine ring, a pyrimidine ring, a pyrazole ring, an imidazole ring, a triazole ring, an oxazole ring, an oxadiazole ring, a thiazole ring and a thiadiazole ring. Of these rings, a pyridine ring and a pyrazine ring are preferable, and a pyridine ring is far preferable.

Examples of a condensed aromatic heterocyclic ring which the ring Q represents include a quinoline ring, an isoquinoline ring, and a quinoxaline ring. Of these rings, a quinoline ring and an isoquinoline ring are preferable, and a quinoline ring is far preferable.

The nonaromatic group which the ring Q may have as a substituent is preferably an alkyl group, an alkoxy group, a fluoro group, a cyano group, an alkylamino group or a diarylamino group, far preferably an alkyl group, a fluoro group or a cyano group.

m represents an integer from 1 to 3, preferably 2 or 3, far preferably 2.

n represents an integer from 0 to 2, preferably 0 or 1, far preferably 1.

And it is further preferable that m represents 2 and n represents 1.

(X—Y) represents an ancillary ligand. It is thought that such a ligand has no direct contribution to photoactive properties but can make modifications to photoactive properties of molecules. Such a ligand is therefore referred to as an “ancillary” ligand. Definitions of “photoactive” and “ancillary” given to the ligand are aimed at a nonattributive theory. For instance, as to the bidentate ligand in the case of Ir, n may stand for 0, 1 or 2. Ancillary ligands usable in light emitting materials can be selected from those heretofore known in the field. Examples of nonattributive use of bidentate ligands are described in Lamansky et al., PCT application WO-A1-0215645, pp. 89-90, which is cited as a reference. Suitable examples of an ancillary ligand include acetylacetonate (acac), picolinate (pic) and their derivatives. The ancillary ligand preferred in the invention is acetylacetonate from the viewpoint of achieving complex stability and high luminous efficiency.

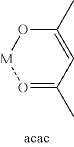

The compound represented by the formula (T-1) is preferably a compound represented by the following formula (T-2).

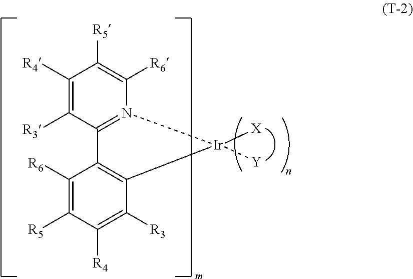

In the formula (T-2), R₃′ represents an alkyl group, a heteroalkyl group, an aryl group or a heteroaryl group, which each may further have a substituent Z.

Each of R₄′ to R₆′ independently represents a hydrogen atom, an alkyl group, an alkenyl group, an alkynyl group, a heteroalkyl group, an aryl group or a heteroaryl group, which each may further have a substituent Z.

Alternatively, R₃′ and R₄′, or R₄′ and R₅′, or R₅′ and R₆′ may combine with each other to complete a condensed 4- to 7-membered ring, and the condensed 4- to 7-membered ring is a cycloalkane ring, a cycloheteroalkane ring, an arene ring or a heteroarene ring, which each may further have a substituent Z.

R₃′ and R₆ may complete a ring by linking via a linking group selected from the groups consisting of —CR₂—CR₂—, —CR═CR—, —CR₂—, —O—, —NR—, —O—CR₂—, —NR—CR₂— and —N═CR—, each of the Rs independently represents a hydrogen atom, an alkyl group, an alkenyl group, an alkynyl group, a heteroalkyl group, an aryl group or a heteroaryl group, which each may further have a substituent Z.

R₅ represents an aryl group or a heteroaryl group, which each may further have a nonaromatic group.

Each of R₃, R₄ and R₆ independently represents a hydrogen atom, an alkyl group, an alkenyl group, an alkynyl group, —CN, —CF₃, —CₙF₂ₙ₊₁, a trifluorovinyl group, —CO₂R, —C(O)R, —NR₂, —NO₂, —OR, a halogen atom, an aryl group or a heteroaryl group, which each may further have a substituent Z.

Alternatively, R₃ and R₄ may combine with each other to complete a condensed 4- to 7-membered ring, and the condensed 4- to 7-membered ring is a cycloalkane ring, a cycloheteroalkane ring, an arene ring or a heteroarene ring, which each may further have a substituent Z.

Each of Zs independently represents a halogen atom, —R′, —OR′, —N(R′)₂, —SR′, —C(O)R′, —C(O)OR′, —C(O)N(R′)₂, —CN, —NO₂, —SO₂, —SOR′, —SO₂R′ or —SO₃R′, and each of R's independently represents a hydrogen atom, an alkyl group, a perhaloalkyl group, an alkenyl group, an alkynyl group, a heteroalkyl group, an aryl group or a heteroaryl group.

(X—Y) represents an ancillary ligand.

m represents an integer from 1 to 3 and n represents an integer from 0 to 2, provided that m+n=3.

R₃′, R₃ to R₆, (X—Y), m and n in the formula (T-2) have the same meanings as R₃′, R₃ to R₆, (X—Y), m and n in the formula (T-1), respectively, and they are also alike in their respective preferences.

R₄′ preferably represents a hydrogen atom, an alkyl group, an aryl group or a fluoro group, and far preferably represents a hydrogen atom.

R₅′ and R₆′ preferably represent hydrogen atoms or combine with each other to complete a condensed 4- to 7-membered ring, and the condensed 4- to 7-membered ring is preferably a cycloalkane ring, a cycloheteroalkane ring, an arene ring or a heteroarene ring, far preferably an arene ring.

When each of those represented by R₄′ to R₆′ can have a substituent Z, the substituent Z is preferably an alkyl group, an alkoxy group, a fluoro group, a cyano group, an alkylamino group or a diarylamino group, far preferably an alkyl group.

The compound represented by the formula (T-2) is preferably a compound represented by the following formula (T-3).

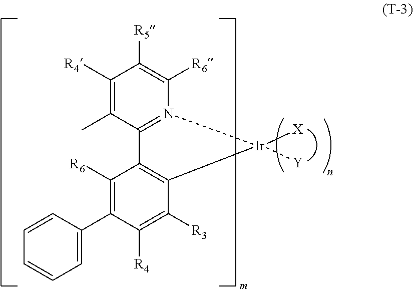

In the formula (T-3), R₄′ represents a hydrogen atom, an alkyl group, an alkenyl group, an alkynyl group, a heteroalkyl group, an aryl group or a heteroacryl group, which each may further have a substituent Z.

R₅″ and R₆″ represent hydrogen atoms or combine with each other to complete a condensed 4- to 7-membered ring, and the condensed 4- to 7-membered ring is a cycloalkane ring, a cycloheteroalkane ring, an arene ring or a heteroarene ring.

Each of R₃, R₄ and R₆ independently represents a hydrogen atom, an alkyl group, an alkenyl group, an alkynyl group, —CN, —CF₃, CₙF₂ₙ₊₁, a trifluorovinyl group, —CO₂R, —C(O)R, —NR₂, —NO₂, —OR, a halogen atom, an aryl group or a heteroaryl group, which each may further have a substituent Z.

Alternatively, R₃ and R₄ may combine with each other to form a condensed 4- to 7-membered ring, and the condensed 4- to 7-membered ring is a cycloalkane ring, a cycloheteroalkane ring, an arene ring or a heteroarene ring, which each may have a substituent Z.

Each of Zs independently represents a halogen atom, —R′, —OR′, —N(R′)₂, —SR′, —C(O)R′, —C(O)OR′, —C(O)N(R′)₂, —CN, —NO₂, —SO₂, —SOR′, —SO₂R′ or —SO₃R′, and each of R's independently represents a hydrogen atom, an alkyl group, a perhaloalkyl group, an alkenyl group, an alkynyl group, a heteroalkyl group, an aryl group or a heteroaryl group.

(X—Y) represents an ancillary ligand.

m represents an integer from 1 to 3 and n represents an integer from 0 to 2, provided that m+n=3.

R₄′, R₃, R₄, R₆, (X—Y), m and n in the formula (T-3) have the same meanings as R₄′, R₃, R₄, R₆, (X—Y), m and n in the formula (T-2), respectively, and they are also alike in their respective preferences.

It is preferable that each of R₅″ and R₆″ represents a hydrogen atom or R₅″ and R₆″ are combined together to complete an arene ring, and it is further preferred that R₅″ and R₆″ are combined together to complete an arene ring.

The compound represented by the formula (T-3) is preferably a compound represented by the following formula (T-4).

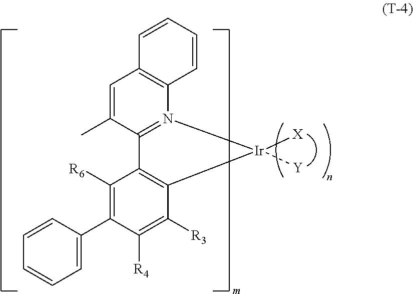

In the formula (T-4), each of R₃, R₄ and R₆ independently represents a hydrogen atom, an alkyl group, an alkenyl group, an alkynyl group, —CN, —CF₃, —CₙF₂ₙ₊₁, a trifluorovinyl group, —CO₂R, —C(O)R, —NR₂, —NO₂, —OR, a halogen atom, an aryl group or a heteroaryl group, which each may further have a substituent Z.

Each of Zs independently represents a halogen atom, —R′, —OR′, —N(R′)₂, —SR′, —C(O)R′, —C(O)OR′, —C(O)N(R′)₂, —CN, —NO₂, —SO₂, —SOR′, —SO₂R′ or —SO₃R′, and each of R's independently represents a hydrogen atom, an alkyl group, a perhaloalkyl group, an alkenyl group, an alkynyl group, a heteroalkyl group, an aryl group or a heteroaryl group.

(X—Y) represents an ancillary ligand.

m represents an integer from 1 to 3 and n represents an integer from 0 to 2, provided that m+n=3.

R₃, R₄, R₆, (X—Y), m and n in the formula (T-4) have the same meanings as R₃, R₄, R₆, (X—Y), m and n in the formula (T-1), respectively, and they are also alike in their respective preferences.

Examples of the compound represented by the formula (T-1) are illustrated below, but the invention should not be construed as being limited to these examples.

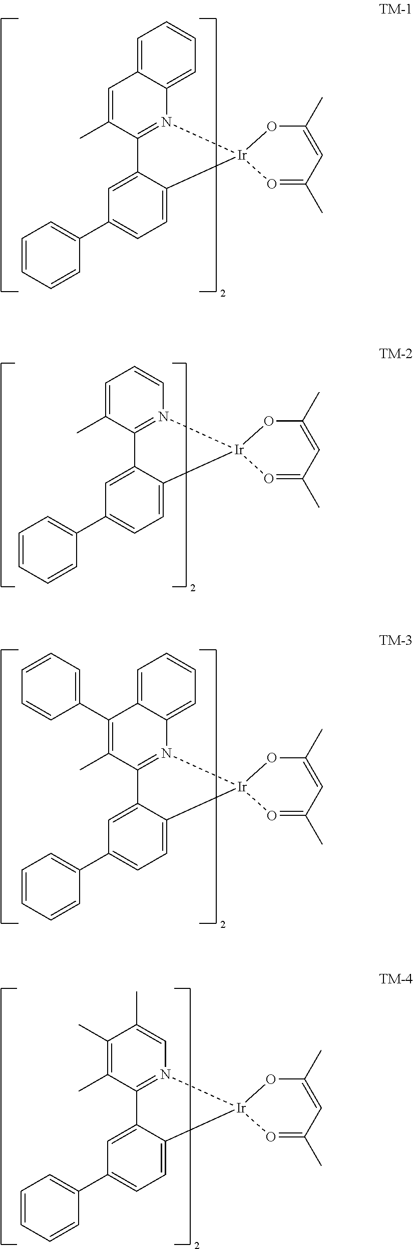

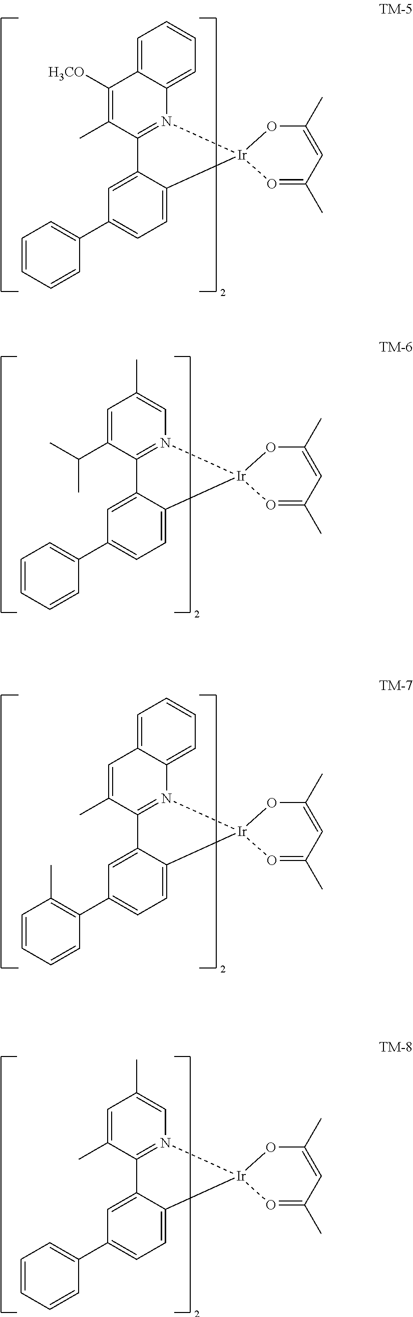

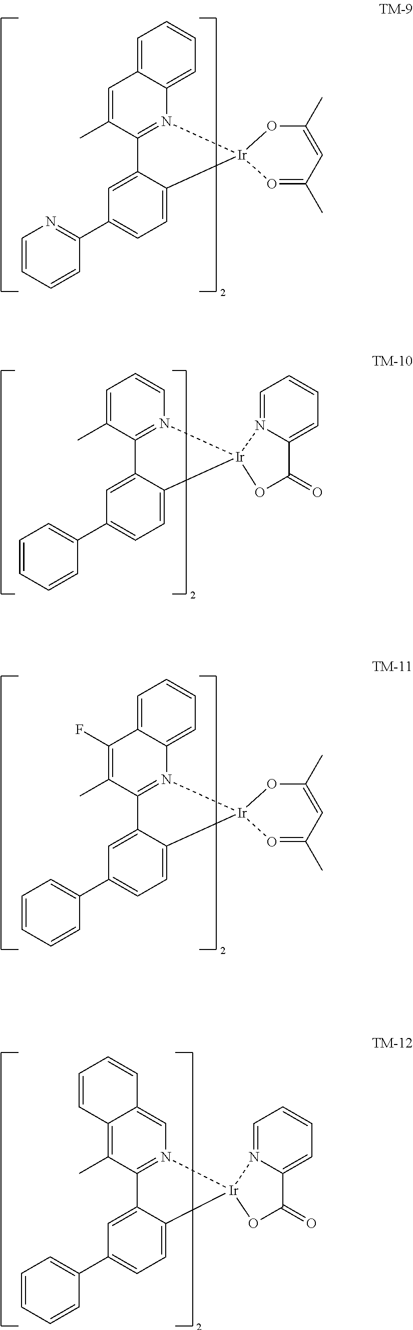

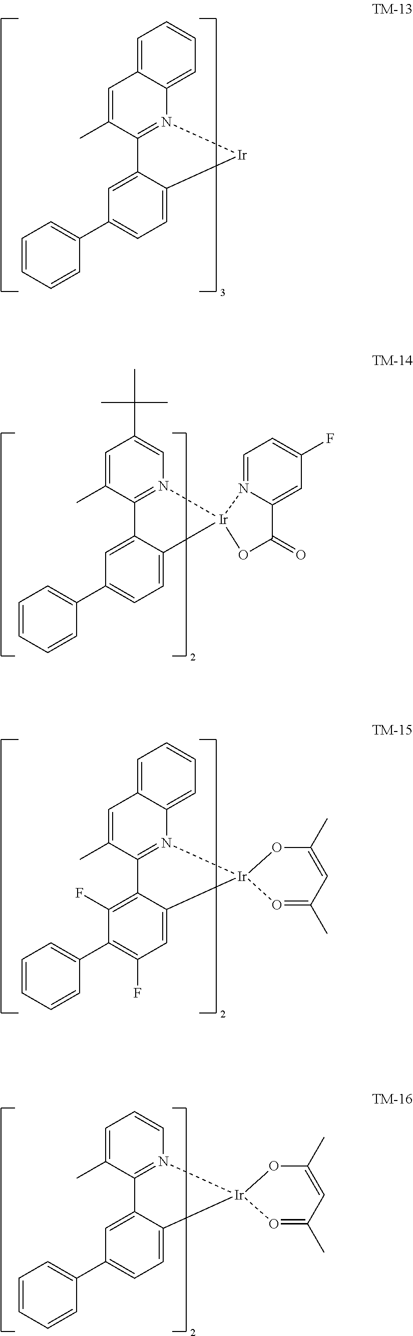

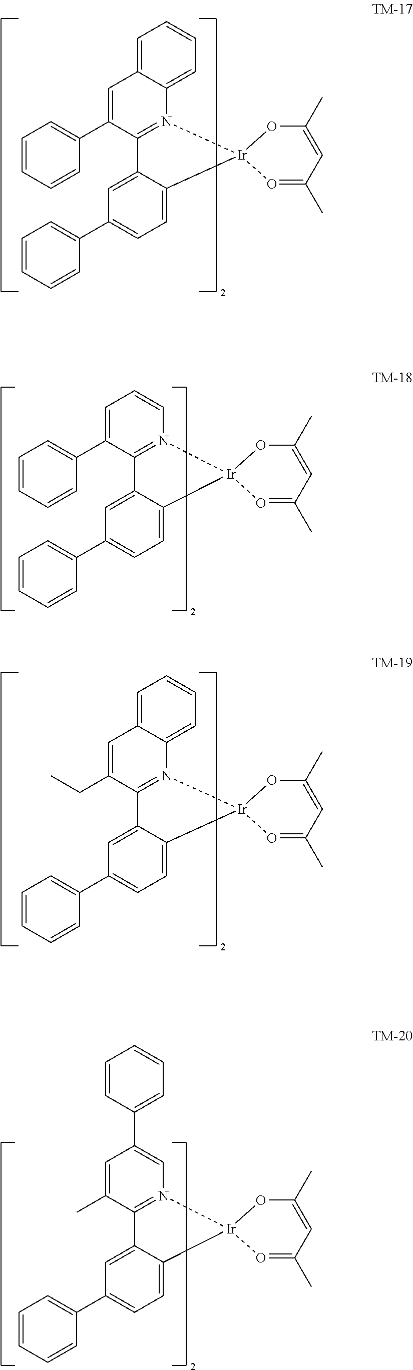

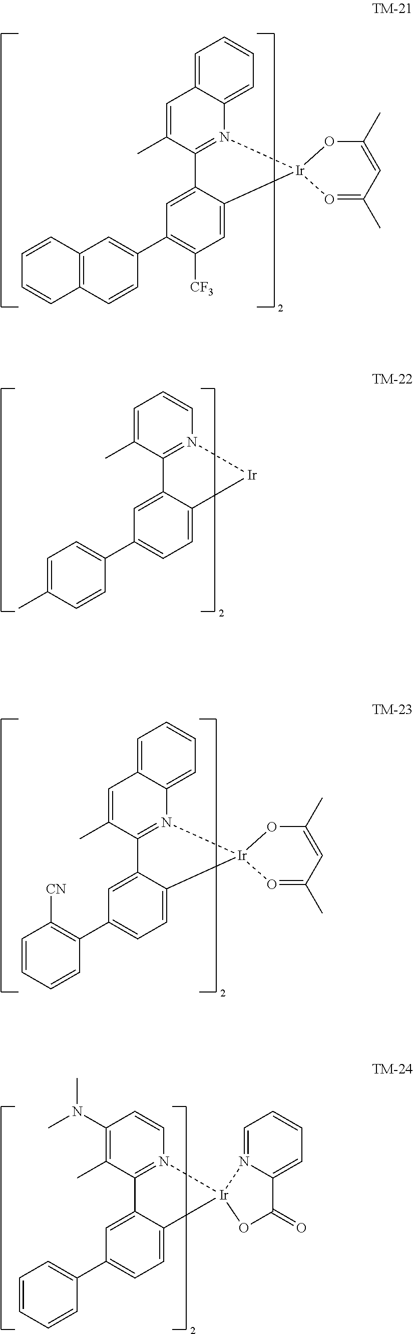

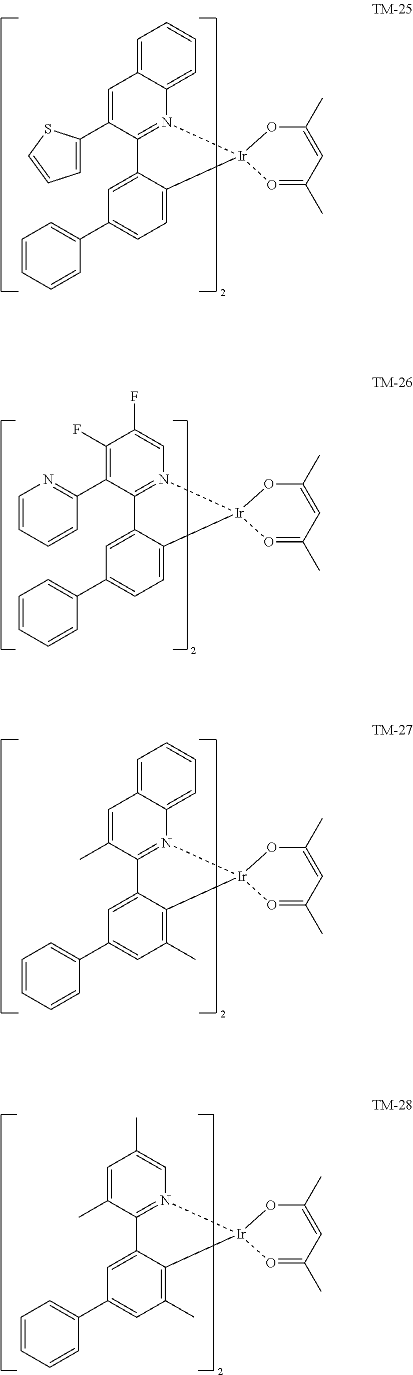

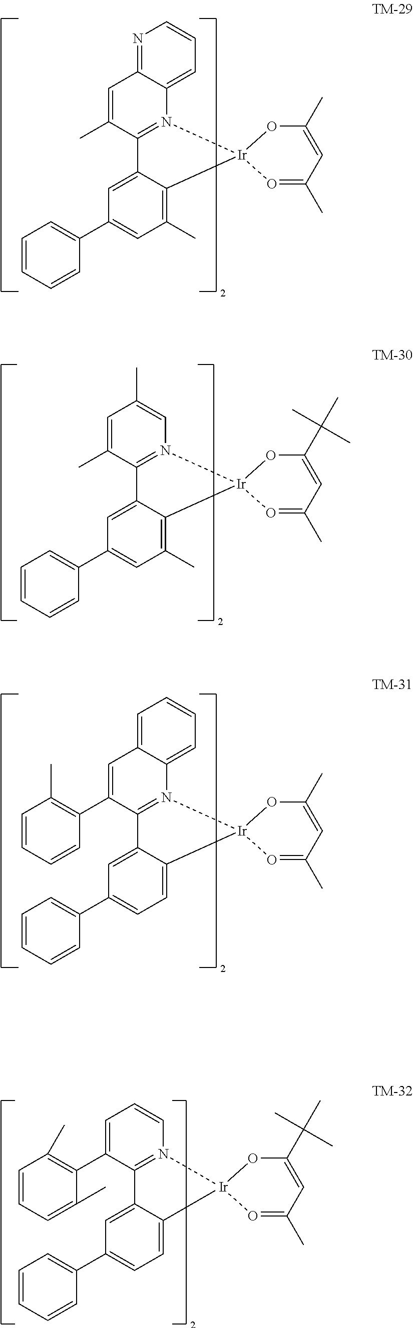

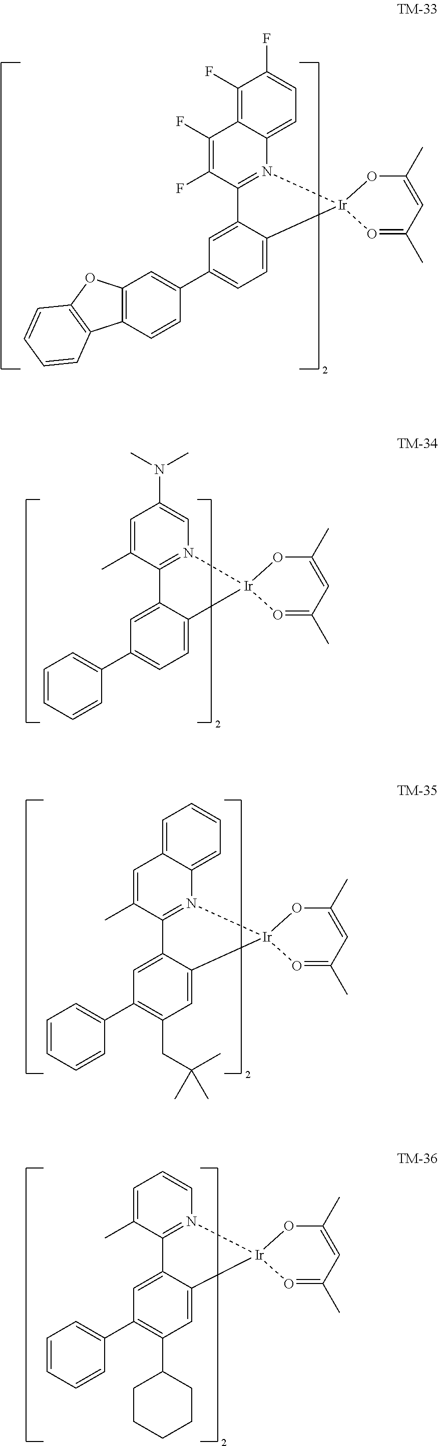

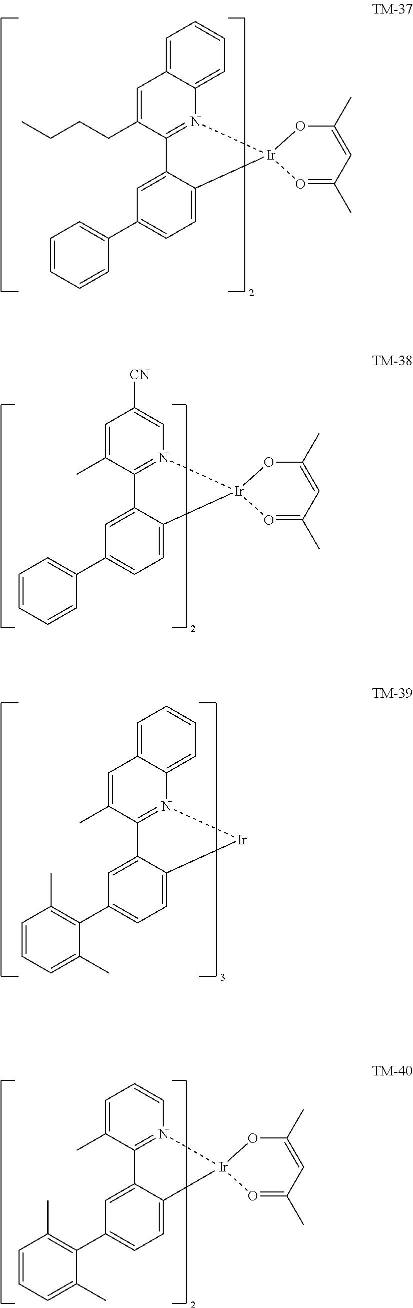

The compounds illustrated above as examples of the compound represented by the formula (T-1) can be synthesized according to various methods as disclosed in JP-A-2009-99783 and U.S. Pat. No. 7,279,232. For instance, Exemplified Compound TM-1 can be synthesized by using 2-chloro-3-methylquinoline as a starting material in accordance with the method disclosed in U.S. Pat. No. 7,279,232, column 21, line 1, to column 27, line 33. And Exemplified Compound TM-2 can be synthesized by using 2-bromo-3-methylpyridine in accordance with the method disclosed in U.S. Pat. No. 7,279,232, column 29, line 1, to column 31, line 29.

In the invention, though the compound represented by the formula (T-1) is incorporated into a light emitting layer, there is no limitation to its usage but the compound may further be incorporated into any layer among organic layers.

In the invention, both the compound of the formula (T-1) and the compound of the formula (1) are incorporated into a light emitting layer in order to minimize shifts in chromaticity under high-temperature drive.

When the compound represented by the formula (T-1) is incorporated into a light emitting layer, the compound content is preferably from 0.1% to 30% by mass, far preferably from 1% to 20% by mass, further preferably from 5% to 15% by mass, with respect to the total mass of the light emitting layer.

### <Composition Containing Compound of Formula (1) and Compound of Formula (T-1)>

The invention also relates to a composition containing the compound represented by the formula (1) and the compound represented by the formula (T-1).

The content of the compound represented by the formula (1) in the composition is preferably from 50% to 99% by mass, far preferably from 70% to 95% by mass.

The content of the compound represented by the formula (T-1) in the composition is preferably from 1% to 30% by mass, far preferably from 5% to 15% by mass.

Other ingredients which the composition can contain may be organic substances or inorganic substances. What can be used as the organic substances are materials recited below as a host material, a fluorescent material, a phosphorescent material and a hydrocarbon material, preferably a host material and a hydrocarbon material, far preferably a compounds represented by the formula (VI) illustrated hereinafter.

The composition according to the invention can form an organic layer for the organic electroluminescence device by using e.g. a dry film-making method, such as a vapor deposition method or a sputtering method, a transfer method or a printing method.

### <Organic Electroluminescence Device>

The present devices are described below in detail.

The present electroluminescence device has a first electrode and a second electrode each on a substrate and a light emitting layer sandwiched between the first electrode and the second electrode. In addition, the light emitting layer contains the compound represented by the formula (1) and the compound represented by the formula (T-1).

In the present organic electroluminescence devices, the light emitting layer is an organic layer, and two or more organic layers may further be included.

In terms of properties of the luminescence device, it is preferred that at least either of the two electrodes, an anode and a cathode, be transparent or translucent.

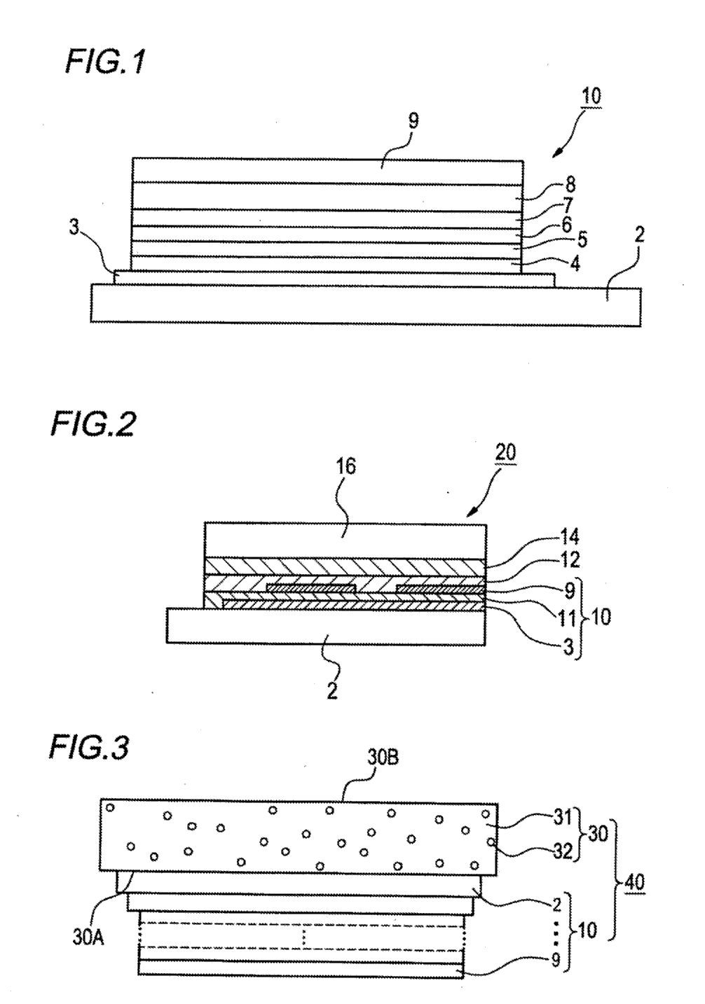

FIG. 1 shows one example of structures of the present organic electroluminescence devices. The present organic electroluminescence device 10 shown in FIG. 1 has, on a supporting substrate 2, a light emitting layer 6 sandwiched between an anode 3 and a cathode 9. More specifically, between an anode 3 and a cathode 9, a hole injection layer 4, a hole transport layer 5, a light emitting layer 6, a hole block layer 7 and an electron transport layer 8 are stacked on in the order of mention.

### <Structure of Organic Layer>

The organic layer has no particular restriction on its layer structure, and the layer structure thereof can be selected appropriately according to purposes of using the organic electroluminescence device. However, it is preferred that the organic layer be formed on the transparent electrode or the back electrode. In such a case, the organic layer is formed on the front of or all over the transparent electrode or the back electrode.

The organic layer has no particular limitations e.g. on its shape, size and thickness, and these factors can be selected as appropriate according to purposes given to the organic layer.

The following are specific examples of a layer structure, but these layer structures should not be construed as limiting the scope of the invention.
Anode/hole transporting layer/light emitting layer/electron transporting layer/cathode
Anode/hole transporting layer/light emitting layer/blocking layer/electron transporting layer/cathode
Anode/hole transporting layer/light emitting layer/blocking layer/electron transporting layer/electron injection layer/cathode
Anode/hole injection layer/hole transporting layer/light emitting layer/blocking layer/electron transporting layer/cathode
Anode/hole injection layer/hole transporting layer/light emitting layer/blocking layer/electron transporting layer/electron injection layer/cathode

The structure, substrate, cathode and anode of an organic electroluminescence device are described e.g. in JP-A-2008-270736, and the items described in such a reference can also be applied to the invention.

### <Substrate>

The substrate used in the invention is preferably a substrate which causes neither scattering nor damping of light emitted from the organic layer. When the substrate is made from an organic material, it is preferable that the organic material has excellent heat resistance, dimensional stability, solvent resistance, electrical insulation and workability.

### <Anode>

In ordinary cases, it is essential only that the anode should function as an electrode for supplying holes into the organic layer, and there is no particular limitation e.g. on anode's shape, structure and size. And the electrode material can be selected from heretofore known ones as appropriate according to uses and purposes of the luminescence device. As mentioned above, the anode is usually provided in a state of being transparent.

### <Cathode>

In ordinary cases, it is essential only that the cathode should function as an electrode for supplying electrons into the organic layer, and there is no particular limitation e.g. on anode's shape, structure and size. And the electrode material can be selected from heretofore known ones as appropriate according to uses and purposes of the luminescence device.

With respect to the substrate, the anode and the cathode, the matters described in JP-A-2008-270736 are applicable in the invention.

### <Organic Layer>

The organic layer in the invention is explained.

### —Formation of Organic Layer—

Each organic layer in the present organic electroluminescence device can be suitably formed in accordance with any of a dry film formation method, such as a vapor deposition method or a sputtering method, a transfer method, a printing method and the like.

### (Light Emitting Layer)

### <Light Emitting Material>

The light emitting material for use in the invention is preferably the compound represented by the formula (T-1).

The light emitting material content in the light emitting layer is generally from 0.1% to 50% by mass with respect to the total mass of compounds constituting the light emitting layer, but from the viewpoints of durability and external quantum efficiency, the content is preferably from 1% to 50% by mass, far preferably from 2% to 40% by mass.

The thickness of the light emitting layer, though not particularly limited, is preferably from 2 nm to 500 nm in ordinary cases. From the viewpoint of external quantum efficiency in particular, the thickness is far preferably from 3 nm to 200 nm, further preferably from 5 nm to 100 nm.

The light emitting layer in the present device may be constituted of only a light emitting material or a mixture of a light emitting material with a host material. The light emitting material may be either a fluorescent material or a phosphorescent material, and one or two or more types of dopant may be added thereto. The host material is preferably a charge transport material. One type of host material or two or more types of host materials may be used. For instance, the host material may be constituted of a mixture of an electron transporting host material and a hole transporting host material. Further, the light emitting layer may contain a material which neither has a charge transporting property nor emits light. The light emitting layer in the present device is preferably the light emitting layer which uses the compound represented by the formula (1) as the host material and the compound represented by the formula (T-1) as the light emitting material.

Additionally, the light emitting layer may be a single layer, or it may include multiple (two or more) constituent layers. When the light emitting layer includes multiple constituent layers, each of two or more constituent layers may contain the compound represented by the formula (1) and the compound represented by the formula (T-1). In addition, each of the multiple constituent layers may emit light different in luminescent color.

The invention relates also to a light emitting layer containing the compound represented by the formula (1) and the compound represented by the formula (T-1). The present light emitting layer can be used in organic electroluminescence device.

### <Host Material>

The host material for use in the invention is preferably the compound represented by the formula (1).

The compound represented by the formula (1) is a compound capable of transporting both holes and electrons, by using the compound represented by the formula (1) in combination with the compound represented by the formula (T-2), it is possible to inhibit the balance between abilities to transport holes and electrons in the light emitting layer from changing with temperature, electric field and other external environments. And thereby the durability under driving can be increased even though the compound has a carbazolyl group. Moreover, a shift in chromaticity under high-temperature drive can be inhibited.

The host material used in the invention may further contain the following compounds. Examples thereof include pyrrole, indole, carbazole (including CBP (4,4′-di(9-carbazolyl)biphenyl)), azaindole, azacarbazole, triazole, oxazole, oxadiazole, pyrazole, imidazole, thiophene, polyarylalkane, pyrazoline, pyrazolone, phenylenediamine, arylamine, amino-substituted chalcone, styrylanthracene, fluorenone, hydrazone, stilbene, silazane, aromatic tertiary amine compounds, styrylamine compounds; porphyrin compounds, polysilane compounds, poly(N-vinylcarbazole), aniline copolymers, thiophene oligomers, oligomers of conductive polymers like polythiophene, organic silanes, carbon film, pyridine, pyrimidine, triazine, anthraquinodimethane, anthrone, diphenylquinone, thiopyran dioxide, carbodiimide, fluorelenylidenemethane, distyrylpyrazine, fluoro-substituted aromatic compounds, tetracarboxylic acid anhydrides of condensed aromatic ring compounds such as naphthalene and perylene, phthalocyanine, various kinds of metal complexes, typified by metal complexes of 8-quinolinol derivatives and metal complexes whose ligands are metallo-phthalocyanines, benzoxazole or benzothiazole molecules, and derivatives of the above-recited metal complexes (e.g. those replaced with substituents or those condensed with other rings).

In the light emitting layer according to the invention, it is preferable that the lowest triplet-state excitation energy (T₁ energy) of the host materials (including the compounds represented by the formula (1)) is higher than T₁ energy of the phosphorescent materials in terms of color purity, luminous efficiency and durability under driving.

The host-compound content in the invention is not particularly limited, but in terms of luminous efficiency and drive voltage it is preferably from 15% to 98% by mass with respect to the total mass of all compounds constituting the light emitting layer. The compound represented by the formula (1) preferably constitutes from 30% to 98% by mass of all host compounds.

When the compound represented by the formula (1) is introduced into a layer other than the light emitting layer (e.g. a charge transport layer), the content thereof in the layer is preferably from 10% to 100% by mass, far preferably from 30% to 100% by mass.

### (Fluorescent Material)

Examples of a fluorescent material usable in the invention include benzoxazole derivatives, benzimidazole derivatives, benzothiazole derivatives, styrylbenzene derivatives, polyphenyl derivatives, diphenylbutadiene derivatives, tetraphenylbutadiene derivatives, naphthalimide derivatives, coumarin derivatives, condensed aromatic compounds, perinone derivatives, oxadiazole derivatives, oxazine derivatives, aldazine derivatives, pyralidine derivatives, cyclopentadiene derivatives, bisstyrylanthracene derivatives, quinacridone derivatives, pyrrolopyridine derivatives, thiadiazolopyridine derivatives, cyclopentadiene derivatives, styrylamine derivatives, diketopyrrolopyrrole derivatives, aromatic dimethylidyne derivatives, various kinds of complexes typified by complexes of 8-quinolinol derivatives and complexes of pyrromethene derivatives, polymeric compounds such as polythiophene, polyphenylene and polyphenylenevinylene, and compounds like organic silane derivatives.

### (Phosphorescent Material)

Examples of a phosphorescent material usable in the invention include the compounds represented by the formula (T-1), and besides, they include the phosphorescent compounds as disclosed in U.S. Pat. No. 6,303,238B1, U.S. Pat. No. 6,097,147, WO 00/57676, WO 00/70655, WO 01/08230, WO 01/39234A2, WO 01/41512A1, WO 02/02714A2, WO 02/15645A1, WO 02/44189A1, WO 05/19373A2, JP-A-2001-247859, JP-A-2002-302671, JP-A-2002-117978, JP-A-2003-133074, JP-A-2002-235076, JP-A-2003-123982, JP-A-2002-170684, EP 1211257, JP-A-2002-226495, JP-A-2002-234894, JP-A-2001-247859, JP-A-2001-298470, JP-A-2002-173674, JP-A-2002-203678, JP-A-2002-203679, JP-A-2004-357791, JP-A-2006-256999, JP-A-2007-19462, JP-A-2007-84635 and JP-A-2007-96259. Examples of luminescent dopants which are far preferred among those compounds include the Ir complexes, the Pt complexes, the Cu complexes, the Re complexes, the W complexes, the Rh complexes, the Ru complexes, the Pd complexes, the Os complexes, the Eu complexes, the Tb complexes, the Gd complexes, the Dy complexes and the Ce complexes. Of these complexes, Ir complexes, the Pt complexes and the Re complexes are particularly preferable, notably Ir complexes, the Pt complexes and the Re complexes each having at least one kind of coordination bond selected from metal-carbon, metal-nitrogen, metal-oxygen and metal-sulfur coordinate bonds. In terms of luminous efficiency, durability under driving, chromaticity and so on, the Ir complexes, the Pt complexes and the Re complexes each having a polydentate ligand, including a tridentate ligand or higher, are preferred over the others.

The content of phosphorescent materials in the light emitting layer is preferably in a range from 0.1% to 50% by mass, far preferably from 0.2% to 50% by mass, further preferably from 0.3% to 40% by mass, especially preferably from 20% to 30% by mass, with respect to the total mass of the light emitting layer.

The content of phosphorescent materials usable in the invention (the compounds represented by the formula (T-1) and/or phosphorescent materials used in combination therewith) is preferably in a range from 0.1% to 50% by mass, far preferably from 1% to 40% by mass, especially preferably from 5% to 30% by mass, with respect to the total mass of the light emitting layer. In the range from 5% to 30% by mass in particular, luminescence chromaticity of the organic electroluminescence device has small dependence on the concentration of added phosphorescent materials.

It is the best for the present organic electroluminescence device to incorporate at least one of the compounds represented by the formula (T-1) in an amount of 5% to 30% by mass with respect to the total mass of the light emitting layer.

The organic electroluminescence devices preferably contain a hydrocarbon compound, notably in their respective light emitting layers.

And the hydrocarbon compound is preferably a compound represented by the following formula (VI).

The proper use of the compound represented by the formula (VI) in combination with the light emitting materials makes it possible to appropriately control interactions between molecules of the material and to render energy-gap interaction between neighboring molecules uniform, thereby allowing further reduction in drive voltage.

Moreover, the compound which is represented by the formula (VI) and usable in organic electroluminescence devices has excellent chemical stability, and slightly causes degradation, such as decomposition, in materials under driving of the devices, and therefore the organic electroluminescence devices containing the compound of the formula (VI) can avoid reduction in their efficiency and lifespan through decomposition of the materials.

The compound represented by the formula (VI) is explained below.

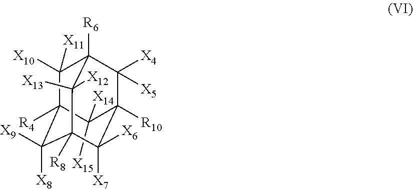

In the formula (VI), each of R₄, R₆, R₈, R₁₀ and X₄ to X₁₅ independently represents a hydrogen atom, an alkyl group or an aryl group.

The alkyl group represented by each of R₄, R₆, R₈, R₁₀ and X₄ to X₁₅ in the formula (VI) may have as a substituent an adamantane structure or an aryl structure, and the number of carbon atoms in the alkyl group is preferably from 1 to 70, far preferably from 1 to 50, further preferably from 1 to 30, still further preferably from 1 to 10, especially preferably from 1 to 6. And the most preferable alkyl groups are linear alkyl groups having 2 to 6 carbon atoms.

Examples of the alkyl group represented by each of R₄, R₆, R₈, R₁₀ and X₄ to X₁₅ in the formula (VI) include an n-C₅₀H₁₀₁ group, an n-C₃₀H₆₁ group, 3-(3,5,7-triphenyladamantane-1-yl)propyl group (number of carbon atoms: 31), a trityl group (number of carbon atoms: 19), 3-(adamantane-1-yl)propyl group (number of carbon atoms: 13), 9-decalyl group (number of carbon atoms: 10), a benzyl group (number of carbon atoms: 7), a cyclohexyl group (number of carbon atoms: 6), a n-hexyl group (number of carbon atoms: 6), an n-pentyl group (number of carbon atoms: 5), an n-butyl group (number of carbon atoms: 4), an n-propyl group (number of carbon atoms: 3), a cyclopropyl group (number of carbon atoms: 3), an ethyl group (number of carbon atoms: 2) and a methyl group (number of carbon atoms: 1).

The aryl group represented by each of R₄, R₆, R₈, R₁₀ and X₄ to X₁₅ in the formula (VI) may have as a substituent an adamantane structure or an alkyl structure, and the number of carbon atoms the aryl group has is preferably from 6 to 30, far preferably from 6 to 20, further preferably from 6 to 15, especially preferably from 6 to 10, the most preferably is 6.

Examples of the aryl group represented by each of R₄, R₆, R₈, R₁₀ and X₄ to X₁₅ in the formula (VI) include a 1-pyrenyl group (number of carbon atoms: 16), a 9-anthracenyl group (number of carbon atoms: 14), a 1-naphthyl group (number of carbon atoms: 10), a 2-naphthyl group (number of carbon atom: 10), a p-t-butylphenyl group (number of carbon atoms: 10), a 2-m-xylyl group (number of carbon atoms: 8), a 5-m-xylyl group (number of carbon atoms: 8), an o-tolyl group (number of carbon atoms: 7), a m-tolyl group (number of carbon atoms: 7), a p-tolyl group (number of carbon atoms: 7) and a phenyl group (number of carbon atoms: 6).

Although each of R₄, R₆, R₈ and R₁₀ in the formula (VI) may be either a hydrogen atom, or an alkyl group, or an aryl group, from the viewpoint that high glass transition temperatures are preferable, it is preferable that at least one of them is an aryl group, it is far preferable that at least two of them are aryl groups, and it is particularly preferable that 3 or 4 of them are aryl groups.

Although each of X₄ to X₁₅ in the formula (VI) may be either a hydrogen atom, or an alkyl group, or an aryl group, it is preferable that each are a hydrogen atom or an aryl group, especially a hydrogen atom.

The organic electroluminescence devices are made using a vacuum deposition process or a solution coating process, and therefore, in terms of vacuum deposition suitability and solubility, the molecular weight of the compounds represented by the formula (VI) in the invention is preferably 2,000 or below, far preferably 1,200 or below, especially 1,000 or below. Also, from the viewpoint of vacuum deposition suitability, the molecular weight is preferably 250 or above, far preferably 350 or above, particularly preferably 400 or above. This is because, when the compounds have too low molecular weight, their vapor pressure becomes low and change from a vapor phase to a solid phase does not occur, and it is therefore difficult for the compounds to form organic layers.

The compound represented by the formula (VI) is preferably in solid phase at room temperature (25° C.), far preferably solid phase in a range from room temperature to 40° C., especially preferably solid phase in a range from room temperature to 60° C.

In the case of using the compound which, though represented by the formula (VI), is not in solid phase at room temperature, it is possible to form a solid phase at ordinary temperatures by combining the compound with other substances.

Uses of the compound represented by the formula (VI) are not limited, and the compound may be incorporated into any of the organic layers. The layer into which the compound represented by the formula (VI) in the invention is introduced is preferably a layer selected from a light emitting layer, a hole injection layer, a hole transport layer, an electron transport layer, an electron injection layer, an exciton block layer and a charge block layer, or a combination of two or more of these layers, far preferably a layer selected from the light emitting layer, the hole injection layer, the hole transport layer, the electron transport layer and the electron injection layer, or a combination of two or more of these layers, especially preferably a layer selected from the light emitting layer, the hole injection layer and the hole transport layer, or a combination of at least two of these layers, the most preferably the light emitting layer.

When the compound represented by the formula (VI) is used in an organic layer, its content is required to be limited so as not to inhibit charge transportability, and therefore it is preferable from 0.1% to 70% by mass, far preferable from 0.1% to 30% by mass, especially preferable from 0.1% to 25% by mass.

When the compound represented by the formula (VI) is used in two or more organic layers, its content in each organic layer is preferably in the range specified above.

Into any one of the organic layers, only one among the compounds represented by the formula (VI) may be incorporated, or any two or more of the compounds represented by the formula (VI) may be combined in arbitrary proportions and incorporated.

Examples of the hydrocarbon compound are illustrated below, but the invention should not be construed as being limited to these examples.

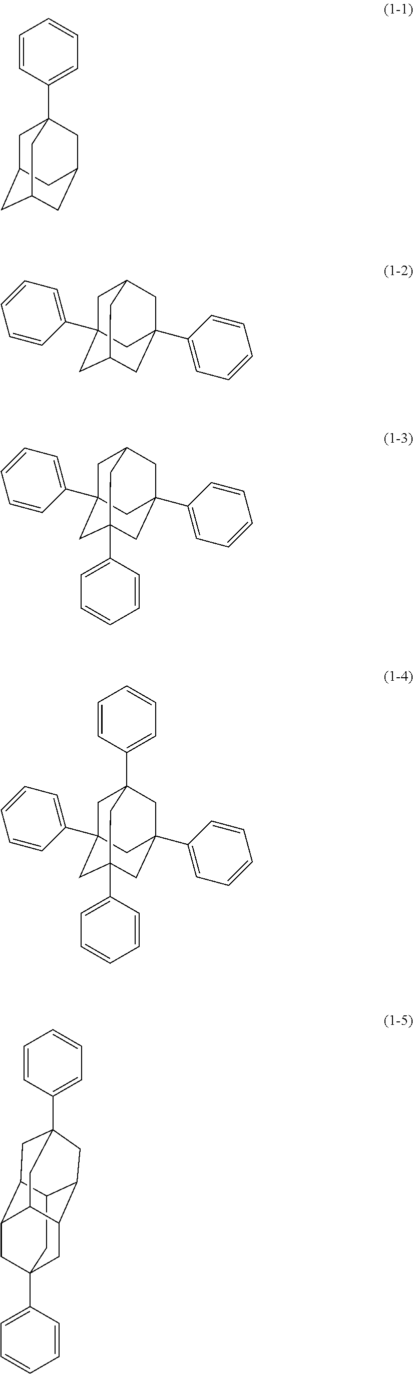

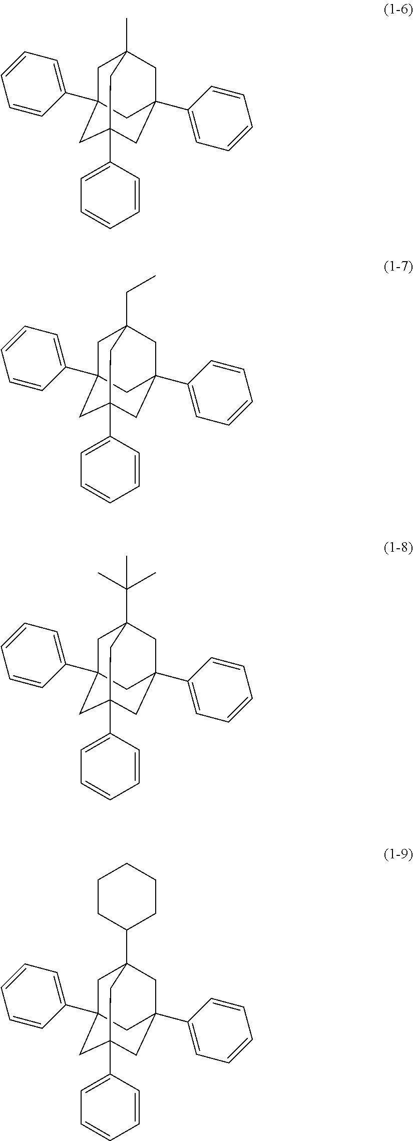

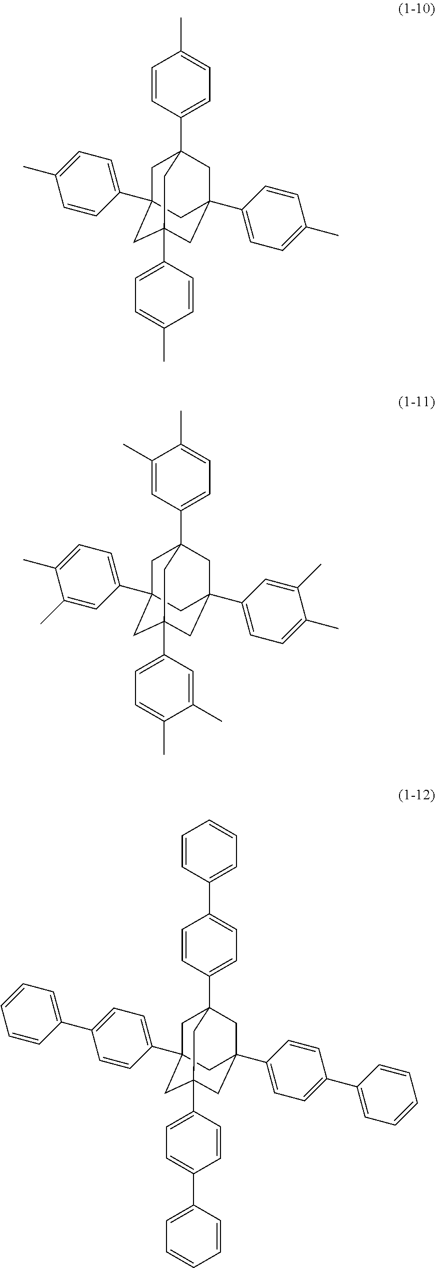

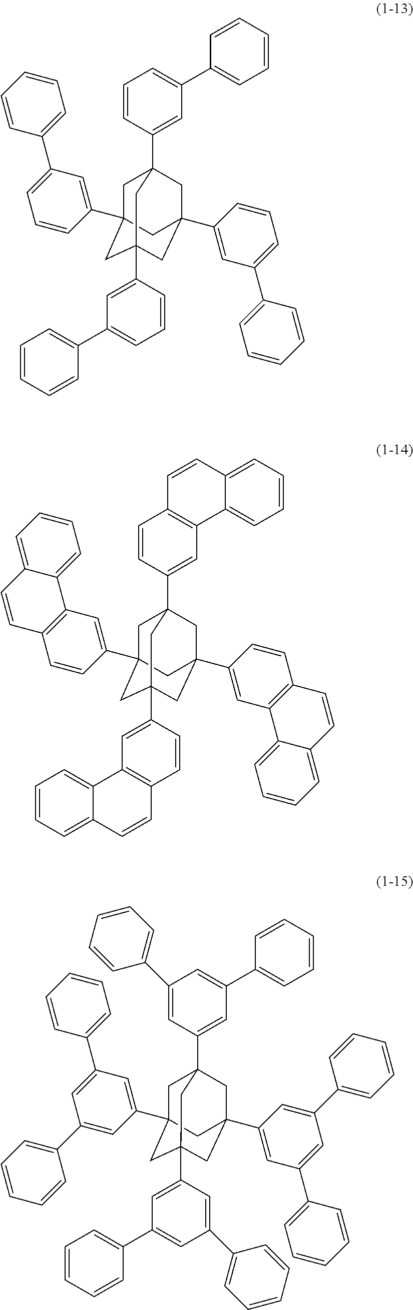

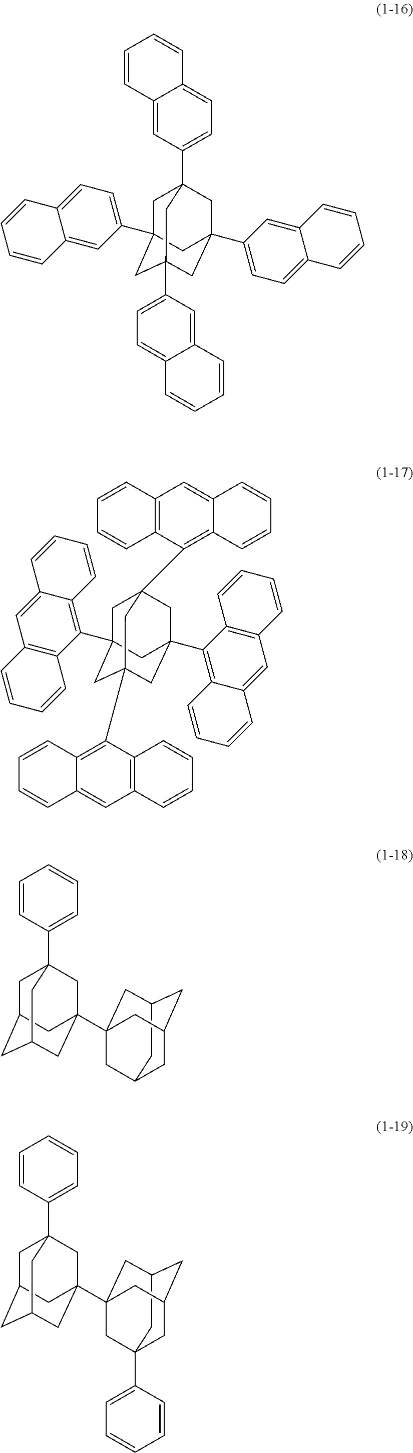

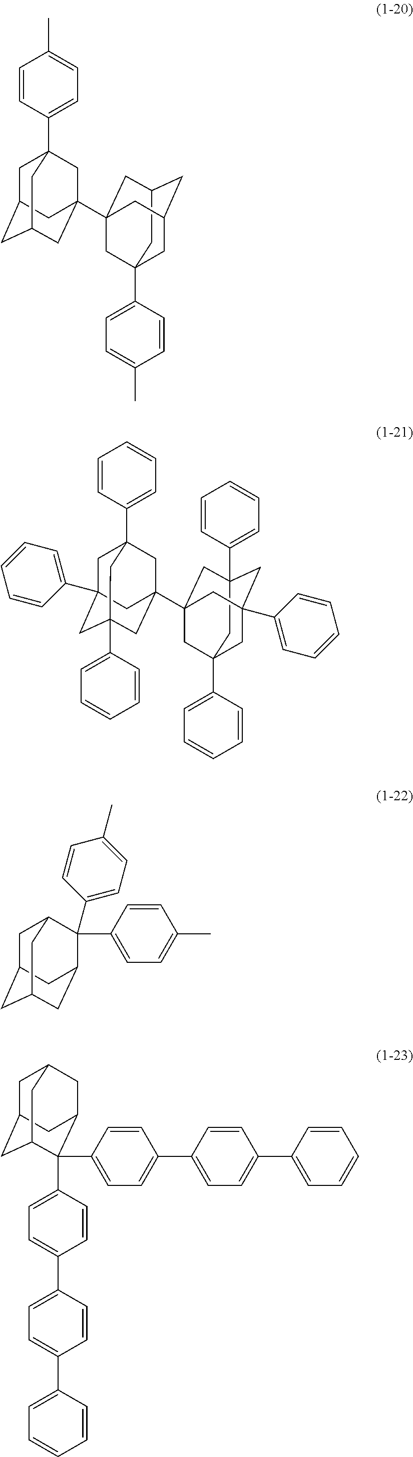

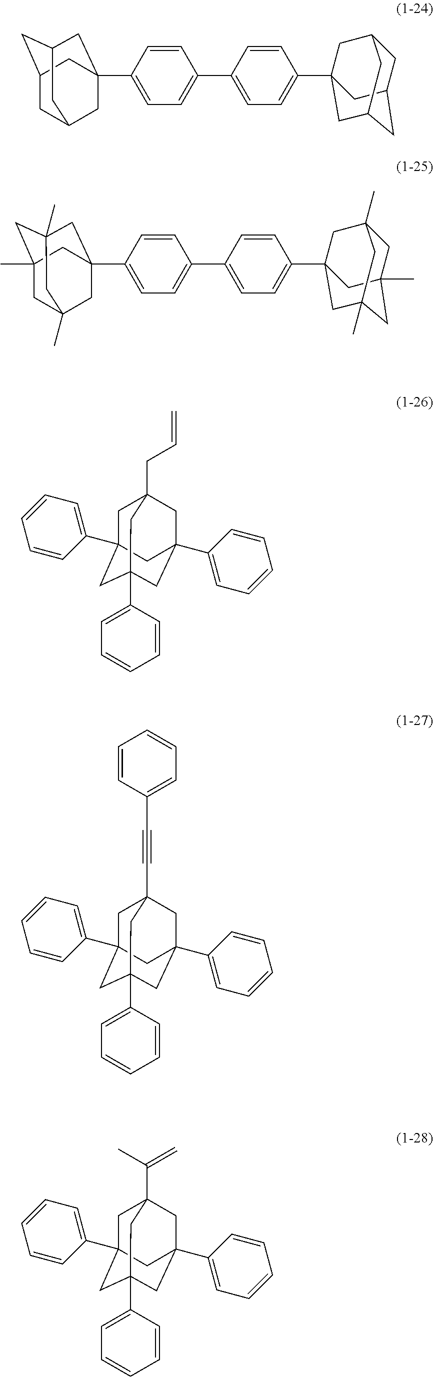

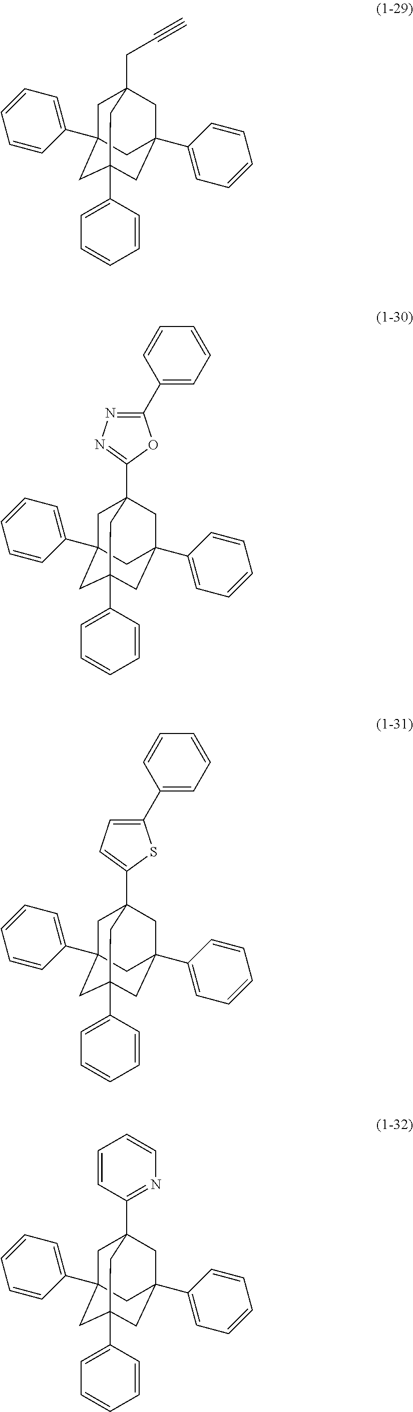

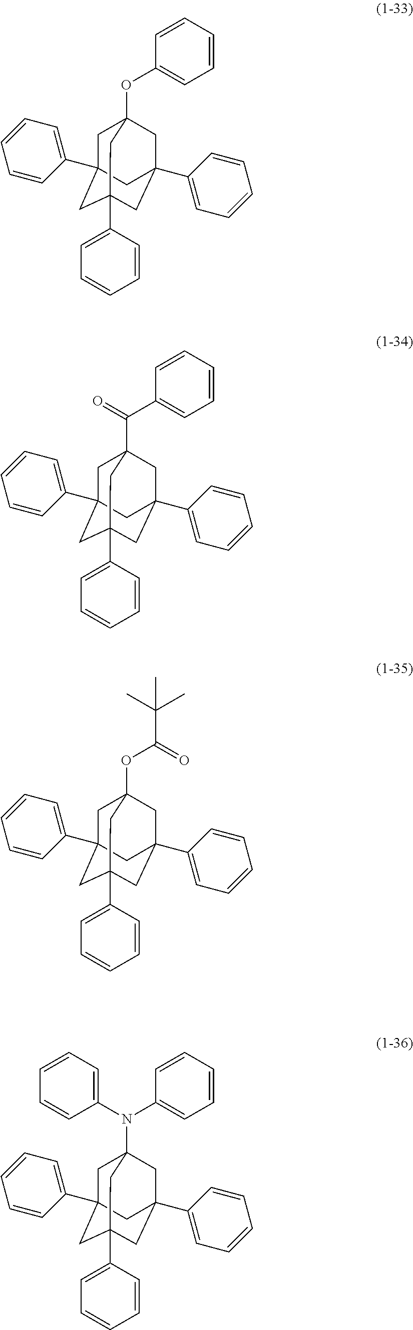

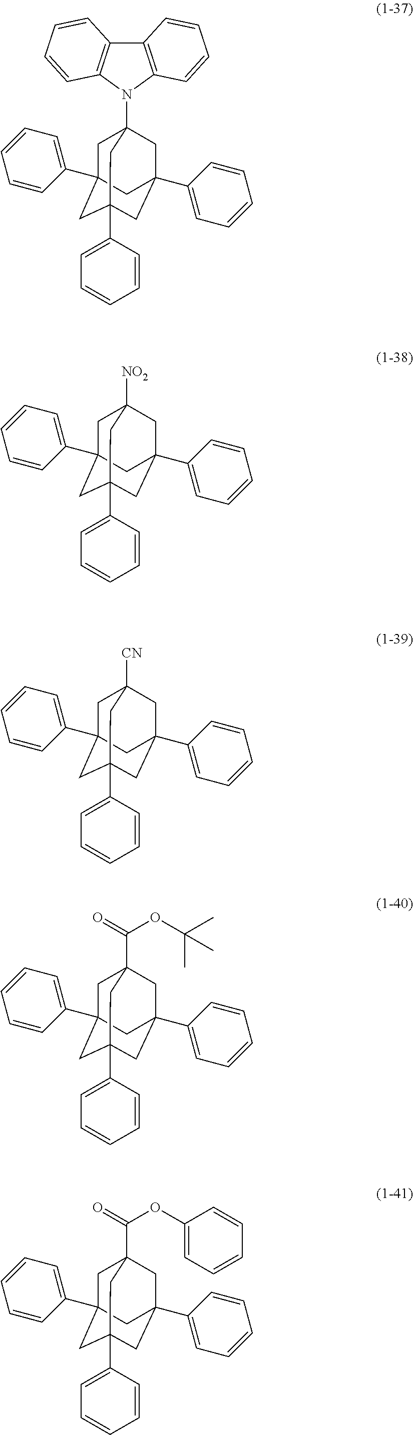

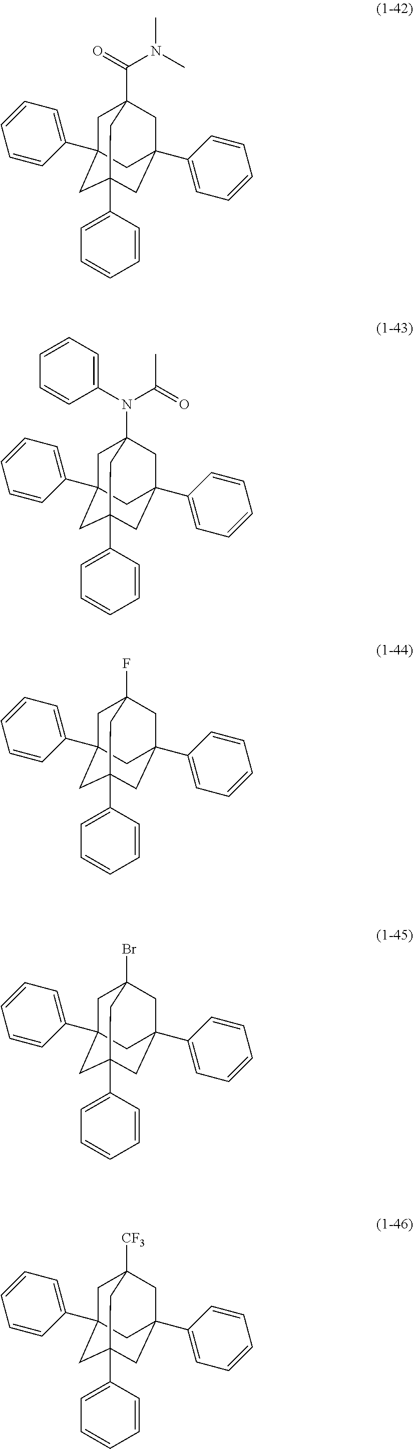

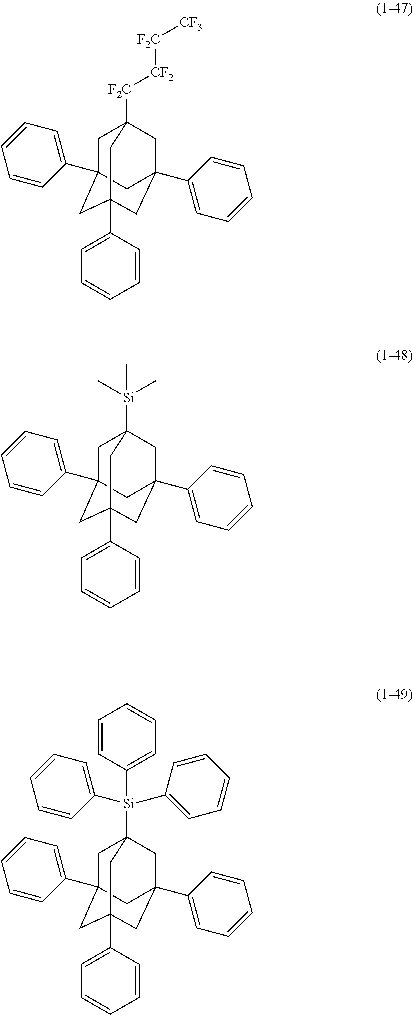

The compound represented by the formula (VI) can be synthesized by appropriately combining adamantane or haloadamantane with haloalkane or alkylmagnesium halide (Grignard reagent). For instance, it is possible to provide coupling between haloadamantane and haloalkane by use of indium (Reference 1). Alternatively, it is possible to convert haloalkane into an alkylcopper reagent and further to couple the reagent to Grignard reagent of an aromatic compound (Reference 2). Further, the coupling of haloalkane can also be performed using an appropriate arylboric acid and a palladium catalyst (Reference 3).
Reference 1: Tetrahedron Lett. 39, 1998, 9557-9558
Reference 2: Tetrahedron Lett. 39, 1998, 2095-2096
Reference 3: J. Am. Chem. Soc. 124, 2002, 13662-13663

The adamantane structure having an aryl group can be synthesized by appropriately combining adamantane or haloadamantane with the corresponding arene or haloarene.

Additionally, even when defined substituents undergo changes under certain synthesis conditions in those production methods or they are unsuitable for carrying out those methods, the intended compounds can be produced with ease by adopting e.g. methods for protecting and deprotecting functional groups (T. W. Greene, Protective Groups in Organic Synthesis, John Wiley & Sons Inc. (1981)). Further, it is also possible to change the order of reaction steps, including a substituent introduction step, as appropriate, if needed.

In general the thickness of the light emitting layer, though not particularly limited, is preferably from 1 nm to 500 nm, far preferably from 5 nm to 200 nm, further preferably from 10 nm to 100 nm.

### —Hole Injection Layer and Hole Transporting Layer—

The hole injection layer and the hole transporting layer are layers having functions of receiving holes from an anode or an anode side and transporting the holes to a cathode side.

### —Electron Injection Layer and Electron Transporting Layer—

The electron injection layer and the electron transporting layer are layers having functions of receiving electron's from a cathode or a cathode side and transporting the electrons to an anode side.

With respect to the hole injection layer, the hole transporting layer, the electron injection layer and the electron transporting layer, the matters described in JP-A-2008-270736, paragraph numbers to, are applicable in the invention.

### —Hole Blocking Layer—

The hole blocking layer is a layer having a function of blocking the holes transported from an anode side to the light emitting layer from passing on through to the cathode side. In the invention, the hole blocking layer can be provided as an organic layer adjacent to the light emitting layer in the cathode side.

Examples of an organic compound which forms the hole blocking layer include aluminum complexes such as aluminum(III) bis(2-methyl-8-quinolinato) 4-phenylphenolate (abbreviated to BAlq), triazole derivatives, and phenanthroline derivatives such as 2,9-dimethyl-4,7-diphenyl-1,10-phenanthroline (abbreviated to BCP).

The thickness of the hole blocking layer is preferably from 1 nm to 500 nm, far preferably from 5 nm to 200 nm, further preferably from 10 nm to 100 nm.

The hole blocking layer may have either a single-layer structure made up of one or more than one material as recited above or a multiple-layer structure made up of two or more layers which are identical or different in composition.

### —Electron Blocking Layer—

The electron blocking layer is a layer having a function of preventing the electrons transported from the cathode side to the light emitting layer from passing through to the anode side. In the invention, the electron blocking layer can be provided as an organic layer adjacent to the light emitting layer on the anode side.

As the examples of the compounds constituting the electron blocking layer, for instance, the hole transport materials described above can be applied.

The thickness of the electron blocking layer is preferably from 1 nm to 500 nm, more preferably from 5 nm to 200 nm, still more preferably from 10 nm to 100 nm. The electron blocking layer may have a single layer structure composed of one or more of the above materials or may be a multilayer structure composed of two or more layers having the same composition or different compositions.

### <Protective Layer>

In the invention, the whole of the organic EL device may be coated with a protective layer.

With respect to the protective layer, the matters described in JP-A-2008-270736, paragraph numbers to, are applicable in the invention.

### <Sealing Enclosure>

The present devices may be sealed in their entirety through the use of sealing enclosure.

With respect to the sealing enclosure, the matters described in JP-A-2008-270736, paragraph number, are applicable in the invention.

### <Film Formation Method>

The invention relates to a film formation method further, wherein the compound represented by the formula (1) and the compound represented by the formula (T-1) are made to sublime at the same time by heating and formed into film.

At the time of film formation, it is preferable that both of the compounds are mixed together, or a composition according to the invention may be used. As to the proportions of the compound represented by the formula (1) and the compound represented by the formula (T-1) which are contained in the mixture or the composition, the compound represented by the formula (T-1) is preferably from 1% to 45%, far preferably from 1% to 25%, with respect to the compound represented by the formula (1).

The heating temperature is preferably from 200° C. to 400° C., far preferably from 250° C. to 320° C.

The heating time is preferably from 0.1 hour to 350 hours, far preferably from 0.1 hour to 150 hours.

The film formation method according to the invention has the advantage that film for the light emitting layer having high efficiency, high durability and a slight color shift under high-temperature drive can be formed with ease.

### (Driving)

The present organic electroluminescence devices each can produce luminescence when direct-current (which may include an alternating current component as required) voltage (ranging usually from 2 to 15 volts) or direct current is applied between the anode and the cathode.

To a driving method for the present organic electroluminescence devices, the driving methods as disclosed in JP-A-2-148687, JP-A-6-301355, JP-A-5-29080, JP-A-7-134558, JP-A-8-234685, JP-A-8-241047, Japanese Patent No. 2784615, U.S. Pat. Nos. 5,828,429 and 6,023,308 can be applied.

The present organic electroluminescence devices can be heightened in light extraction efficiency by utilizing various publicly-known improvements. For instance, it is possible to improve light extraction efficiency and increase external quantum efficiency by working on the substrate's surface profile (e.g. forming a pattern of microscopic asperities on the substrate's surface), or by controlling refractive indices of the substrate, the ITO layer and the organic layers, or by controlling thicknesses of the substrate, the ITO layer and the organic layers, or so on.

The present luminescence devices may adopt a mode of extracting luminescence from the anode side, or the so-called top luminous mode.

The present organic EL devices may have resonator structure. For instance, each device has on a transparent substrate a multilayer film mirror made up of a plurality of laminated films that have different refractive indices, a transparent or translucent electrode, a light emitting layer and a metal electrode which are superposed on top of each other. Reflections of light produced in the light emitting layer occur repeatedly between the multilayer film mirror and the metal electrode which function as reflector plates, thereby producing resonance.

In another aspect, the transparent or translucent electrode and the metal electrode function as reflector plates, respectively, on the transparent substrate, and reflections of light produced in the light emitting layer occur repeatedly between the reflector plates, thereby producing resonance.

In order to form a resonance structure, the optical distance determined from effective refractive indices of the two reflector plates, and refractive indices and thicknesses of each layers sandwiched between the two reflector plates are adjusted to have optimum values for achieving the desired resonance wavelength. The calculating formula in the first aspect case is described in JP-A-9-180883, and that in the second aspect case is described in JP-A-2004-127795.

### (Use of Present Luminescence Device)

The present luminescence devices can be used suitably for light luminous apparatus, pixels, indication devices, displays, backlights, electrophotographic devices, illumination light sources, recording light sources, exposure light sources, readout light sources, sign, billboards, interior decorations or optical communications, especially preferably for devices driven in a region of high-intensity luminescence, such as illumination apparatus and display apparatus.

Next the present light luminous apparatus is explained by reference to FIG. 2.

The present light luminous apparatus incorporates any one of the present organic electroluminescence devices.

FIG. 2 is a cross-sectional diagram schematically showing one example of the present light luminous apparatus.

The light luminous apparatus 20 in FIG. 2 includes a transparent substrate 2 (supporting substrate), an organic electroluminescence device 10, a sealing enclosure 16 and so on.

The organic electroluminescence device 10 is formed by stacking on the substrate 2 an anode 3 (first electrode), an organic layer 11 and a cathode 9 (second electrode) in the order of mention. In addition, a protective layer 12 is superposed on the cathode 9, and on the protective layer 12 a sealing enclosure 16 is further provided via an adhesive layer 14. Incidentally, part of each of the electrodes 3 and 9, a diaphragm and an insulating layer are omitted in FIG. 2.

Herein, a light cure adhesive such as epoxy resin, or a thermosetting adhesive can be used for the adhesive layer 14. Alternatively, a thermosetting adhesive sheet may be used as the adhesive layer 14.

The present light luminous apparatus has no particular restrictions as to its uses, and specifically, it can be utilized e.g. as not only illumination apparatus but also display apparatus of a television set, a personal computer, a mobile phone, an electronic paper or the like.

Then, illumination apparatus relating to an embodiment of the invention is explained by reference to FIG. 3.

FIG. 3 is a cross-sectional diagram schematically showing one example of the illumination apparatus relating to an embodiment of the invention.

As shown in FIG. 3, the illumination apparatus 40 relating to an embodiment of the invention is equipped with the organic electroluminescence device 10 and a light scattering member 30. More specifically, the illumination apparatus 40 is configured to bring the substrate 2 of the organic electroluminescence device 10 into a contact with the light scattering member 30.

The light scattering member 30 has no particular restriction so long as it can scatter light, but a suitable example thereof is a glass substrate. And fine particles of transparent resin can be given as a suitable example of fine particles 32. In such illumination apparatus 40, light emitted from the organic electroluminescence device 10 enters the light scattering member 30 at the light incidence plane 30A, the entering light is scattered by the light scattering member, and the light scattered emerges from the light exit plane 30B as light for illumination.

### EXAMPLES

The invention will now be illustrated in more detail by reference to the following examples, but these examples should not be construed as limiting the scope of the invention.

### Synthesis Example 1

Exemplified Compound TM-1 and TM-13 shown hereafter is synthesized according to the method described in EXAMPLE 1 and EXAMPLE 13, respectively of U.S. Pat. No. 7,279,232.

### Example 1

An indium tin oxide (ITO) film-coated glass substrate having an area of 2.5 square centimeters and a thickness of 0.5 mm (made by GEOMATEC Corporation, surface resistivity: 10 Ω/sq) is placed in a cleaning vessel and subjected to ultrasonic cleaning in 2-propanol, and the thus cleaned substrate is further subjected to UV-ozone treatment of 30 minutes. Onto this transparent anode (ITO film), the following organic layers are evaporated in sequence by use of a vacuum evaporation method.

First layer: ITO/CuPc (copper phthalocyanine), Thickness: 10 nm
Second layer: NPD (N,N′-di-α-naphthyl-N,N′-diphenyl)-benzidine, Thickness: 30 nm
Third layer: Dopant (5% by mass), Host material (95% by mass), Thickness: 30 nm
Fourth layer: BAlq, Thickness: 10 nm
Fifth layer: Alq (tris(8-hydroxyquinoline)aluminum complex, Thickness: 40 nm

Onto this layer, 0.2 nm-thick film of lithium fluoride and 70 nm-thick film of metal aluminum are evaporated in the order of mention, thereby forming a cathode.

The laminate thus obtained is placed in a glove box having undergone argon gas displacement without exposure to the air, and sealed by means of a sealing can made of stainless steel and a UV cure adhesive (XNR5516HV, produced by Nagase-Chiba, Ltd.), thereby providing Device 1 according to the invention.

### Examples 2 to 26 and Comparative Examples 1 to 12

A variety of devices are made in the same manner as in Example 1, except that the materials the third layer are changed as shown in Tables 1 to 3.

TABLE 1

| | | | | | Chromaticity | |
|---|---|---|---|---|---|---|
| | Ingredients in Light Emitting | | External | | Shift after | |
| | Layer | | Quantum | Drive | High-Temperature | |
| | Host Material | Dopant | Efficiency | Durability | Drive | Color |
| Comparative | CBP | 5% | 3.2% | 100 | (0.01, 0.02) | Red |
| Example 1 | | Ir(btp)₂(acac) | | | | |
| Comparative | H-1 | 5% | 3.1% | 120 | (0.01, 0.03) | |
| Example 2 | | Ir(btp)₂(acac) | | | | |
| Comparative | Exemplified | 5% | 3.4% | 110 | (0.01, 0.03) | |
| Example 3 | Compound 4 | Ir(btp)₂(acac) | | | | |
| Comparative | CBP | 5% | 6.7% | 145 | (<0.005, 0.009) | |
| Example 4 | | TM-1 | | | | |
| Comparative | H-1 | 5% | 10.7% | 400 | (0.02, 0.03) | |
| Example 5 | | TM-1 | | | | |
| Example 1 | Exemplified | 5% | 12.0% | 650 | (<0.005, <0.005) | |
| | Compound 4 | TM-1 | | | | |
| Example 2 | Exemplified | 5% | 10.4% | 480 | (<0.005, <0.005) | |
| | Compound 49 | TM-1 | | | | |
| Example 3 | Exemplified | 5% | 8.9% | 450 | (<0.005, <0.005) | |
| | Compound 68 | TM-1 | | | | |
| Example 4 | Exemplified | 5% | 10.5% | 750 | (<0.005, <0.005) | |
| | Compound 100 | TM-1 | | | | |
| Example 5 | Exemplified | 5% | 12.4% | 580 | (<0.005, <0.005) | |
| | Compound 101 | TM-1 | | | | |
| Example 6 | Exemplified | 5% | 11.9% | 550 | (<0.005, <0.005) | |
| | Compound 103 | TM-1 | | | | |
| Example 7 | Exemplified | 5% | 11.7% | 570 | (<0.005, <0.005) | |
| | Compound 38 | TM-1 | | | | |
| Example 8 | Exemplified | 5% | 13.0% | 450 | (<0.005, <0.005) | |
| | Compound 7 | TM-1 | | | | |
| Example 9 | Exemplified | 5% | 11.3% | 540 | (<0.005, <0.005) | |
| | Compound 54 | TM-1 | | | | |
| Example 10 | Exemplified | 5% | 10.6% | 490 | (<0.005, <0.005) | |
| | Compound 100 | TM-1 | | | | |
| Example 11 | Exemplified | 5% | 11.5% | 600 | (<0.005, <0.005) | |
| | Compound 111 | TM-1 | | | | |

TABLE 2

| | | | | | Chromaticity | |
|---|---|---|---|---|---|---|
| | Ingredients in Light Emitting | | External | | Shift after | |
| | Layer | | Quantum | Drive | High-Temperature | |
| | Host Material | Dopant | Efficiency | Durability | Drive | Color |
| Comparative | CBP | 5% | 6.7% | 150 | (<0.005, 0.008) | Red |
| Example 6 | | TM-19 | | | | |
| Comparative | H-1 | 5% | 10.6% | 420 | (0.02, 0.02) | |
| Example 7 | | TM-19 | | | | |
| Example 12 | Exemplified | 5% | 11.5% | 630 | (<0.005, <0.005) | |
| | Compound 4 | TM-19 | | | | |
| Example 13 | Exemplified | 5% | 10.9% | 450 | (<0.005, <0.005) | |
| | Compound 49 | TM-19 | | | | |
| Example 14 | Exemplified | 5% | 9.7% | 440 | (<0.005, <0.005) | |
| | Compound 68 | TM-19 | | | | |
| Example 15 | Exemplified | 5% | 10.5% | 610 | (<0.005, <0.005) | |
| | Compound 4 | TM-15 | | | | |
| Example 16 | Exemplified | 5% | 10.7% | 600 | (<0.005, <0.005) | |
| | Compound 4 | TM-23 | | | | |
| Example 17 | Exemplified | 5% | | | | |
| | Compound 4 | TM-35 | 10.6% | 620 | (<0.005, <0.005) | |
| Example 18 | Exemplified | 5% | 10.7% | 530 | (<0.005, <0.005) | |
| | Compound 4 | TM-27 | | | | |

TABLE 3

| | | | | | Chromaticity | |
|---|---|---|---|---|---|---|
| | Ingredients in Light Emitting | | External | | Shift after | |
| | Layer | | Quantum | Drive | High-Temp. | |
| | Host Material | Dopant | Efficiency | Durability | Drive | Color |
| Comparative | CBP | 5% | 7.9% | 300 | (0.02, 0.02) | Green |
| Example 8 | | Ir(ppy)₂(acac) | | | | |
| Comparative | H-1 | 5% | No | Impossible | Impossible | |
| Example 9 | | Ir(ppy)₂(acac) | luminous | to evaluate | to evaluate | |
| | | | of light | | | |
| Comparative | Exemplified | 5% | 14.6% | 500 | (0.01, 0.02) | |
| Example 10 | Compound 4 | Ir(ppy)₂(acac) | | | | |
| Comparative | CBP | 5% | 15.7% | 450 | (0.02, 0.02) | |
| Example 11 | | TM-2 | | | | |
| Comparative | H-1 | 5% | No | Impossible | Impossible | |
| Example 12 | | TM-2 | luminous | to evaluate | to evaluate | |
| | | | of light | | | |
| Example 19 | Exemplified | 5% | 18.9% | 1,000 | (<0.005, <0.005) | |
| | Compound 4 | TM-2 | | | | |
| Example 20 | Exemplified | 5% | 15.8% | 650 | (<0.005, <0.005) | |
| | Compound 49 | TM-2 | | | | |
| Example 21 | Exemplified | 5% | 16.4% | 690 | (<0.005, <0.005) | |
| | Compound 68 | TM-2 | | | | |
| Example 22 | Exemplified | 5% | 17.1% | 670 | (<0.005, <0.005) | |
| | Compound 4 | TM-8 | | | | |
| Example 23 | Exemplified | 5% | 16.5% | 660 | (<0.005, <0.005) | |
| | Compound 4 | TM-16 | | | | |
| Example 24 | Exemplified | 5% | 15.2% | 640 | (<0.005, <0.005) | |
| | Compound 4 | TM-38 | | | | |
| Example 25 | Exemplified | 5% | 15.3% | 690 | (<0.005, <0.005) | |
| | Compound 4 | TM-40 | | | | |
| Example 26 | Exemplified | 5% | 16.1% | 540 | (<0.005, <0.005) | |
| | Compound 4 | TM-24 | | | | |

### (Performance Evaluation of Organic Electroluminescence Device)

Performance evaluations of the various devices thus obtained are conducted.

### (a) External Quantum Efficiency

Each device is made to emit light through the application of a direct-current voltage by means of Source Measure Unit 2400 made by TOYO Corporation, and the intensity of the light is measured with a luminance meter BM-8 made by TOPCON CORPORATION. And the luminous spectrum and the luminous wavelength are measured with a Spectral Analyzer PMA-11 made by Hamamatsu Photonics K.K. On the basis of these data, the external quantum efficiency at a luminance of about 1,000 cd/m² is calculated according to a luminance conversion method.

### (c) Drive Durability

Each device is made to continue emitting light through the application of a direct-current voltage to achieve the luminance of 1,000 cd/m², and the time required for the luminance to be reduced to 500 cd/m² is taken as an index of drive durability. In Tables 1 to 3, the drive durability values are shown as relative values, with the case of Comparative Example 1 being taken as 100.

(d) Chromaticity Shift under High-Temperature Drive

Differences in x-value and y-value (Δx, Δy) between the chromaticity of light emitted from each device through the application of a direct-current voltage to achieve the luminance of 1,000 cd/m² (Δx) and the chromaticity of light emitted from each device at the time when the luminance is reduced to 500 cd/m² by the device being placed in an 80° C. constant-temperature oven and made to continue emitting light through the application of a direct-current voltage to achieve the luminance of 1,000 cd/m² (Δy) are taken as an index of chromaticity shift under high-temperature drive.

From the results shown in Tables 1 to 3, it can be seen that the present devices using carbazolyl-containing host materials represented by the formula (1) and particular iridium complexes represented by the formula (T-1) in combination in their respective light emitting layers are extremely superior in external quantum efficiency and drive durability to the comparative devices, and have a smaller color shift after high-temperature drive than the comparative devices.

In the cases of light luminous apparatus, display apparatus and illumination apparatus, it is necessary to instantaneously emit high-intensity light from every pixel part by the passage of high current density through each pixel part. The present luminescence devices are therefore designed to enhance luminous efficiency in such cases, and thereby they can be used to advantage.

In addition, the present devices are superior in luminous efficiency and durability even when used in high-temperature surroundings as in the case of an in-car use, and therefore they are suitable for use in light luminous apparatus, display apparatus and illumination apparatus.

The structures of the compounds used in Examples and Comparative Examples are illustrated below.

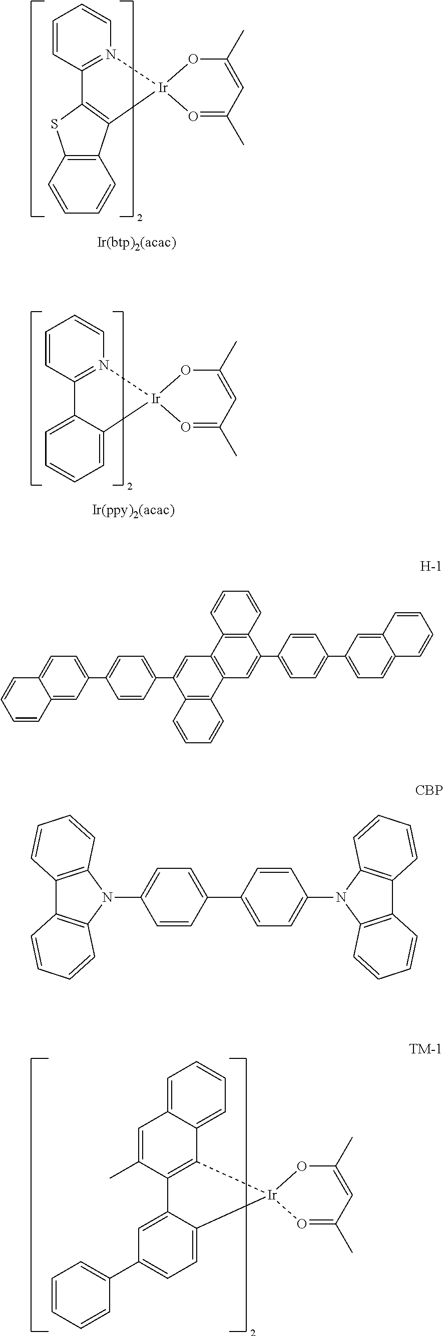

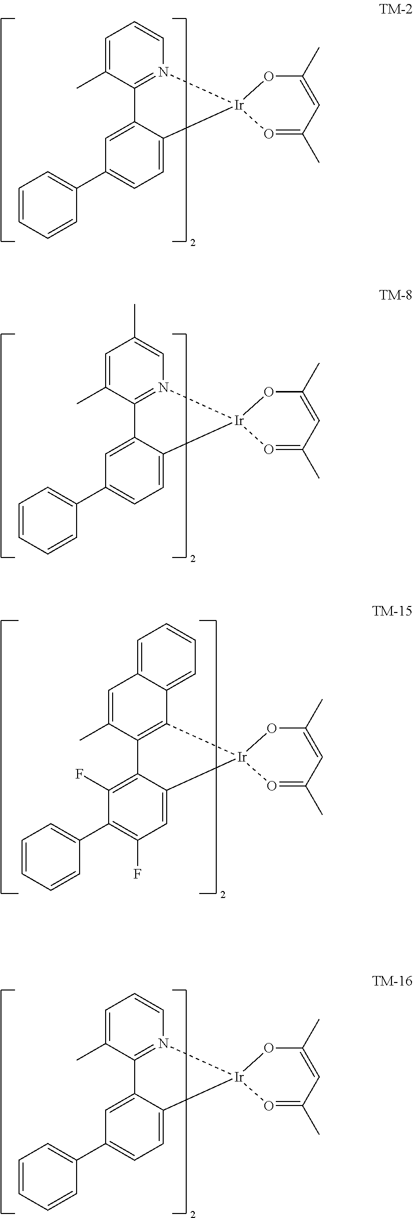

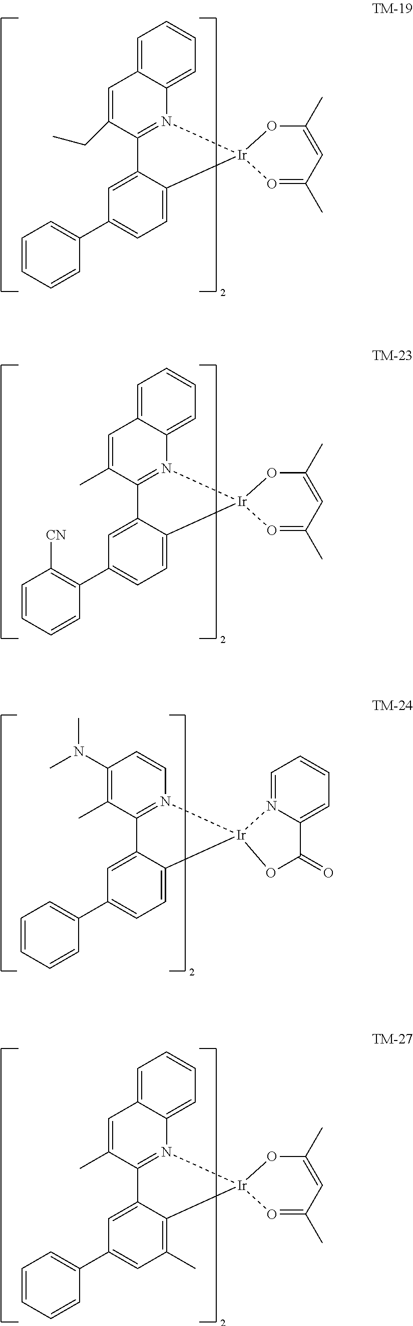

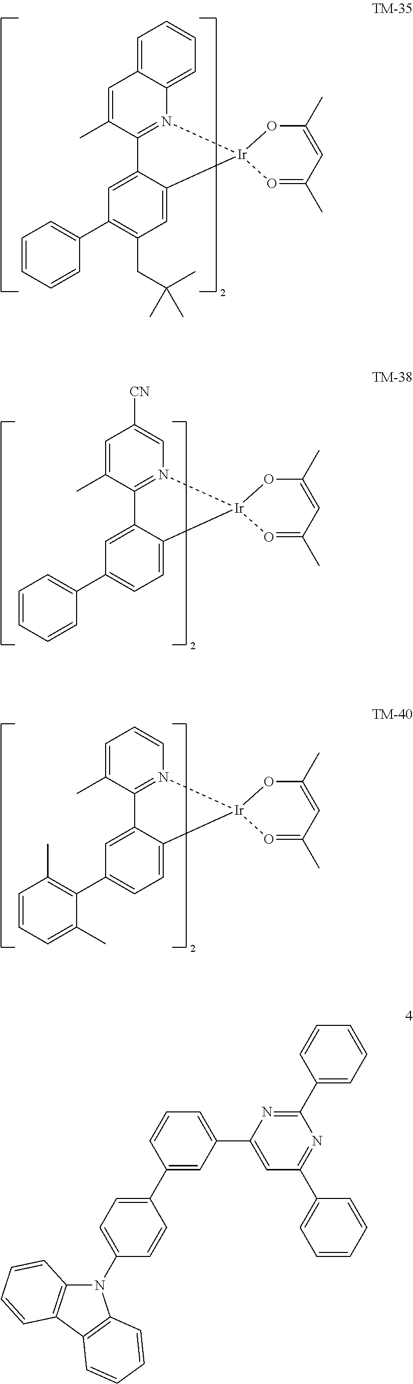

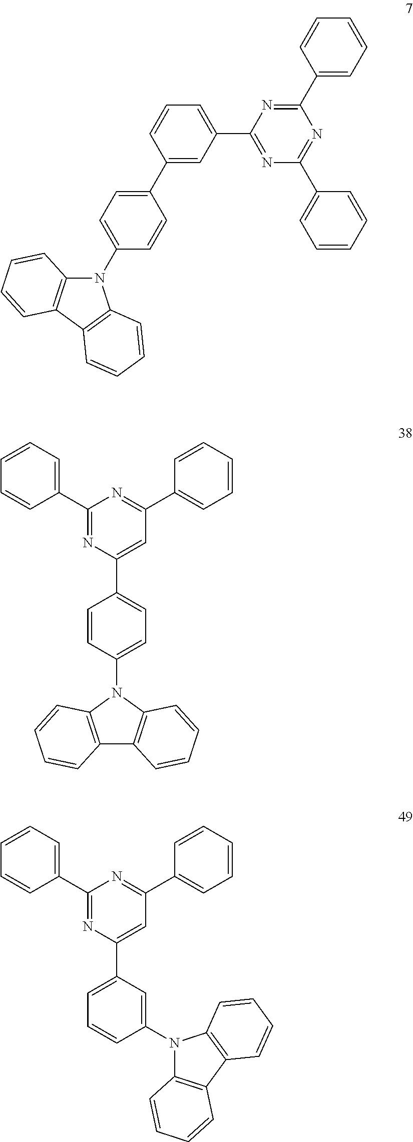

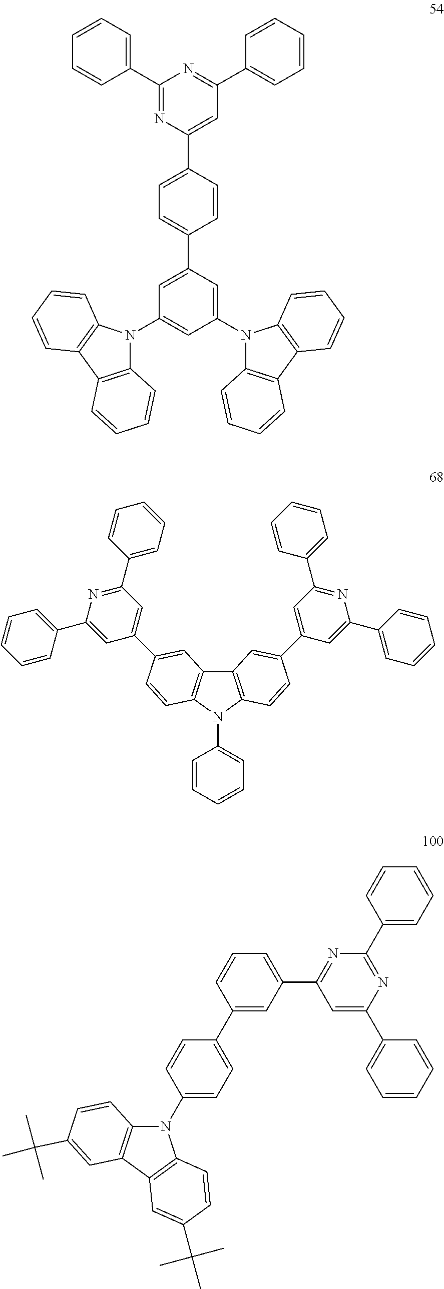

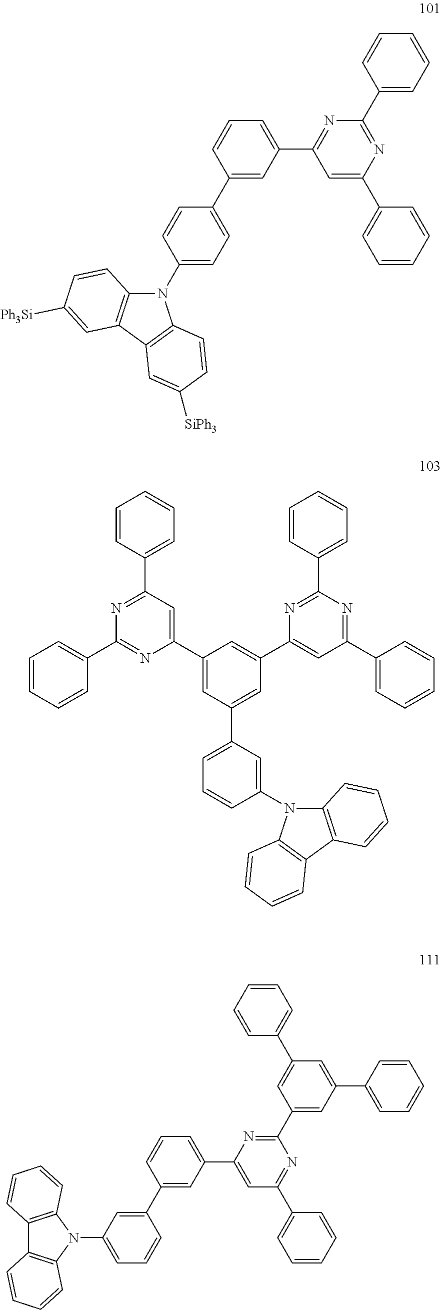

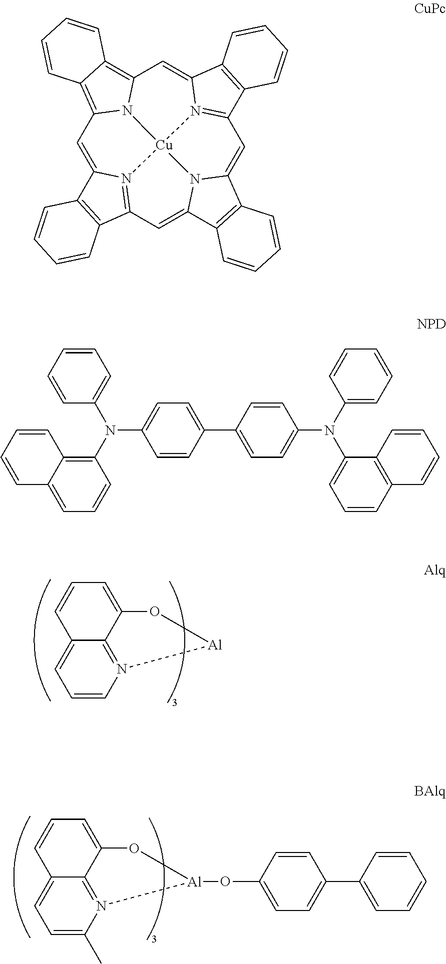

### INDUSTRIAL APPLICABILITY

According to the present invention, an organic electroluminescence device which has excellent luminescence characteristics and capable of suppressing a chromaticity shift under high-temperature drive and excel in luminous efficiency, a composition and a light emitting layer useful to such an organic electroluminescence device, a film formation method for the compound useful to such an organic electroluminescence device, a light luminous apparatus and an illumination apparatus each incorporating such an organic electroluminescence device can be provided.

This application is based on Japanese patent application Nos. 2009-180224 filed on Jul. 31, 2009, and 2009-221665 filed on Sep. 25, 2009, the entire content of which is hereby incorporated by reference, the same as if set forth at length.

### DESCRIPTION OF REFERENCE NUMERALS AND SIGNS

2 . . . Substrate
3 . . . Anode
4 . . . Hole injection layer
5 . . . Hole transporting layer
6 . . . Light emitting layer
7 . . . Hole blocking layer
8 . . . Electron transporting layer
9 . . . Cathode
10 . . . Organic electroluminescence device (Organic EL device)
11 . . . Organic Layer
12 . . . Protective Layer
14 . . . Adhesive Layer
16 . . . Sealing enclosure
20 . . . Light luminous apparatus
30 . . . Light scattering member
30A . . . Light incidence plane
30B . . . Light exit plane
32 . . . Fine particles
40 . . . Illumination apparatus

1.-15. (canceled)

16. An organic electroluminescence device, comprising on a substrate:
a pair of electrodes; and
a light emitting layer sandwiched between the electrodes,
wherein the light emitting layer contains a compound represented by the following formula (3) and a compound represented by the following formula (T-2): 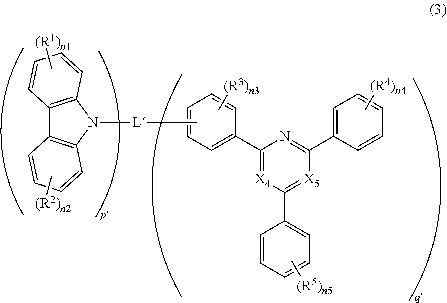
wherein each of X₄ and X₅ independently represents a nitrogen atom or a carbon atom, and a ring containing X₄ and X₅ is a pyridine or a pyrimidine; L′ represents a single bond or a phenylene group; each of R¹ to R⁵ independently represents a fluorine atom, a methyl group, a phenyl group, a cyano group, a pyridyl group, a pyrimidyl group, a silyl group, a carbazolyl group, or tert-butyl group; each of n1 to n5 independently represents an integer of 0 or 1; and each of p′ and q′ independently represents an integer of 1 or 2, and 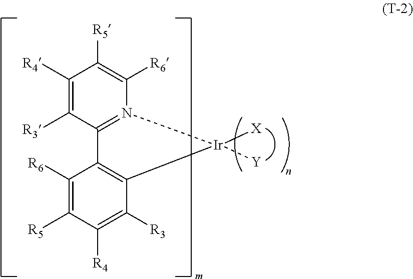
wherein R₃′ represents an alkyl group; each of R₄′ to R₆′ independently represents a hydrogen atom, an alkyl group, an alkenyl group, a heteroalkyl group, an aryl group or a heteroaryl group; R₅′ and R₆′ may combine with each other to from an aryl ring; R₅ represents an aryl group or a heteroaryl group, which each may further have a nonaromatic group, the nonaromatic group is an alkyl group, an alkoxy group, a fluoro group, a cyano group, an alkylamino group, or diarylamino group; each of R₃, R₄ and R₆ independently represents a hydrogen atom or an alkyl group; the heteroalkyl group represents a group in which at least one carbon in an alkyl group is replaced with O, —NR—, or S, and R represents a hydrogen atom, an alkyl group, an alkenyl group, an alkynyl group, a heteroalkyl group, an aryl group, or a heteroaryl group; (X—Y) represents an acetylacetonate or a picolinate; and m represents an integer of 2 and n represents an integer of 1.

17. The organic electroluminescence device according to claim 16,
wherein the ring containing X₄ and X₅ is a pyrimidine.

18. The organic electroluminescence device according to claim 16,
wherein the compound represented by the formula (T-2) is a compound represented by the following formula (T-3): 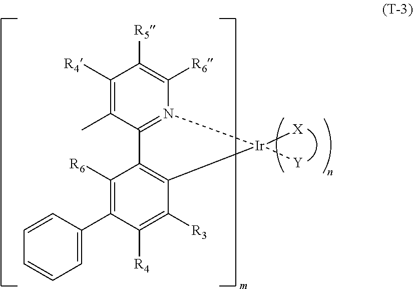
wherein R₄′ independently represents a hydrogen atom, an alkyl group, an alkenyl group, a heteroalkyl group, an aryl group or a heteroaryl group; R₅″ and R₆″ represent hydrogen atoms or combine with each other to form an aryl ring; each of R₃, R₄ and R₆ independently represents a hydrogen atom or an alkyl group; the heteroalkyl group represents a group in which at least one carbon in an alkyl group is replaced with O, —NR—, or S, and R represents a hydrogen atom, an alkyl group, an alkenyl group, an alkynyl group, a heteroalkyl group, an aryl group, or a heteroaryl group; (X—Y) represents an acetylacetonate or a picolinate; and m represents an integer of 2 and n represents an integer of 1.

19. The organic electroluminescence device according to claim 18,
wherein the compound represented by the formula (T-3) is a compound represented by the following formula (T-4): 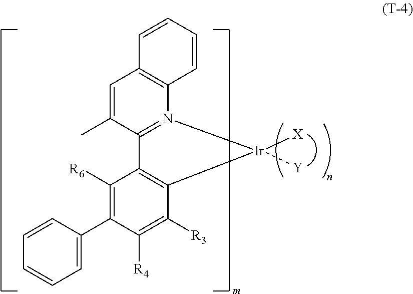
wherein each of R₃, R₄ and R₆ independently represents a hydrogen atom or an alkyl group; (X—Y) represents an acetylacetonate or a picolinate; and m represents an integer of 2 and n represents an integer of 1.

20. The organic electroluminescence device according to claim 18,
wherein R₄′ in the formula (T-2) or (T-3) represents a hydrogen atom, an alkyl group, an aryl group, or a fluoro group.

21. The organic electroluminescence device according to claim 16,
wherein R₅′ and R₆′ in the formula (T-2) represents a hydrogen atom or combine with each other to form an aryl ring.

22. A composition comprising:
a compound represented by the formula (3); and
a compound represented by the formula (T-2), which are recited in claim 16.

23. A light emitting layer comprising:
a compound represented by the formula (3); and
a compound represented by the formula (T-2), which are recited in claim 16.

24. A film formation method,
wherein a compound represented by the formula (3) and a compound represented by the formula (T-2), which are recited in claim 16, are made to sublime by simultaneous heating to form a film.

25. A light luminous apparatus comprising the organic electroluminescence device according to claim 16.

26. A display apparatus comprising the organic electroluminescence device according to claim 16.

27. An illumination apparatus comprising the organic electroluminescence device according to claim 16.
